(19) United States
(12) Patent Application Publication
(10) Pub. No.: US 2019/0285783 A1
(43) Pub. Date: Sep. 19, 2019

(54) COMPOSITION, FILM, OPTICAL FILTER, PATTERN FORMING METHOD, SOLID IMAGE PICKUP ELEMENT, IMAGE DISPLAY DEVICE, AND INFRARED SENSOR

(71) Applicant: FUJIFILM Corporation, Tokyo (JP)

(72) Inventor: Tetsushi MIYATA, Haibara-gun (JP)

(73) Assignee: FUJIFILM Corporation, Tokyo (JP)

(21) Appl. No.: 16/430,995

(22) Filed: Jun. 4, 2019

Related U.S. Application Data
(63) Continuation of application No. PCT/JP2017/044126, filed on Dec. 8, 2017.

(30) Foreign Application Priority Data
Jan. 11, 2017 (JP) 2017-002635

(51) Int. Cl. G02B 5/20; H01L 27/146; C08K 5/00; C08K 5/17; C08K 5/3415; C09B 23/01; C09B 57/00

(52) U.S. Cl. CPC G02B 5/208; H01L 27/14621; C08K 5/0041; C08K 5/005; C08L 33/14; C08K 5/3415; C09B 23/0041; C09B 57/007; C08K 5/17

(57) ABSTRACT

A composition includes a near infrared absorbing colorant, a surfactant, and an antioxidant, in which the near infrared absorbing colorant is a compound that includes a π-conjugated plane having a monocyclic or fused aromatic ring, a content of the near infrared absorbing colorant is 10 mass % or higher with respect to a total solid content of the composition, and the antioxidant is a compound that includes a phenol structure with a hydrocarbon group having one or more carbon atoms.

### CROSS-REFERENCE TO RELATED APPLICATIONS

This application is a Continuation of PCT International Application No. PCT/JP2017/044126, filed on Dec. 8, 2017, which claims priority under 35 U.S.C. § 119(a) to Japanese Patent Application No. 2017-002635, filed on Jan. 11, 2017. Each of the above application(s) is hereby expressly incorporated by reference, in its entirety, into the present application.

### BACKGROUND OF THE INVENTION

### 1. Field of the Invention

The present invention relates to a composition, a film, an optical filter, a pattern forming method, a solid image pickup element, an image display device, and an infrared sensor.

### 2. Description of the Related Art

In a video camera, a digital still camera, a mobile phone with a camera function, or the like, a charge coupled device (CCD) or a complementary metal-oxide semiconductor (CMOS), which is a solid image pickup element for a color image, is used. In a light receiving section of this solid image pickup element, a silicon photodiode having sensitivity to infrared light is used. Therefore, visibility may be corrected using a near infrared cut filter.

The near infrared cut filter is manufactured using a composition including a near infrared absorbing colorant. For example, JP1999-231126A (JP-H11-231126A) describes that a near infrared cut filter is manufactured using a polymer composition including: at least two or more colorants selected from the group consisting of a diimmonium compound, a fluorine-containing phthalocyanine compound, and a nickel complex compound as near infrared absorbing colorants; and further including a hindered phenol primary antioxidant and a phosphorus secondary antioxidant as antioxidants.

An antioxidant is used in, for example, a composition for a chromatic color filter (for example, refer to JP2002-022925A) or a composition for lithographic printing (for example, refer to JP2009-086355A).

### SUMMARY OF THE INVENTION

According to the investigation by the present inventors, it was found that, in a case where a film is obtained by using a composition including 10 mass % or higher of a compound having a wide π-conjugated plane with respect to the total solid content as a near infrared absorbing colorant, the moisture resistance of the film is insufficient, and spectral characteristics of the film are likely to vary in case of being exposed to a high humidity environment. In addition, according to the investigation by the present inventors, it was found that moisture resistance was insufficient in the near infrared cut filter described in JP1999-231126A (JP-H11-231126A).

JP2002-022925A and JP2009-086355A neither describes nor implies the composition including 10 mass % or higher of the near infrared absorbing colorant with respect to the total solid content.

Accordingly, an object of the present invention is to provide a composition with which a film in which moisture resistance is excellent and spectral characteristics are not likely to vary even in case of being exposed to a high humidity environment can be manufactured. In addition, another object of the present invention is to provide a film having high moisture resistance, an optical filter, a pattern forming method, a solid image pickup element, an image display device, and an infrared sensor.

According to the investigation, the present inventors found that the objects can be achieved using a composition described below, thereby completing the present invention. The present invention provides the following.

<1> A composition comprising:

a near infrared absorbing colorant;

a surfactant; and

an antioxidant,

in which the near infrared absorbing colorant is a compound that includes a π-conjugated plane having a monocyclic or fused aromatic ring,

a content of the near infrared absorbing colorant is 10 mass % or higher with respect to a total solid content of the composition, and

the antioxidant is a compound that includes a phenol structure with a hydrocarbon group having one or more carbon atoms.

<2> The composition according to <1>,

in which the antioxidant is a compound having a structure represented by the following Formula (A-1),

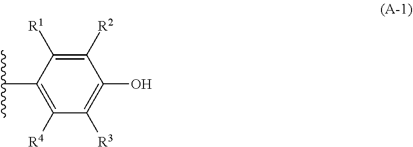

in Formula (A-1), R¹ to R⁴ each independently represent a hydrogen atom or a substituent, at least one of R¹, . . . , or R⁴ represents a hydrocarbon group having one or more carbon atoms, and a wave line represents a direct bond to another atom or atomic group in the antioxidant.

<3> The composition according to <2>,

in which at least one of R² or R³ in Formula (A-1) represents a hydrocarbon group having one or more carbon atoms.

<4> The composition according to <2> or <3>, in which the antioxidant is a compound having two or more structures represented by Formula (A-1) in one molecule.

<5> The composition according to any one of <1> to <4>, in which the antioxidant is a compound represented by the following Formula (A-2),

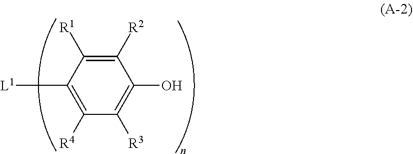

in Formula (A-2), R¹ to R⁴ each independently represent a hydrogen atom or a substituent, at least one of R¹, . . . , or R⁴ represents a hydrocarbon group having one or more carbon atoms, L¹ represents an n-valent group, and n represents an integer of 1 or more.

<6> The composition according to any one of <1> to <5>, in which the surfactant is a fluorine surfactant.

<7> The composition according to any one of <1> to <6>,

in which the near infrared absorbing colorant has a maximum absorption in a wavelength range of 700 to 1000 nm, and

a ratio Amax/A550 of an absorbance Amax at the maximum absorption to an absorbance A550 at a wavelength of 550 nm is 50 to 500.

<8> The composition according to any one of <1> to <7>,

in which the near infrared absorbing colorant is at least one selected from a pyrrolopyrrole compound, a squarylium compound, or a cyanine compound.

<9> The composition according to any one of <1> to <8>, further comprising: a chromatic colorant or a coloring material that allows transmission of infrared light and shields visible light.

<10> The composition according to any one of <1> to <9>, further comprising: a curable compound.

<11> The composition according to <10>, further comprising:

a photoradical polymerization initiator,

wherein the curable compound includes a radically polymerizable compound.

<12> A film which is formed using the composition according to any one of <1> to <11>.

<13> An optical filter which is formed using the composition according to any one of <1> to <11>.

<14> The optical filter according to <13>,

in which the optical filter is a near infrared cut filter or an infrared transmitting filter.

<15> A pattern forming method comprising:

a step of forming a composition layer on a support using the composition according to any one of <1> to <11>; and

a step of forming a pattern on the composition layer using a photolithography method or a dry etching method.

<16> A solid image pickup element comprising:

the film according to <12>.

<17> An image display device comprising:

the film according to <12>.

<18> An infrared sensor comprising:

the film according to <12>.

According to the present invention, it is possible to provide a composition with which a film in which moisture resistance is excellent and spectral characteristics are not likely to vary even in case of being exposed to a high humidity environment can be manufactured. In addition, it is possible to provide a film having high moisture resistance, an optical filter, a pattern forming method, a solid image pickup element, an image display device, and an infrared sensor.

### BRIEF DESCRIPTION OF THE DRAWINGS

FIG. 1 is a schematic diagram showing an embodiment of an infrared sensor.

### DESCRIPTION OF THE PREFERRED EMBODIMENTS

Hereinafter, the details of the present invention will be described.

In this specification, numerical ranges represented by “to” include numerical values before and after “to” as lower limit values and upper limit values.

In this specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In this specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by excimer laser, an extreme ultraviolet ray (EUV ray), an X-ray, or an electron beam.

In this specification, “(meth)allyl group” denotes either or both of allyl and methallyl, “(meth)acrylate” denotes either or both of acrylate or methacrylate, “(meth)acryl” denotes either or both of acryl and methacryl, and “(meth)acryloyl” denotes either or both of acryloyl and methacryloyl.

In this specification, a weight-average molecular weight and a number-average molecular weight are defined as values in terms of polystyrene obtained by gel permeation chromatography (GPC). In this specification, an weight-average molecular weight (Mw) and a number-average molecular weight (Mn) can be obtained by using HLC-8220 (manufactured by Tosoh Corporation), using TSKgel Super AWM-H (manufactured by Tosoh Corporation; 6.0 mm ID (inner diameter)×15.0 cm) as a column, and using tetrahydrofuran as an eluent.

In this specification, near infrared light denotes light (electromagnetic wave) having a maximum absorption in a wavelength range of 700 to 2500 nm.

In this specification, a total solid content denotes the total mass of all the components of the composition excluding a solvent.

In this specification, the term “step” denotes not only an individual step but also a step which is not clearly distinguishable from another step as long as an effect expected from the step can be achieved.

<Composition>

A composition according to an embodiment of the present invention comprises:

a near infrared absorbing colorant;

a surfactant; and

an antioxidant,

in which the near infrared absorbing colorant is a compound that includes a π-conjugated plane having a monocyclic or fused aromatic ring,

a content of the near infrared absorbing colorant is 10 mass % or higher with respect to a total solid content of the composition, and

the antioxidant is a compound that includes a phenol structure with a hydrocarbon group having one or more carbon atoms.

With the composition according to the embodiment of the present invention, a film in which moisture resistance is excellent and spectral characteristics are not likely to vary even in case of being exposed to a high humidity environment can be manufactured. The reason why this effect is obtained is presumed to be as follows.

In a case where a compound that has a π-conjugated plane including a monocyclic or fused aromatic ring is used as a near infrared absorbing colorant, this near infrared absorbing colorant is likely to cause an aggregate to be formed in the film due to an interaction between π-conjugated planes. It is presumed that the formation of an aggregate is likely to be promoted in a high humidity environment. Therefore, it is presumed that, in a case where the film including the near infrared absorbing colorant is exposed to a high humidity environment, for example, particles of the near infrared absorbing colorant locally aggregate in the film such that spectral characteristics are likely to vary. However, in addition to the near infrared absorbing colorant, the composition according to the embodiment of the present invention further includes: a compound (hereinafter, also referred to as “phenol antioxidant”) that includes a phenol structure with a hydrocarbon group having one or more carbon atoms as an antioxidant; and a surfactant. The composition according to the embodiment of the present invention includes the phenol antioxidant. Therefore, it is presumed that a phenol portion in the phenol antioxidant and the near infrared absorbing colorant approach each other due to an interaction. This phenol antioxidant includes a hydrocarbon group having one or more carbon atoms. Therefore, due to a steric hindrance of the hydrocarbon group having one or more carbon atoms, the aggregation of particles of the near infrared absorbing colorant can be suppressed. In addition, it is presumed that, by including the surfactant and unevenly distributing the surfactant on the film surface, the film surface can be treated to be hydrophobic. Therefore, it is presumed that the phenol antioxidant is likely to interact with the near infrared absorbing colorant such that the aggregation of particles of the near infrared absorbing colorant can be more effectively suppressed. Therefore, it is presumed that, with the composition according to the embodiment of the present invention, a film in which moisture resistance is excellent and spectral characteristics are not likely to vary even in case of being exposed to a high humidity environment can be manufactured.

In addition, with the composition according to the embodiment of the present invention, a film having excellent heat resistance can be formed. As described above, with the composition according to the embodiment of the present invention, the surfactant can be unevenly distributed on the film surface, and the phenol antioxidant can be made to be likely to be present in the vicinity of the near infrared absorbing colorant in the film. Therefore, it is presumed that exposure of the near infrared absorbing colorant to the air interface can be suppressed by the surfactant unevenly distributed on the film surface, and an attack of a thermally excited oxygen radical to the near infrared absorbing colorant can be effectively suppressed by the phenol antioxidant present in the vicinity of the near infrared absorbing colorant. Therefore, with the composition according to the embodiment of the present invention, a film having excellent heat resistance can be formed.

Hereinafter, each component of the composition according to the embodiment of the present invention will be described.

<<Near Infrared Absorbing Colorant>>

The composition according to the embodiment of the present invention includes a near infrared absorbing colorant as a compound that includes a π-conjugated plane having a monocyclic or fused aromatic ring. In the present invention, it is preferable that the near infrared absorbing colorant is a compound having an absorption in a near infrared range (preferably in a wavelength range of 700 to 1300 nm and more preferably in a wavelength range of 700 to 1000 nm).

In the present invention, the near infrared absorbing colorant includes the π-conjugated plane having a monocyclic or fused aromatic ring. Therefore, due to an interaction between aromatic rings on the π-conjugated plane of the near infrared absorbing colorant, a J-aggregate of the near infrared absorbing colorant is likely to be formed in the film, and a film having excellent spectral characteristics in a near infrared range can be formed.

In the present invention the near infrared absorbing colorant may be a pigment (also referred to as “near infrared absorbing pigment”) or a dye (also referred to as “near infrared absorbing dye”). It is preferable that the near infrared absorbing colorant is a pigment because a pattern having excellent rectangularity can be easily formed.

The number of atoms constituting the π-conjugated plane of the near infrared absorbing colorant other than hydrogen is preferably 6 or more, more preferably 14 or more, still more preferably 20 or more, still more preferably 25 or more, and still more preferably 30 or more. For example, the upper limit is preferably 80 or less and more preferably 50 or less. In a case where the near infrared absorbing colorant includes two or more π-conjugated planes, the total number of atoms constituting the respective π-conjugated planes of the near infrared absorbing colorant other than hydrogen is preferably 6 or more, more preferably 14 or more, still more preferably 20 or more, still more preferably 25 or more, and still more preferably 30 or more. For example, the upper limit is preferably 80 or less and more preferably 50 or less.

The number of monocyclic or fused aromatic rings in the π-conjugated plane included in the near infrared absorbing colorant is preferably 2 or more, more preferably 3 or more, still more preferably 4 or more, and still more preferably 5 or more. The upper limit is preferably 100 or less, more preferably 50 or less, and still more preferably 30 or less. Examples of the aromatic ring include a benzene ring, a naphthalene ring, a pentalene ring, an indene ring, an azulene ring, a heptalene ring, an indacene ring, a perylene ring, a pentacene ring, a quaterrylene ring, an acenaphthene ring, a phenanthrene ring, an anthracene ring, a naphthacene ring, a chrysene ring, a triphenylene ring, a fluorene ring, a pyridine ring, a quinoline ring, an isoquinoline ring, an imidazole ring, a benzimidazole ring, a pyrazole ring, a thiazole ring, a benzothiazole ring, a triazole ring, a benzotriazole ring, an oxazole ring, a benzoxazole ring, an imidazoline ring, a pyrazine ring, a quinoxaline ring, a pyrimidine ring, a quinazoline ring, a pyridazine ring, a triazine ring, a pyrrole ring, an indole ring, an isoindole ring, a carbazole ring, and a fused ring including the above-described ring.

It is preferable that the near infrared absorbing colorant is a compound having a maximum absorption in a wavelength range of 700 to 1000 nm. In this specification, “having a maximum absorption in a wavelength range of 700 to 1000 nm” denotes having a maximum absorbance in a wavelength range of 700 to 1000 nm in an absorption spectrum of the near infrared absorbing colorant in a solution. Examples of a measurement solvent used for the measurement of the absorption spectra of the near infrared absorbing colorant in the solution include chloroform, methanol, dimethyl sulfoxide, ethyl acetate, and tetrahydrofuran. In the case of a compound which is soluble in chloroform, chloroform is used as the measurement solvent. In the case of a compound which is not soluble in chloroform, methanol is used. In addition, in the case of a compound which is not soluble in chloroform and methanol, dimethyl sulfoxide is used.

It is preferable that the near infrared absorbing colorant is a compound that has a maximum absorption in a wavelength range of 700 to 1000 nm and in which a ratio Amax/A550 of an absorbance Amax at the maximum absorption to an absorbance A550 at a wavelength of 550 nm is 50 to 500. Amax/A550 in the near infrared absorbing colorant is preferably 70 to 450 and more preferably 100 to 400. According to this aspect, a film having excellent visible transparency and near infrared shielding properties can be easily manufactured. The absorbance A550 at a wavelength of 550 nm and the absorbance Amax at the maximum absorption are values obtained from the absorption spectrum of the near infrared absorbing colorant in the solution.

In the present invention, as the near infrared absorbing colorant, at least two compounds having different maximum absorptions are preferably used. According to this aspect, the waveform of the absorption spectrum of the film is wider than that in a case where one near infrared absorbing colorant is used, and the film can shield near infrared light in a wide wavelength range. In a case where at least two compounds having different maximum absorptions are used, it is preferable that the compounds include at least a first near infrared absorbing colorant having a maximum absorption in a wavelength range of 700 to 1000 nm, and a second near infrared absorbing colorant having a maximum absorption in a wavelength range of 700 to 1000 nm which is shorter than the maximum absorption of the first near infrared absorbing colorant, and a difference between the maximum absorption of the first near infrared absorbing colorant and the maximum absorption of the second near infrared absorbing colorant is 1 to 150 nm.

In the present invention, as the near infrared absorbing colorant, at least one selected from a pyrrolopyrrole compound, a cyanine compound, a squarylium compound, a phthalocyanine compound, a naphthalocyanine compound, a quaterrylene compound, a merocyanine compound, a croconium compound, an oxonol compound, a diimmonium compound, a dithiol compound, a triarylmethane compound, a pyrromethene compound, an azomethine compound, an anthraquinone compound, or a dibenzofuranone compound is preferable, at least one selected from a pyrrolopyrrole compound, a cyanine compound, a squarylium compound, a phthalocyanine compound, a naphthalocyanine compound, or a quaterrylene compound is more preferable, at least one selected from a pyrrolopyrrole compound, a cyanine compound, and a squarylium compound is still more preferable, or a pyrrolopyrrole compound is still more preferable. Examples of the diimmonium compound include a compound described in JP2008-528706A, the content of which is incorporated herein by reference. Examples of the phthalocyanine compound include a compound described in paragraph “0093” of JP2012-077153A, oxytitaniumphthalocyanine described in JP2006-343631A, and a compound described in paragraphs “0013” to “0029” of JP2013-195480A, the contents of which are incorporated herein by reference. Examples of the naphthalocyanine compound include a compound described in paragraph “0093” of JP2012-077153A, the content of which is incorporated herein by reference. In addition, as the cyanine compound, the phthalocyanine compound, the naphthalocyanine compound, the diimmonium compound, or the squarylium compound, for example, a compound described in paragraphs “0010” to “0081” of JP2010-111750A may be used, the content of which are incorporated in this specification. In addition, the details of the cyanine compound can be found in, for example, “Functional Colorants by Makoto Okawara, Masaru Matsuoka, Teijiro Kitao, and Tsuneoka Hirashima, published by Kodansha Scientific Ltd.”, the content of which is incorporated herein by reference. In addition, a compound described in paragraphs JP2016-146619A can also be used as the near infrared absorbing colorant, the content of which is incorporated herein by reference.

As the pyrrolopyrrole compound, a compound represented by Formula (PP) is preferable. According to this aspect, a cured film having excellent heat resistance and light fastness can be easily obtained.

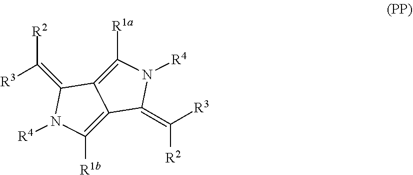

In the formula, R^{1a} and R^{1b} each independently represent an alkyl group, an aryl group, or a heteroaryl group, R² and R³ each independently represent a hydrogen atom or a substituent, R² and R³ may be bonded to each other to form a ring, R⁴'s each independently represent a hydrogen atom, an alkyl group, an aryl group, a heteroaryl group, —BR^{4A}R^{4B}, or a metal atom, R⁴ may form a covalent bond or a coordinate bond with at least one selected from the group consisting of R^{1a}, R^{1b}, and R³, and R^{4A} and R^{4B} each independently represent a substituent. The details of Formula (PP) can be found in paragraphs “0017” to “0047” of JP2009-263614A, paragraphs “0011” to “0036” of JP2011-068731A, and paragraphs “0010” to “0024” of WO2015/166873A, the contents of which are incorporated herein by reference.

R^{1a} and R^{1b} each independently represent preferably an aryl group or a heteroaryl group, and more preferably an aryl group. In addition, the alkyl group, the aryl group, and the heteroaryl group represented by R^{1a} to R^{1b} may have a substituent or may be unsubstituted. Examples of the substituent include an alkoxy group, a hydroxy group, a halogen atom, a cyano group, a nitro group, —OCOR¹¹, —SOR¹², and —SO₂R¹³. R¹¹ to R¹³ each independently represent a hydrocarbon group or a heteroaryl group. In addition, examples of the substituent include substituents described in paragraphs “0020” to “0022” of 2009-263614A. Among these, as the substituent, an alkoxy group, a hydroxy group, a cyano group, a nitro group, —OCOR¹¹, —SOR¹², or —SO₂R¹³ is preferable. As the group represented by R^{1a} and R^{1b}, an aryl group which has an alkoxy group having a branched alkyl group as a substituent, an aryl group which has a hydroxy group as a substituent, or an aryl group which has a group represented by —OCOR¹¹ as a substituent is preferable. The number of carbon atoms in the branched alkyl group is preferably 3 to 30 and more preferably 3 to 20.

It is preferable that at least one of R² or R³ represents an electron-withdrawing group, and it is more preferable that R² represents an electron-withdrawing group (preferably a cyano group) and R³ represents a heteroaryl group. It is preferable that the heteroaryl group is a 5-membered or 6-membered ring. In addition, the heteroaryl group is preferably a monocycle or a fused ring, more preferably a monocycle or a fused ring composed of 2 to 8 rings, and still more preferably a monocycle or a fused ring composed of 2 to 4 rings. The number of heteroatoms constituting the heteroaryl group is preferably 1 to 3 and more preferably 1 or 2. Examples of the heteroatom include a nitrogen atom, an oxygen atom, and a sulfur atom. It is preferable that the heteroaryl group has one or more nitrogen atoms.

It is preferable that R⁴ represents a hydrogen atom or a group represented by —BR^{4A}R^{4B}As the substituent represented by R^{4A} and R^{4B}, a halogen atom, an alkyl group, an alkoxy group, an aryl group, or a heteroaryl group is preferable, an alkyl group, an aryl group, or a heteroaryl group is more preferable, and an aryl group is still more preferable. Specific examples of the group represented by —BR^{4A}R^{4B} include a difluoroboron group, a diphenylboron group, a dibutylboron group, a dinaphthylboron group, and a catecholboron group. In particular, a diphenylboron group is preferable.

Specific examples of the compound represented by Formula (PP) include the following compounds. In the following structural formulae, Me represents a methyl group, and Ph represents a phenyl group. In addition, examples of the pyrrolopyrrole compound include a compound described in paragraphs “0016” to “0058” of JP2009-263614A, a compound described in paragraphs “0037” to “0052” of JP2011-068731A, and a compound described in paragraphs “0010” to “0033” of WO2015/166873A, the contents of which are incorporated herein by reference.

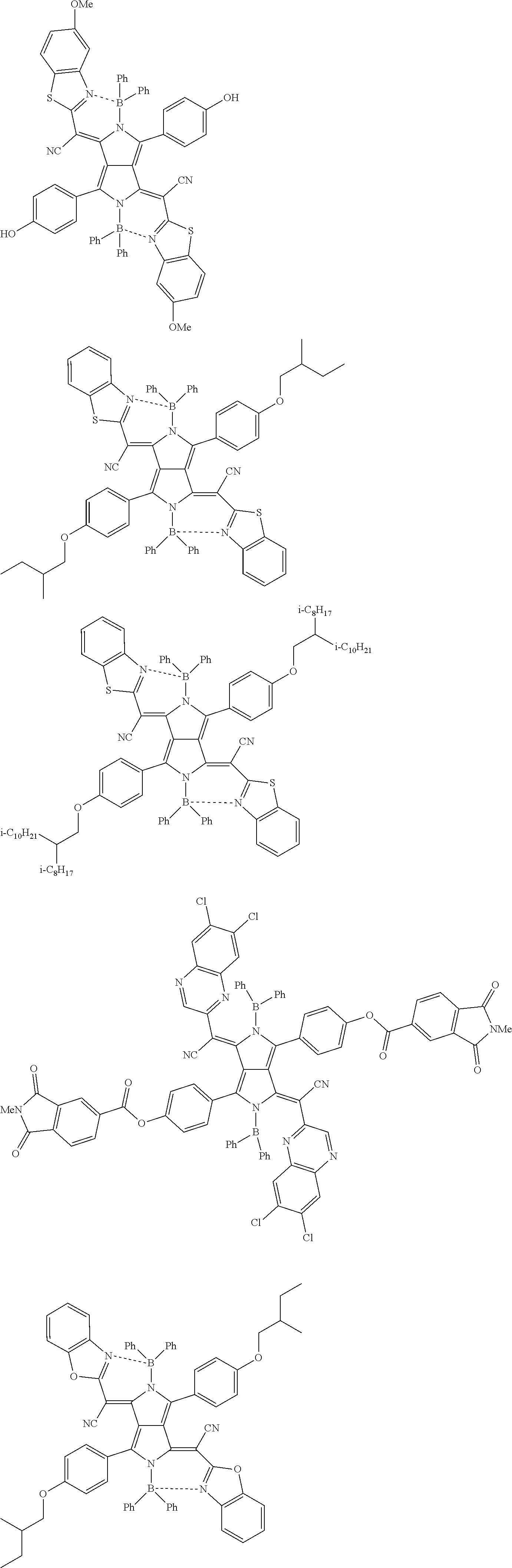

As the squarylium compound, a compound represented by the following Formula (SQ) is preferable.

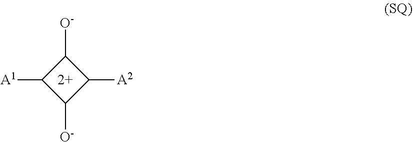

In Formula (SQ), A¹ and A² each independently represent an aryl group, a heteroaryl group, or a group represented by the following Formula (A-1).

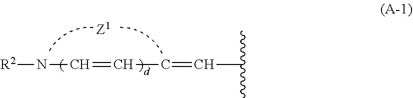

In Formula (A-1), Z¹ represents a non-metal atomic group for forming a nitrogen-containing heterocycle, R² represents an alkyl group, an alkenyl group, or an aralkyl group, d represents 0 or 1, and a wave line represents a direct bond. The details of Formula (SQ) can be found in paragraphs “0020” to “0049” of JP2011-208101A, the content of which is incorporated herein by reference.

As shown below, cations in Formula (SQ) are present without being localized.

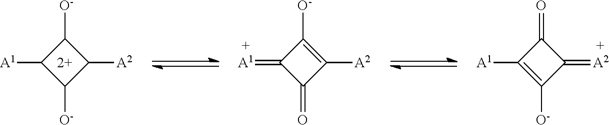

Specific examples of the squarylium compound include the following compounds. In the following structural formula, EH represents an ethylhexyl group. Examples of the squarylium compound include a compound described in paragraphs “0044” to “0049” of JP2011-208101A, the content of which is incorporated herein by reference.

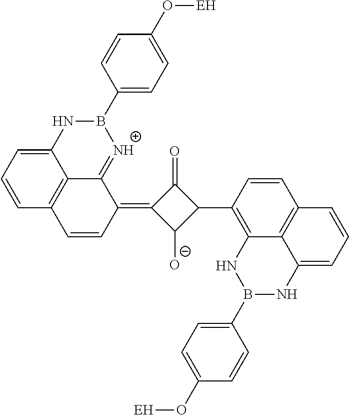

As the cyanine compound, a compound represented by Formula (C) is preferable.

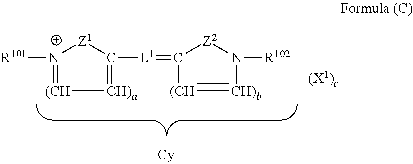

In the formula, Z¹ and Z² each independently represent a non-metal atomic group for forming a 5- or 6-membered nitrogen-containing heterocycle which may be fused.

R¹⁰¹ and R¹⁰² each independently represent an alkyl group, an alkenyl group, an alkynyl group, an aralkyl group, or an aryl group.

L¹ represents a methine chain including an odd number of methine groups.

a and b each independently represent 0 or 1.

In a case where a represents 0, a carbon atom and a nitrogen atom are bonded through a double bond. In a case where b represents 0, a carbon atom and a nitrogen atom are bonded through a single bond.

In a case where a site represented by Cy in the formula is a cation site, X¹ represents an anion, and c represents the number of X¹'s for balancing charge. In a case where a site represented by Cy in the formula is an anion site, X¹ represents a cation, and c represents the number of X¹'s for balancing charge. In a case where charge of a site represented by Cy in the formula is neutralized in a molecule, c represents 0.

Specific examples of the cyanine compound include the following compounds. In the following structural formulae, Me represents a methyl group. In addition, examples of the cyanine compound include a compound described in paragraphs “0044” and “0045” of JP2009-108267A, a compound described in paragraphs “0026” to “0030” of JP2002-194040, a compound described in JP2015-172004A, a compound described in JP2015-172102A, and a compound described in JP2008-088426A, the contents of which are incorporated herein by reference.

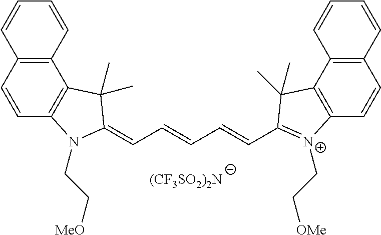

In the present invention, as the near infrared absorbing colorant, a commercially available product can also be used. Examples of the commercially available product include SDO-C33 (manufactured by Arimoto Chemical Co., Ltd.); EXCOLOR IR-14, EXCOLOR IR-10A, EXCOLOR TX-EX-801B, and EXCOLOR TX-EX-805K (manufactured by Nippon Shokubai Co., Ltd.); Shigenox NIA-8041, Shigenox NIA-8042, Shigenox NIA-814, Shigenox NIA-820, and Shigenox NIA-839 (manufactured by Hakkol Chemical Co., Ltd.); Epolite V-63, Epolight 3801, and Epolight3036 (manufactured by Epolin Inc.); PRO-JET 825LDI (manufactured by Fujifilm Corporation); NK-3027 and NK-5060 (manufactured by Hayashibara Co., Ltd.); and YKR-3070 (manufactured by Mitsui Chemicals, Inc.).

In the composition according to the embodiment of the present invention, the content of the near infrared absorbing colorant is preferably 10 mass % or higher, more preferably 12 mass % or higher, and still more preferably 14 mass % or higher with respect to the total solid content of the composition according to the embodiment of the present invention. In a case where the content of the near infrared absorbing colorant is 10 mass % or higher, a film having excellent near infrared shielding properties can be easily formed. The upper limit of the content of the near infrared absorbing colorant is preferably 80 mass % or lower, more preferably 75 mass % or lower, and still more preferably 70 mass % or lower. In the present invention, as the near infrared absorbing colorant, one kind may be used alone, or two or more kinds may be used. In a case where two or near infrared absorbing colorants are used in combination, it is preferable that the total content of the two or more near infrared absorbing colorants is in the above-described range.

<<Other Near Infrared Absorbers>>

The composition according to the embodiment of the present invention may further include near infrared absorbers (also referred to as “other near infrared absorbers”) other than the near infrared absorbing colorant. Examples of the other near infrared absorbers include an inorganic pigment (inorganic particles). The shape of the inorganic pigment is not particularly limited and may have a sheet shape, a wire shape, or a tube shape irrespective of whether or not the shape is spherical or non-spherical. As the inorganic pigment, metal oxide particles or metal particles are preferable. Examples of the metal oxide particles include indium tin oxide (ITO) particles, antimony tin oxide (ATO) particles, zinc oxide (ZnO) particles, Al-doped zinc oxide (Al-doped ZnO) particles, fluorine-doped tin dioxide (F-doped SnO₂) particles, and niobium-doped titanium dioxide (Nb-doped TiO₂) particles. Examples of the metal particles include silver (Ag) particles, gold (Au) particles, copper (Cu) particles, and nickel (Ni) particles. In addition, as the inorganic pigment, a tungsten oxide compound can also be used. As the tungsten oxide compound, cesium tungsten oxide is preferable. The details of the tungsten oxide compound can be found in paragraph “0080” of JP2016-006476A, the content of which is incorporated herein by reference.

In a case where the composition according to the embodiment of the present invention includes the other near infrared absorbers, the content of the other near infrared absorbers is preferably 0.01 to 50 mass % with respect to the total solid content of the composition according to the embodiment of the present invention. The lower limit is preferably 0.1 mass % or higher and more preferably 0.5 mass % or higher. The upper limit is preferably 30 mass % or lower, and more preferably 15 mass % or lower.

In addition, the content of the other near infrared absorbers is preferably 1 to 99 mass % with respect to the total mass of the near infrared absorbing colorant and the other near infrared absorbers. The upper limit is preferably 80 mass % or lower, more preferably 50 mass % or lower, and still more preferably 30 mass % or lower.

In addition, it is also preferable that the composition according to the embodiment of the present invention does not substantially include the other near infrared absorbers. Substantially not including the other near infrared absorbers represents that the content of the other near infrared absorbers is preferably 0.5 mass % or lower, more preferably 0.1 mass % or lower, and still more preferably 0 mass % with respect to the total mass of the near infrared absorbing colorant and the other near infrared absorbers.

<<Surfactant>>

The composition according to the embodiment of the present invention includes a surfactant. As the surfactants, various surfactants such as a fluorine surfactant, a nonionic surfactant, a cationic surfactant, an anionic surfactant, or a silicone surfactant can be used, and a fluorine surfactant is preferable. By the composition according to the embodiment of the present invention including the fluorine surfactant, an effect of suppressing the floating of the near infrared absorbing colorant on the film surface can be expected.

In the present invention, the surfactant may be a compound having a molecular weight of lower than 1000 or a compound having a molecular weight (in the case of a polymer, weight-average molecular weight) of 1000 or higher. In particular, due to the reason that the effect of the present invention can be obtained, it is preferable that the surfactant is a polymer having a weight-average molecular weight of 1000 or higher. The weight-average molecular weight of the surfactant is preferably 3000 or higher and more preferably 5000 or higher. In addition, the upper limit of the weight-average molecular weight of the surfactant is preferably 100000 or lower, more preferably 50000 or lower, and still more preferably 30000 or lower.

Specific examples of the fluorine surfactant include a surfactant described in paragraphs “0060” to “0064” of JP2014-041318A (paragraphs “0060” to “0064” of corresponding WO2014/17669A) and a surfactant described in paragraphs “0117” to “0132” of JP2011-132503A, the content of which is incorporated herein by reference. Examples of a commercially available product of the fluorine surfactant include: MEGAFACE F171, F172, F173, F176, F177, F141, F142, F143, F144, R30, F437, F475, F479, F482, F554, and F780 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC1068, SC-381, SC-383, S393, and KH-40 (all of which are manufactured by Asahi Glass Co., Ltd.); POLYFOX PF636, PF656, PF6320, PF6520, and PF7002 (all of which are manufactured by OMNOVA Solutions Inc.); and FTERGENT FTX-218D (manufactured by Neos Co., Ltd.).

In addition, as the fluorine surfactant, an acrylic compound in which, in a case where heat is applied to a molecular structure which has a functional group having a fluorine atom, the functional group having a fluorine atom is cut and a fluorine atom is volatilized can also be preferably used. Examples of the fluorine surfactant include MEGAFACE DS series (manufactured by DIC Corporation, The Chemical Daily, Feb. 22, 2016, Nikkei Business Daily, Feb. 23, 2016), for example, MEGAFACE DS-21.

As the fluorine surfactant, a block polymer can also be used. Examples of the block polymer include a compound described in JP2011-089090A. As the fluorine surfactant, a fluorine-containing polymer compound is preferably used, the fluorine-containing polymer compound including: a repeating unit derived from a (meth)acrylate compound having a fluorine atom; and a repeating unit derived from a (meth)acrylate compound having two or more (preferably 5 or more) alkyleneoxy groups (preferably an ethyleneoxy group and a propyleneoxy group). For example, the following compound can also be used as the fluorine surfactant used in the present invention.

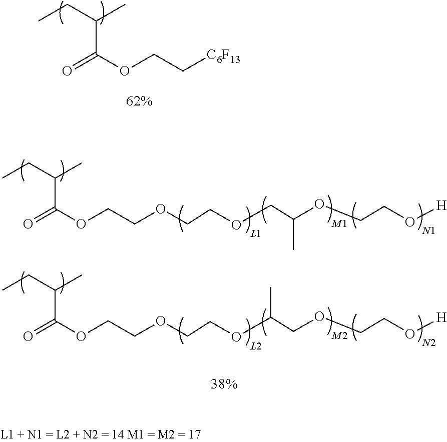

The weight-average molecular weight of the compound is preferably 3000 to 50000 and, for example, 14000. In the compound, “%” representing the proportion of a repeating unit is mol %.

In addition, as the fluorine surfactant, a fluorine-containing polymer having an ethylenically unsaturated group at a side chain can also be used. Specific examples include a compound described in paragraphs “0050” to “0090” and paragraphs “0289” to “0295” of JP2010-164965A, for example, MEGAFACE RS-101, RS-102, RS-718K, and RS-72-K manufactured by DIC Corporation. As the fluorine surfactant, a compound described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE)), SOLSPERSE 20000 (manufactured by Lubrication Technology Inc.), NCW-101, NCW-1001, and NCW-1002 (all of which are manufactured by Wako Pure Chemical Industries, Ltd.), PIONIN D-6112, D-6112-W, and D-6315 (all of which are manufactured by Takemoto Oil&Fat Co., Ltd.), and OLFINE E1010, SURFYNOL 104, 400, and 440 (all of which are manufactured by Nissin Chemical Co., Ltd.).

Examples of the cationic surfactant include an organosiloxane polymer KP341 (manufactured by Shin-Etsu Chemical Co., Ltd.), a (meth)acrylic acid (co)polymer POLYFLOW No. 75, No. 90, or No. 95 (manufactured by Kyoeisha Chemical Co., Ltd.), and W001 (manufactured by Yusho Co., Ltd.).

Examples of the anionic surfactant include W004, W005, and W017 (manufactured by Yusho Co., Ltd.), and SANDET BL (manufactured by Sanyo Chemical Industries Ltd.).

Examples of the silicone surfactant include: TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Corporation); TSF-4440, TSF-4300, TSF-4445, TSF-4460, and TSF-4452 (all of which are manufactured by Momentive Performance Materials Inc.); KP341, KF6001, and KF6002 (all of which are manufactured by Shin-Etsu Chemical Co., Ltd.); and BYK307, BYK323, and BYK330 (all of which are manufactured by BYK-Chemie Japan K.K.).

The content of the surfactant is preferably 0.001 to 30 mass % with respect to the total solid content of the composition. The upper limit is preferably 30 mass %% or lower, more preferably 15 mass % or lower, and still more preferably 1 vol % or lower. The lower limit is preferably 0.005 mass % or higher. As the surfactant, one kind may be used alone, or two or more kinds may be used in combination.

<<Antioxidant>>

(Phenol Antioxidant)

The composition according to the embodiment of the present invention includes a compound (hereinafter, also referred to as “phenol antioxidant”) that includes a phenol structure with a hydrocarbon group having one or more carbon atoms as an antioxidant. Here, the phenol structure with a hydrocarbon group having one or more carbon atoms refers to a structure in which each of a hydroxyl group and a hydrocarbon group having one or more carbon atoms is bonded to a benzene ring.

In the phenol structure with a hydrocarbon group having one or more carbon atoms in the antioxidant, two or more hydroxyl groups may be bonded to one benzene ring. However, a structure in which one hydroxyl group is bonded to one benzene ring is preferable. In addition, the number of hydrocarbon groups having one or more carbon atoms bonded to one benzene ring is preferably 1 to 4, more preferably 1 to 3, and still more preferably 2 or 3. In addition, in the phenol structure with a hydrocarbon group having one or more carbon atoms, it is preferable that a hydroxyl group and a hydrocarbon group having one or more carbon atoms are bonded to a benzene ring to be adjacent to each other.

The number of carbon atoms in the hydrocarbon group is 1 or more, preferably 1 to 30, more preferably 1 to 20, still more preferably 1 to 10, and still more preferably 1 to 5.

The hydrocarbon group is preferably an aliphatic hydrocarbon group and more preferably a saturated aliphatic hydrocarbon group. In addition, the aliphatic hydrocarbon group may be a linear, branched, or cyclic aliphatic hydrocarbon group but is preferably a branched aliphatic hydrocarbon group. Specifically, the hydrocarbon group is preferably a linear, branched, or cyclic alkyl group and more preferably a branched alkyl group. Specific examples of the hydrocarbon group include a methyl group, an ethyl group, a propyl group, an iso-propyl group, a butyl group, an iso-butyl group, and a tert-butyl group. The hydrocarbon group may have a substituent but is preferably unsubstituted. Examples of the substituent include groups described below regarding a substituent T.

In the present invention, the phenol antioxidant may be a compound that includes only one phenol structure with a hydrocarbon group having one or more carbon atoms in one molecule. However, due to the reason that the approach capability of the near infrared absorbing colorant is high, it is preferable that the antioxidant is a compound that includes two or more phenol structures with a hydrocarbon group having one or more carbon atoms in one molecule. The upper limit of phenol structures with a hydrocarbon group having one or more carbon atoms in one molecule is preferably 8 or less and more preferably 6 or less.

In the present invention, the molecular weight of the phenol antioxidant is preferably 100 to 2500, more preferably 300 to 2000, and still more preferably 500 to 1500. According to this aspect, the sublimability (residual rate during film formation) of the phenol antioxidant is excellent, and the transferability of the phenol antioxidant in the film is excellent.

In the present invention, the phenol antioxidant is preferably a compound having a structure represented by the following Formula (A-1) and more preferably a compound having two or more structures represented by Formula (A-1) in one molecule. The upper limit of the structures represented by Formula (A-1) in one molecule is preferably 8 or less and more preferably 6 or less.

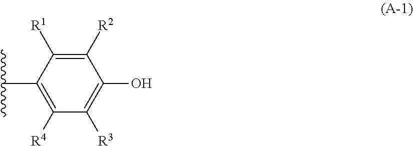

In the formula, R¹ to R⁴ each independently represent a hydrogen atom or a substituent, at least one of R¹, . . . , or R⁴ represents a hydrocarbon group having one or more carbon atoms, and a wave line represents a direct bond to another atom or atomic group in the antioxidant.

Examples of the substituent represented by R¹ to R⁴ in Formula (A-1) include groups described below regarding the substituent T. In Formula (A-1), at least one of R¹, . . . , or R⁴ represents a hydrocarbon group having one or more carbon atoms. A preferable range of the hydrocarbon group is the same as the above-described range. It is preferable that at least one of R² or R³ in Formula (A-1) represents a hydrocarbon group having one or more carbon atoms, it is more preferable that R² and R³ represent a hydrocarbon group having one or more carbon atoms, it is still more preferable that R² and R³ represent a hydrocarbon group having one or more carbon atoms and at least one of R² or R³ represents a branched alkyl group, it is still more preferable that one of R² or R³ represents a branched alkyl group and the other one of R² or R³ represents a linear alkyl group or a branched alkyl group, it is still more preferable that one of R² or R³ represents a branched alkyl group and the other one of R² or R³ represents a linear alkyl group, and it is most preferable that one of R² or R³ represents a tert-butyl group and the other one of R² or R³ represents a methyl group. With the structure in which one of R² or R³ represents a branched alkyl group and the other one of R² or R³ represents a linear alkyl group or a branched alkyl group, an effect of improving the heat stability of the film or suppressing the aggregation of the near infrared absorbing colorant can be expected. In addition, with the structure in which one of R² or R³ represents a branched alkyl group and the other one of R² or R³ represents a linear alkyl group, an effect of further improving the heat stability of the film or more effectively suppressing the aggregation of the near infrared absorbing colorant can be expected.

Examples of the substituent T include the following groups.

(Substituent T)

The substituent T includes an alkyl group (preferably an alkyl group having 1 to 30 carbon atoms), an alkenyl group (preferably an alkenyl group having 2 to 30 carbon atoms), an alkynyl group (preferably an alkynyl group having 2 to 30 carbon atoms), an aryl group (preferably an aryl group having 6 to 30 carbon atoms), an amino group (preferably an amino group having 0 to 30 carbon atoms), an alkoxy group (preferably an alkoxy group having 1 to 30 carbon atoms), an aryloxy group (preferably an aryloxy group having 6 to 30 carbon atoms), a heteroaryloxy group, an acyl group (preferably having an acyl group 1 to 30 carbon atoms), an alkoxycarbonyl group (preferably an alkoxycarbonyl group having 2 to 30 carbon atoms), an aryloxycarbonyl group (preferably an aryloxycarbonyl group having 7 to 30 carbon atoms), an acyloxy group (preferably an acyloxy group having 2 to 30 carbon atoms), an acylamino group (preferably an acylamino group having 2 to 30 carbon atoms), an alkoxycarbonylamino group (preferably an alkoxycarbonylamino group having 2 to 30 carbon atoms), an aryloxycarbonylamino group (preferably an aryloxycarbonylamino group having 7 to 30 carbon atoms), a sulfamoyl group (preferably a sulfamoyl group having 0 to 30 carbon atoms), a carbamoyl group (preferably a carbamoyl group having 1 to 30 carbon atoms), an alkylthio group (preferably an alkylthio group having 1 to 30 carbon atoms), an arylthio group (preferably an arylthio group having 6 to 30 carbon atoms), a heteroarylthio group (preferably having 1 to 30 carbon atoms), an alkylsulfonyl group (preferably having 1 to 30 carbon atoms), an arylsulfonyl group (preferably having 6 to 30 carbon atoms), a heteroarylsulfonyl group (preferably having 1 to 30 carbon atoms), an alkylsulfinyl group (preferably having 1 to 30 carbon atoms), an arylsulfinyl group (preferably having 6 to 30 carbon atoms), a heteroarylsulfinyl group (preferably having 1 to 30 carbon atoms), a ureido group (preferably having 1 to 30 carbon atoms), a phosphoric amide group (preferably having 1 to 30 carbon atoms), a hydroxy group, a mercapto group, a halogen atom, a cyano group, an alkylsulfino group, an arylsulfino group, a hydrazino group, an imino group, a heteroaryl group (preferably having 1 to 30 carbon atoms), and tetrahydrofuranyl group. In a case where the above-described groups can be further substituted, the groups may further have a substituent. Examples of the substituent which may be further included include the groups described regarding the substituent T.

In the present invention, it is preferable that the phenol antioxidant is a compound represented by Formula (A-2).

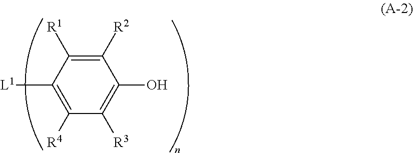

In the formula, R¹ to R⁴ each independently represent a hydrogen atom or a substituent, at least one of R¹, . . . , or R⁴ represents a hydrocarbon group having one or more carbon atoms, L¹ represents an n-valent group, and n represents an integer of 1 or more.

Examples of the substituent represented by R¹ to R⁴ in Formula (A-2) include groups described below regarding the substituent T. In Formula (A-2), at least one of R¹, . . . , or R⁴ represents a hydrocarbon group having one or more carbon atoms. A preferable range of the hydrocarbon group is the same as the above-described range. It is preferable that at least one of R² or R³ in Formula (A-2) represents a hydrocarbon group having one or more carbon atoms, it is more preferable that R² and R³ represent a hydrocarbon group having one or more carbon atoms, it is still more preferable that R² and R³ represent a hydrocarbon group having one or more carbon atoms and at least one of R² or R³ represents a branched alkyl group, it is still more preferable that one of R² or R³ represents a branched alkyl group and the other one of R² or R³ represents a linear alkyl group or a branched alkyl group, it is still more preferable that one of R² or R³ represents a branched alkyl group and the other one of R² or R³ represents a linear alkyl group, and it is most preferable that one of R² or R³ represents a tert-butyl group and the other one of R² or R³ represents a methyl group.

Examples of the n-valent group represented by L¹ include a hydrocarbon group, a heterocyclic group, —O—, —S—, —NR—, —CO—, —COO—, —OCO—, —SO₂—, a group including a combination of the above-described groups. R represents a hydrogen atom, an alkyl group, or an aryl group.

The hydrocarbon group may be an aliphatic hydrocarbon group or an aromatic hydrocarbon group. In addition, the aliphatic hydrocarbon group may be cyclic or acyclic. In addition, the aliphatic hydrocarbon group may be a saturated aliphatic hydrocarbon group or an unsaturated aliphatic hydrocarbon group. The hydrocarbon group may have a substituent or may be unsubstituted. Examples of the substituent include the above-described substituent T. In addition, the cyclic aliphatic hydrocarbon group and the aromatic hydrocarbon group may be a monocycle or a fused ring.

The heterocyclic group may be a monocycle or a fused ring. Examples of the heteroatom constituting the heterocyclic group include a nitrogen atom, an oxygen atom, and a sulfur atom.

Specific examples of the n-valent group include a group (in which a ring structure may be formed) including one of the following structural unit or a combination of two or more of the following structural units. R represents a hydrogen atom, an alkyl group, or an aryl group. In the following formulae, * represents a direct bond.

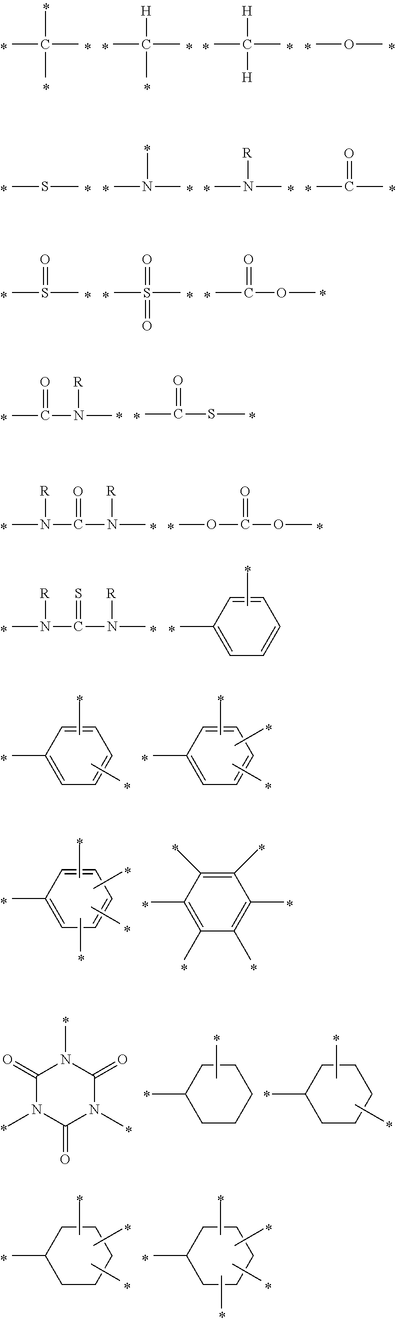

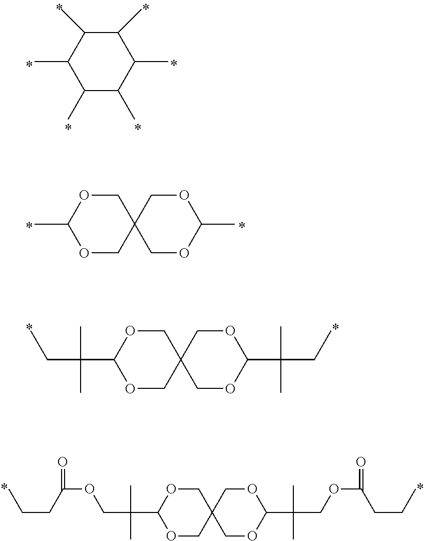

In Formula (A-2), n represents an integer of 1 or more, preferably an integer of 1 to 8, more preferably an integer of 2 to 6, and still more preferably an integer of 2 to 4.

Specific examples of the phenol antioxidant include the following compounds. In addition, as the phenol antioxidant, a commercially available product may also be used. Representative examples which are available as the commercially available product include ADEKA STAB AO-20, 30, 40, 50, 60, 70, and 80 (all of which are manufactured by Adeka Corporation).

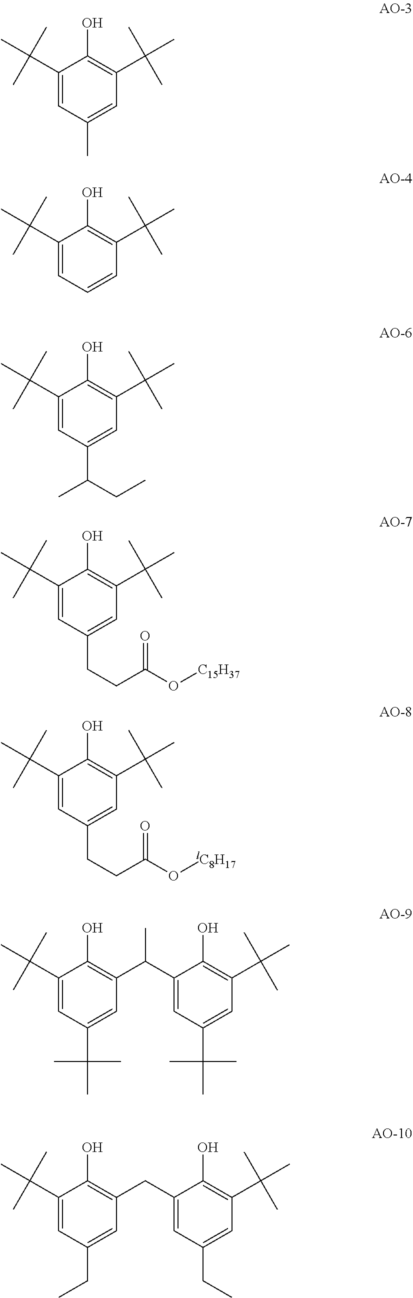

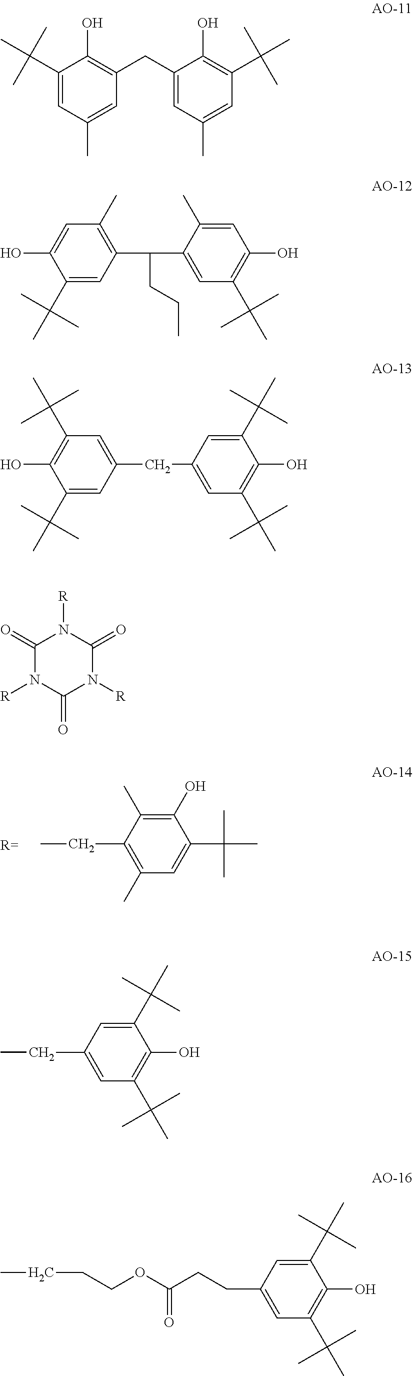

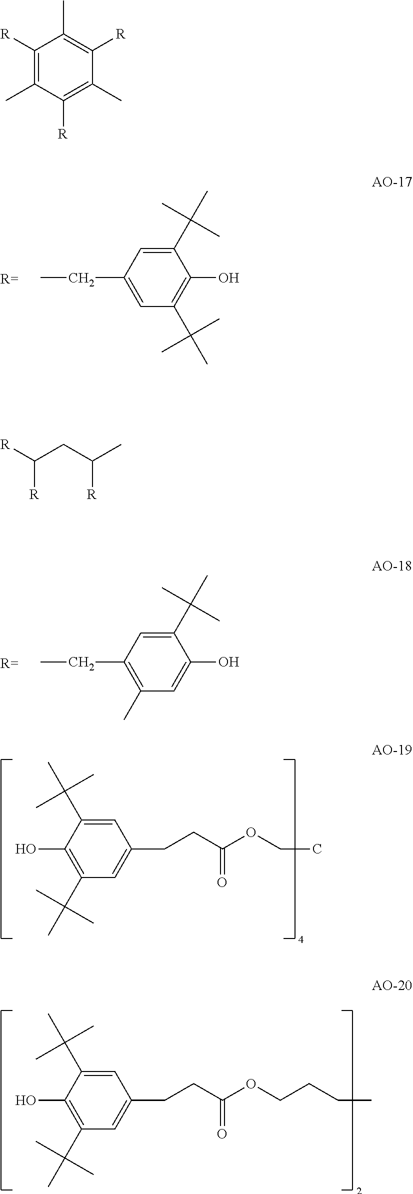

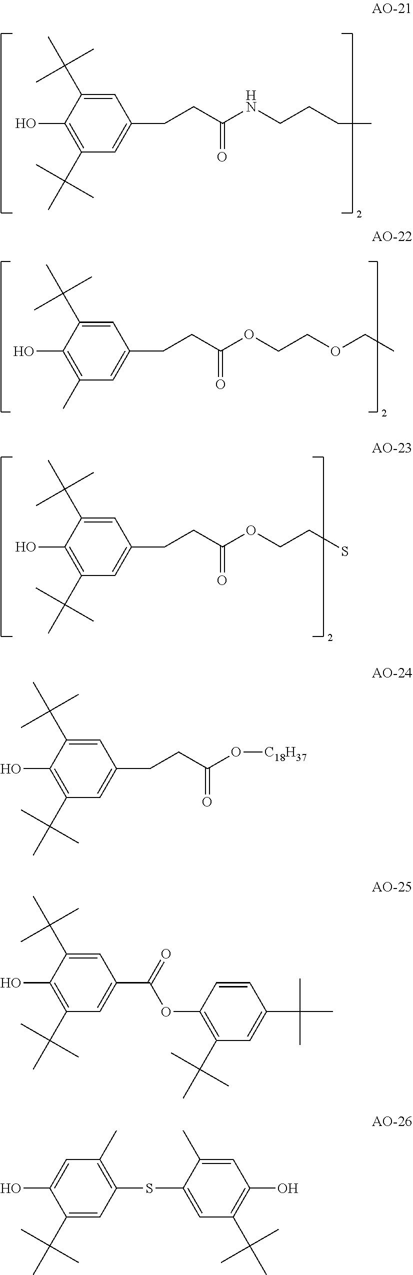

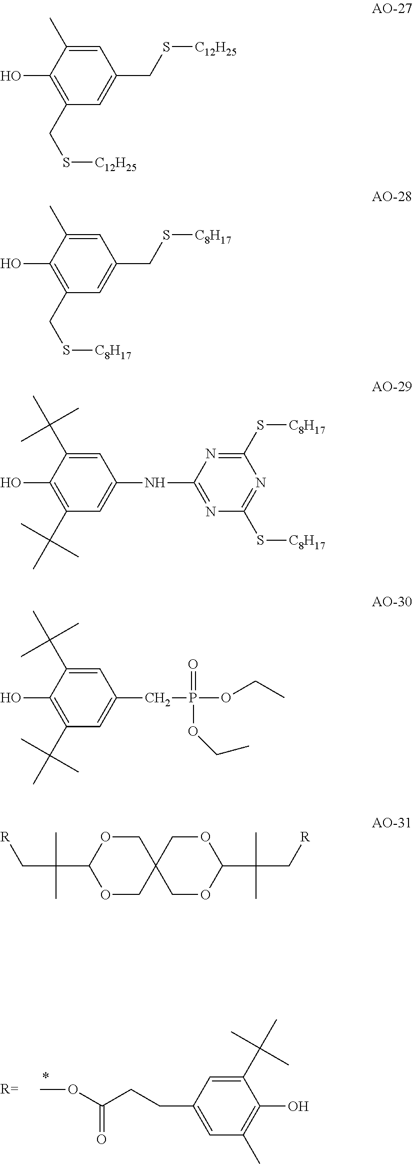

In the present invention, as the antioxidant, the phenol antioxidant and an antioxidant other than the phenol antioxidant (also referred to as “other antioxidant”) may be used in combination. Examples of the other antioxidant include an N-oxide compound, a piperidine-1-oxyl free-radical compound, a piperidine 1-oxyl free-radical compound, a pyrrolidine 1-oxyl free-radical compound, a N-nitrosophenylhydroxylamine compound, a diazonium compound, a phosphorus compound, and a sulfur compound. Specific examples of these compounds include compounds described in paragraphs “0034” to “0041” of JP2014-032380A, the content of which is incorporated herein by reference. Representative examples which are available as a commercially available product of the phosphorus compound include ADEKA STAB 2112, PEP-8, PEP-24G, PEP-36, PEP-45, and HP-10 (manufactured by Adeka Corporation), and IRGAFOS 38, 168 and P-EPQ (manufactured by BASF SE). Representative examples which are available as a commercially available product of the sulfur compound include SUMILIZER MB (manufactured by Sumitomo Chemical Co., Ltd.) and ADEKA STAB AO-412S (manufactured by Adeka Corporation).

In the composition according to the embodiment of the present invention, the content of the antioxidant is preferably 0.01 to 20 mass % with respect to the total solid content of the composition. The upper limit is preferably 15 mass %% or lower, more preferably 10 mass % or lower, and still more preferably 5 mass % or lower. The lower limit is preferably 0.05 mass % or higher. As the antioxidant, one kind may be used alone, or two or more kinds may be used in combination.

In addition, in the composition according to the embodiment of the present invention, the content of the phenol antioxidant is preferably 0.01 to 20 mass % with respect to the total solid content of the composition. The upper limit is preferably 15 mass %% or lower, more preferably 10 mass % or lower, and still more preferably 5 mass % or lower. The lower limit is preferably 0.05 mass % or higher. As the antioxidant, one kind may be used alone, or two or more kinds may be used in combination.

In the composition according to the embodiment of the present invention, the content of the phenol antioxidant is preferably 0.05 mass % or higher, more preferably 0.1 mass % or higher, and still more preferably 0.5 mass % or higher with respect to the total amount of the antioxidants.

<<Curable Compound>>

It is preferable that the composition according to the embodiment of the present invention includes a curable compound. Examples of the curable compound include a crosslinking compound and a resin. The resin may be a non-crosslinking resin (resin not having a crosslinking group) or a crosslinking resin (resin having a crosslinking group). Examples of the crosslinking group include a group having an ethylenically unsaturated bond, an epoxy group, a methylol group, and an alkoxymethyl group. Examples of the group having an ethylenically unsaturated bond include a vinyl group, a (meth)allyl group, and a (meth)acryloyl group. The crosslinking resin (resin having a crosslinking group) may be a crosslinking compound.

In the composition according to the embodiment of the present invention, the content of the curable compound is preferably 0.1 to 80 mass % with respect to the total solid content of the composition according to the embodiment of the present invention. The lower limit is more preferably 0.5 mass % or higher, still more preferably 1 mass % or higher, and still more preferably 5 mass % or higher. The upper limit is more preferably 75 mass % or lower and still more preferably 70 mass % or lower. As the curable compound, one kind may be used alone, or two or more kinds may be used. In a case where two or more curable compounds are used in combination, it is preferable that the total content of the two or more curable compounds is in the above-described range.

(Crosslinking Compound)

Examples of the crosslinking compound include a compound which has a group having an ethylenically unsaturated bond, a compound having an epoxy group, a compound having a methylol group, and a compound having an alkoxymethyl group. The crosslinking compound may be a monomer or a resin. The monomer type compound that has a group having an ethylenically unsaturated bond can be preferably used as a radically polymerizable compound. In addition, the compound having an epoxy group, the compound having a methylol group, and the compound having an alkoxymethyl group can be preferably used as a cationically polymerizable compound.

The molecular weight of the monomer type crosslinking compound is preferably lower than 2000, more preferably 100 or higher and lower than 2000, and still more preferably 200 or higher and lower than 2000. The upper limit is, for example, preferably 1500 or lower. The weight-average molecular weight (Mw) of the resin type crosslinking compound is preferably 2000 to 2000000. The upper limit is 1000000 or lower and more preferably 500000 or lower. The lower limit is 3000 or higher and more preferably 5000 or higher.

Examples of the resin type crosslinking compound include an epoxy resin and a resin which includes a repeating unit having a crosslinking group. Examples of the repeating unit having a crosslinking group include the following (A2-1) to (A2-4).

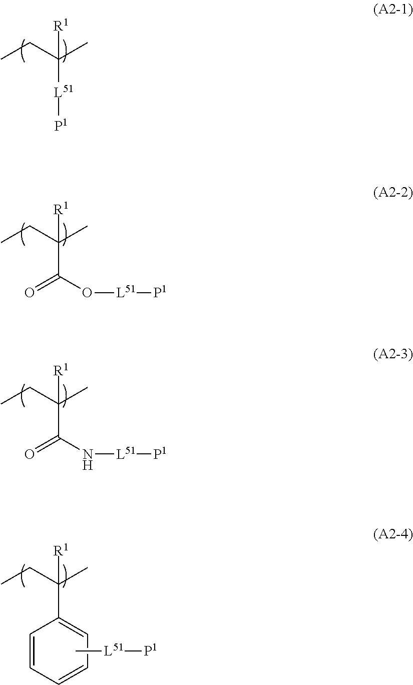

R¹ represents a hydrogen atom or an alkyl group. The number of carbon atoms in the alkyl group is preferably 1 to 5, more preferably 1 to 3, and still more preferably 1. It is preferable that R¹ represents a hydrogen atom or a methyl group.

L⁵¹ represents a single bond or a divalent linking group. Examples of the divalent linking group include an alkylene group, an arylene group, —O—, —S—, —CO—, —COO—, —OCO—, —SO₂—, —NR¹⁰— (R¹⁰ represents a hydrogen atom or an alkyl group and preferably a hydrogen atom), and a group including a combination thereof. Among these, a group including a combination —O— and at least one of an alkylene group, an arylene group, or an alkylene group is preferable. The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic. The number of carbon atoms in the arylene group is preferably 6 to 18, more preferably 6 to 14, and still more preferably 6 to 10.

P¹ represents a crosslinking group. Examples of the crosslinking group include a group having an ethylenically unsaturated bond, an epoxy group, a methylol group, and an alkoxymethyl group.

The compound which has a group having an ethylenically unsaturated bond is preferably a (meth)acrylate compound having 3 to 15 functional groups and more preferably a (meth)acrylate compound having 3 to 6 functional groups. Examples of the compound which includes a group having an ethylenically unsaturated bond can be found in paragraphs “0033” and “0034” of JP2013-253224A, the content of which is incorporated herein by reference. As specific examples, ethyleneoxy-modified pentaerythritol tetraacrylate (as a commercially available product, NK ESTER ATM-35E manufactured by Shin-Nakamura Chemical Co., Ltd.), dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., A-DPH-12E, manufactured by Shin-Nakamura Chemical Co., Ltd.), or a structure in which the (meth)acryloyl group is bonded through an ethylene glycol or a propylene glycol residue is preferable. In addition, oligomers of the above-described examples can be used. In addition, the details can be found in paragraphs “0034” to “0038” of JP2013-253224A and paragraph “0477” of JP2012-208494A (corresponding to paragraph “0585” of US2012/0235099A), the contents of which are incorporated herein by reference. As specific examples of the compound which has a group having an ethylenically unsaturated bond, diglycerin ethylene oxide (EO)-modified (meth)acrylate (as a commercially available product, M-460 manufactured by Toagosei Co., Ltd.), pentaerythritol tetraacrylate (A-TMMT manufactured by Shin-Nakamura Chemical Co., Ltd.), or 1,6-hexanediol diacrylate (KAYARAD HDDA manufactured by Nippon Kayaku Co., Ltd.) can also be used. In addition, oligomers of the above-described examples can be used. For examples, RP-1040 (manufactured by Nippon Kayaku Co., Ltd.) is used.

The compound which includes a group having an ethylenically unsaturated bond may further have an acid group such as a carboxyl group, a sulfo group, or a phosphate group. Examples of a commercially available product include ARONIX series (for example, M-305, M-510, or M-520, manufactured by Toagosei Co., Ltd.).

In addition, a compound having a caprolactone structure is also preferable as the compound which includes a group having an ethylenically unsaturated bond. Examples of the compound having a caprolactone structure can be found in paragraphs “0042” to “0045” of JP2013-253224A, the content of which is incorporated herein by reference. Examples of a commercially available product of the compound having a caprolactone structure include SR-494 (manufactured by Sartomer) which is a tetrafunctional acrylate having four ethyleneoxy chains, DPCA-60 (manufactured by Nippon Kayaku Co., Ltd.) which is a hexafunctional acrylate having six pentyleneoxy chains, and TPA-330 (manufactured by Nippon Kayaku Co., Ltd.) which is a trifunctional acrylate having three isobutyleneoxy chains.

In a case where the composition according to the embodiment of the present invention includes the compound which includes a group having an ethylenically unsaturated bond, the content of the compound which includes a group having an ethylenically unsaturated bond is preferably 0.1 mass % or higher, more preferably 0.5 mass % or higher, still more preferably 1 mass % or higher, and still more preferably 5 mass % or higher with respect to the total solid content of the composition. The upper limit is preferably 80 mass % or lower, more preferably 75 mass % or lower, and still more preferably 70 mass % or lower.

Examples of the compound having an epoxy group (hereinafter, also referred to as “epoxy compound”) include a monofunctional or polyfunctional glycidyl ether compound, and a polyfunctional aliphatic glycidyl ether compound. In addition, as the epoxy compound, a compound having an alicyclic epoxy group can also be used.

Examples of the epoxy compound include a compound having one or more epoxy groups in one molecule. The number of epoxy groups in one molecule is preferably 1 to 100. The upper limit is, for example, 10 or less or 5 or less. The lower limit is preferably 2 or more.

The epoxy compound may be a low molecular weight compound (for example, molecular weight: lower than 1000) or a high molecular weight compound (macromolecule; for example, molecular weight: 1000 or higher, and in the case of a polymer, weight-average molecular weight: 1000 or higher). The weight-average molecular weight of the epoxy compound is preferably 2000 to 100000. The upper limit of the weight-average molecular weight is preferably 10000 or lower, more preferably 5000 or lower, and still more preferably 3000 or lower.

Examples of a commercially available product of the epoxy compound include EHPE 3150 (manufactured by Daicel Corporation), EPICLON N-695 (manufactured by DIC Corporation), ADEKA GLYCILOL ED-505 (manufactured by Adeka Corporation, an epoxy group-containing monomer), and MARPROOF G-0150M, G-0105SA, G-0130SP, G-0250SP, G-1005S, G-1005SA, G-1010S, G-2050M, G-01100, or G-01758 (manufactured by NOF Corporation, an epoxy group-containing polymer). In addition, as the epoxy compound, compounds described in paragraphs “0034” to “0036” of JP2013-011869A, paragraphs “0147” to “0156” of JP2014-043556A, and paragraphs “0085” to “0092” of JP2014-089408A can also be used. The contents of which are incorporated herein by reference.

In a case where the composition according to the embodiment of the present invention includes the epoxy compound, the content of the epoxy compound is preferably 0.1 mass % or higher, more preferably 0.5 mass % or higher, still more preferably 1 mass % or higher, and still more preferably 5 mass % or higher with respect to the total solid content of the composition. The upper limit is preferably 80 mass % or lower, more preferably 75 mass % or lower, and still more preferably 70 mass % or lower.

In addition, in a case where the composition according to the embodiment of the present invention includes the radically polymerizable compound and the epoxy compound, a mass ratio radically polymerizable compound:epoxy compound is preferably 100:1 to 100:400 and more preferably 100:1 to 100:100.

Examples of the compound having a methylol group (hereinafter, also referred to as “methylol compound”) include a compound in which a methylol group is bonded to a nitrogen atom or a carbon atom which forms an aromatic ring. In addition, examples of the compound having an alkoxymethyl group (hereinafter, also referred to as “alkoxymethyl compound”) include a compound in which an alkoxymethyl group is bonded to a nitrogen atom or a carbon atom which forms an aromatic ring. As the compound in which an alkoxymethyl group or a methylol group is bonded to a nitrogen atom, for example, alkoxy methylated melamine, methylolated melamine, alkoxy methylated benzoguanamine, methylolated benzoguanamine, alkoxy methylated glycoluril, methylolated glycoluril, alkoxy methylated urea, or methylolated urea is preferable. In addition, the details can be found in paragraphs “0134” to “0147” of JP2004-295116A or paragraphs “0095” to “0126” of JP2014-089408A, the content of which is incorporated herein by reference.

Preferable examples of a commercially available product of the methylol compound and the alkoxymethyl compound which can be used include: CYMEL 300, 301, 303, 370, 325, 327, 701, 266, 267, 238, 1141, 272, 202, 1156, 1158, 1123, 1170, 1174, UFR65, and 300 (all of which are manufactured by Mitsubishi Cyanamid); and NIKALAC MX-750, -032, -706, -708, -40, -31, -270, -280, -290, -750LM, NIKALAC MS-11, NIKALAC MW-30HM, -100LM, and -390 (all of which are manufactured by Sanwa Chemical Co., Ltd.); and RESITOP C-357 (manufactured by Gunei Chemical Industry Co., Ltd.).

In a case where the composition according to the embodiment of the present invention includes the methylol compound, the content of the methylol compound is preferably 0.1 mass % or higher, more preferably 0.5 mass % or higher, still more preferably 1 mass % or higher, and still more preferably 5 mass % or higher with respect to the total solid content of the composition. The upper limit is preferably 80 mass % or lower, more preferably 75 mass % or lower, and still more preferably 70 mass % or lower.

In a case where the composition according to the embodiment of the present invention includes the alkoxymethyl compound, the content of the alkoxymethyl compound is preferably 0.1 mass % or higher, more preferably 0.5 mass % or higher, still more preferably 1 mass % or higher, and still more preferably 5 mass % or higher with respect to the total solid content of the composition. The upper limit is preferably 80 mass % or lower, more preferably 75 mass % or lower, and still more preferably 70 mass % or lower.

(Resin)

The composition according to the embodiment of the present invention may include a resin as the curable compound. It is preferable that the curable compound includes at least a resin. The resin can also be used as a dispersant. The resin which is used to disperse the pigments and the like will also be referred to as a dispersant. However, the above-described uses of the resin are merely exemplary, and the resin can be used for purposes other than the uses. The resin having a crosslinking group also corresponds to the crosslinking compound.

The weight-average molecular weight (Mw) of the resin is preferably 2000 to 2000000. The upper limit is preferably 1000000 or lower and more preferably 500000 or lower. The lower limit is preferably 3000 or higher and more preferably 5000 or higher.

Examples of the resin include a (meth)acrylic resin, an epoxy resin, an enethiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide imide resin, a polyolefin resin, a cyclic olefin resin, a polyester resin, and a styrene resin. Among these resins, one kind may be used alone, or a mixture of two or more kinds may be used. Examples of the epoxy resin include the polymer type compounds among the compounds described above as the examples of the epoxy compound regarding the crosslinking compound. In addition, as the resin, a resin described in Examples of WO2016/088645A or a resin described in Examples of JP2016-146619A can also be used.

The resin used in the present invention may have an acid group. Examples of the acid group include a carboxyl group, a phosphate group, a sulfo group, and a phenolic hydroxyl group. Among these acid groups, one kind may be used alone, or two or more kinds may be used in combination. The resin having an acid group can be preferably used as an alkali-soluble resin. By the composition according to the embodiment of the present invention including the alkali-soluble resin, a desired pattern can be formed by alkali development.

As the resin having an acid group, a polymer having a carboxyl group at a side chain is preferable. Specific examples of the resin include an alkali-soluble phenol resin such as a methacrylic acid copolymer, an acrylic acid copolymer, an itaconic acid copolymer, a crotonic acid copolymer, a maleic acid copolymer, a partially esterified maleic acid copolymer, or a novolac resin, an acidic cellulose derivative having a carboxyl group at a side chain thereof, and a resin obtained by adding an acid anhydride to a polymer having a hydroxyl group. In particular, a copolymer of (meth)acrylic acid and another monomer which is copolymerizable with the (meth)acrylic acid is preferable as the alkali-soluble resin. Examples of the monomer which is copolymerizable with the (meth)acrylic acid include an alkyl (meth)acrylate, an aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyl toluene, glycidyl methacrylate, acrylonitrile, vinyl acetate, N-vinylpyrrolidone, tetrahydrofurfuryl methacrylate, a polystyrene macromonomer, and a polymethyl methacrylate macromonomer. Examples of other monomers include a N-position-substituted maleimide monomer described in JP1998-300922A (JP-H10-300922A) such as N-phenylmaleimide or N-cyclohexylmaleimide. Among these monomers which are copolymerizable with the (meth)acrylic acid, one kind may be used alone, or two or more kinds may be used in combination. Specific examples of the resin having an acid group include resins having the following structures.

The resin having an acid group may further include a repeating unit having a crosslinking group. In a case where the resin having an acid group further includes the repeating unit having a crosslinking group, the content of the repeating unit having a crosslinking group is preferably 10 to 90 mol %, more preferably 20 to 90 mol %, and still more preferably 20 to 85 mol % with respect to all the repeating units. In addition, the content of the repeating unit having an acid group is preferably 1 to 50 mol %, more preferably 5 to 40 mol %, and still more preferably 5 to 30 mol % with respect to all the repeating units.

As the resin having an acid group, a copolymer including benzyl (meth)acrylate and (meth)acrylic acid; a copolymer including benzyl (meth)acrylate, (meth)acrylic acid, and 2-hydroxyethyl (meth)acrylate; or a multi-component copolymer including benzyl (meth)acrylate, (meth)acrylic acid, and another monomer can be preferably used. In addition, copolymers described in JP1995-140654A (JP-H7-140654A) obtained by copolymerization of 2-hydroxyethyl (meth)acrylate can be preferably used, and examples thereof include: a copolymer including 2-hydroxypropyl (meth)acrylate, a polystyrene macromonomer, benzyl methacrylate, and methacrylic acid; a copolymer including 2-hydroxy-3-phenoxypropyl acrylate, a polymethyl methacrylate macromonomer, benzyl methacrylate, and methacrylic acid; a copolymer including 2-hydroxyethyl methacrylate, a polystyrene macromonomer, methyl methacrylate, and methacrylic acid; or a copolymer including 2-hydroxyethyl methacrylate, a polystyrene macromonomer, benzyl methacrylate, and methacrylic acid.

As the resin having an acid group, a polymer obtained by polymerization of monomer components including a compound represented by the following Formula (ED1) and/or a compound represented by the following Formula (ED2) (hereinafter, these compounds will also be referred to as “ether dimer”) is also preferable.

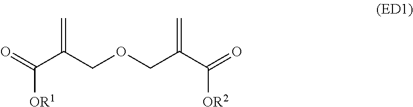

In Formula (ED1), R¹ and R² each independently represent a hydrogen atom or a hydrocarbon group having 1 to 25 carbon atoms which may have a substituent.

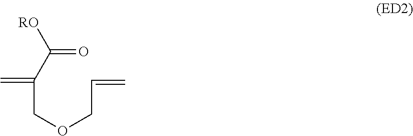

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph “0317” of JP2013-029760A, the content of which is incorporated herein by reference. Among these ether dimers, one kind may be used alone, or two or more kinds may be used in combination.

The resin having an acid group may include a repeating unit which is derived from a compound represented by the following Formula (X).

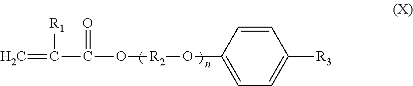

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring. n represents an integer of 1 to 15.

The details of the resin having an acid group can be found in paragraphs “0558” to “0571” of JP2012-208494A (paragraphs “0685” to “0700” of corresponding US2012/0235099A) and paragraphs “0076” to “0099” of JP2012-198408A, the contents of which are incorporated herein by reference.

The acid value of the resin having an acid group is preferably 30 to 200 mgKOH/g. The lower limit is preferably 50 mgKOH/g or higher and more preferably 70 mgKOH/g or higher. The upper limit is preferably 150 mgKOH/g or lower and more preferably 120 mgKOH/g or lower.

Examples of the resin having an acid group include resins having the following structures. In the following structural formulae, Me represents a methyl group.

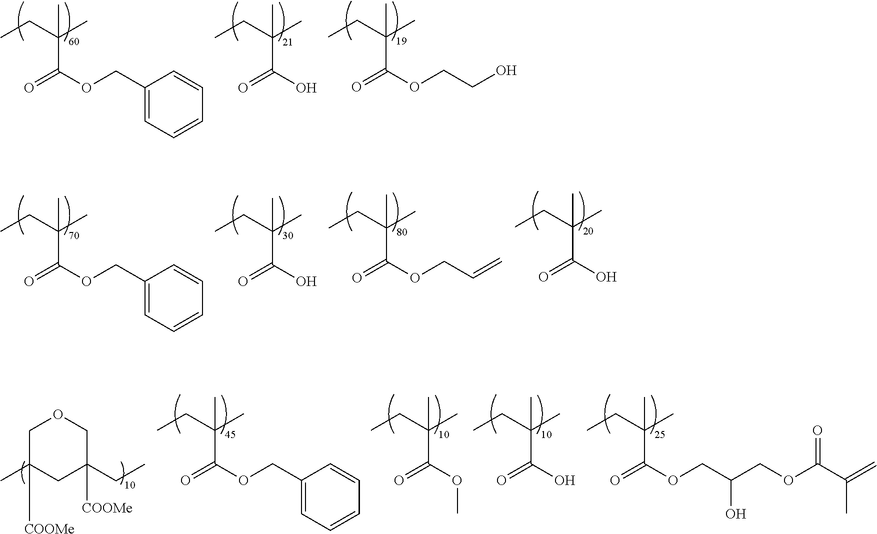

In the composition according to the embodiment of the present invention, as the resin, a resin having a repeating unit represented by any one of Formulae (A3-1) to (A3-7) is also preferably used.

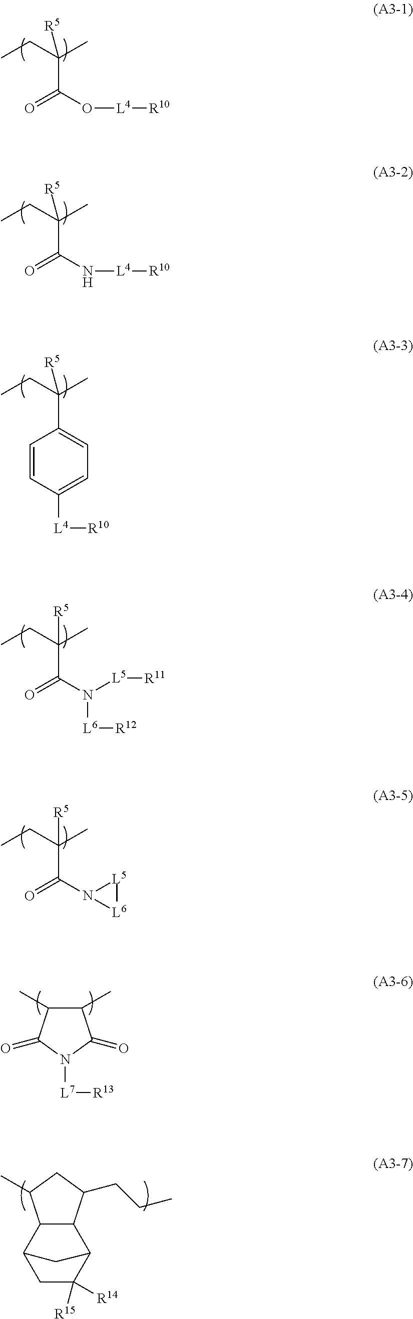

In the formulae, R⁵ represents a hydrogen atom or an alkyl group, L⁴ to L⁷ each independently represent a single bond or a divalent linking group, and R¹⁰ to R¹³ each independently represent an alkyl group or an aryl group. R¹⁴ and R¹⁵ each independently represent a hydrogen atom or a substituent.

R⁵ represents a hydrogen atom or an alkyl group. The number of carbon atoms in the alkyl group is preferably 1 to 5, more preferably 1 to 3, and still more preferably 1. It is preferable that R⁵ represents a hydrogen atom or a methyl group.

L⁴ to L⁷ each independently represent a single bond or a divalent linking group. Examples of the divalent linking group include an alkylene group, an arylene group, —O—, —S—, —CO—, —COO—, —OCO—, —SO₂—, —NR¹⁰— (R¹⁰ represents a hydrogen atom or an alkyl group and preferably a hydrogen atom), and a group including a combination thereof. Among these, a group including a combination —O— and at least one of an alkylene group, an arylene group, or an alkylene group is preferable. The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic. The number of carbon atoms in the arylene group is preferably 6 to 18, more preferably 6 to 14, and still more preferably 6 to 10.

The alkyl group represented by R¹⁰ may be linear, branched, or cyclic and is preferably cyclic. The alkyl group may have a substituent or may be unsubstituted. The number of carbon atoms in the alkyl group is preferably 1 to 30, more preferably 1 to 20, and still more preferably 1 to 10. The number of carbon atoms in the aryl group represented by R¹⁰ is preferably 6 to 18, more preferably 6 to 12, and still more preferably 6. It is preferable that R¹⁰ represents a cyclic alkyl group or an aryl group.

The alkyl group represented by R¹¹ and R¹² may be linear, branched, or cyclic and is preferably linear or branched. The alkyl group may have a substituent or may be unsubstituted. The number of carbon atoms in the alkyl group is preferably 1 to 12, more preferably 1 to 6, and still more preferably 1 to 4. The number of carbon atoms in the aryl group represented by R¹¹ and R¹² is preferably 6 to 18, more preferably 6 to 12, and still more preferably 6. It is preferable that R¹¹ and R¹² represent a linear or branched alkyl group.

The alkyl group represented by R¹³ may be linear, branched, or cyclic and is preferably linear or branched. The alkyl group may have a substituent or may be unsubstituted. The number of carbon atoms in the alkyl group is preferably 1 to 12, more preferably 1 to 6, and still more preferably 1 to 4. The number of carbon atoms in the aryl group represented by R¹³ is preferably 6 to 18, more preferably 6 to 12, and still more preferably 6. It is preferable that R¹³ represents a linear or branched alkyl group or an aryl group.

Examples of the substituent represented by R¹⁴ and R¹⁵ include a halogen atom, a cyano group, a nitro group, an alkyl group, an alkenyl group, an alkynyl group, an aryl group, a heteroaryl group, an aralkyl group, an alkoxy group, an aryloxy group, a heteroaryloxy group, an alkylthio group, an arylthio group, a heteroarylthio group, —NR^{a1}R^{a2}, —COR^{a3}, —COOR^{a4}, —OCOR^{a5}, —NHCOR^{a6}, —CONR^{a7}R^{a8}, —NHCONR^{a9}R^{a10}, —NHCOOR^{a11}, —SO₂Ra¹², —SO₂OR^{a13}, —NHSO₂R^{a14}, and —SO₂NR^{a15}Ra¹⁶. R^{a1} to R^{a16} each independently represent a hydrogen atom, an alkyl group, an alkenyl group, an alkynyl group, an aryl group, or a heteroaryl group. In particular, it is preferable that at least one of R¹⁴ or R¹⁵ represents a cyano group or —COOR^{a4}. It is preferable that R^{a4} represents a hydrogen atom, an alkyl group, or an aryl group.

Examples of a commercially available product of the resin having a repeating unit represented by Formula (A3-7) include ARTON F4520 (manufactured by JSR Corporation). In addition, the details of the resin having a repeating unit represented by Formula (A3-7) can be found in paragraphs “0053” to “0075” and “0127” to “0130” of JP2011-100084A, the content of which is incorporated herein by reference.

The composition according to the embodiment of the present invention may include a dispersant as a resin. In particular, in a case where a pigment is used, it is preferable that the composition includes a dispersant. Examples of the dispersant include an acidic dispersant (acidic resin) and a basic dispersant (basic resin). It is preferable that the dispersant includes at least an acidic dispersant, and it is more preferable that the dispersant consists of only an acidic dispersant. By the dispersant including at least the acidic dispersant, the pigment dispersibility is improved, and excellent developability can be obtained. Therefore, a pattern can be suitably formed using a photolithography method. In a case where the dispersant consists of only an acidic dispersant, for example, the content of the acidic dispersant is preferably 99 mass % or higher and more preferably 99.9 mass % or higher with respect to the total mass of the dispersant.

Here, the acidic dispersant (acidic resin) refers to a resin in which the amount of an acid group is more than the amount of a basic group. In a case where the sum of the amount of an acid group and the amount of a basic group in the acidic dispersant (acidic resin) is represented by 100 mol %, the amount of the acid group in the resin is preferably 70 mol % or higher and more preferably substantially 100 mol %. The acid group in the acidic dispersant (acidic resin) is preferably a carboxyl group. An acid value of the acidic dispersant (acidic resin) is preferably 40 to 105 mgKOH/g, more preferably 50 to 105 mgKOH/g, and still more preferably 60 to 105 mgKOH/g.

In addition, the basic dispersant (basic resin) refers to a resin in which the amount of a basic group is more than the amount of an acid group. In a case where the sum of the amount of an acid group and the amount of a basic group in the basic dispersant (basic resin) is represented by 100 mol %, the amount of the basic group in the resin is preferably higher than 50 mol %. The basic group in the basic dispersant is preferably amine.

It is preferable that the resin A used as the dispersant further includes a repeating unit having an acid group. By the resin, which is used as the dispersant, including the repeating unit having an acid group, in a case where a pattern is formed using a photolithography method, the amount of residues formed in an underlayer of a pixel can be reduced.

It is preferable that the resin used as the dispersant is a graft copolymer. Since the graft copolymer has affinity to the solvent due to the graft chain, the pigment dispersibility and the dispersion stability over time are excellent. In addition, the composition has affinity to the curable compound or the like due to the presence of the graft chain. Therefore, formation of residues during alkali development can be suppressed. As the graft copolymer, a graft copolymer including a repeating unit represented by any one of the following Formulae (111) to (114) is preferably used.

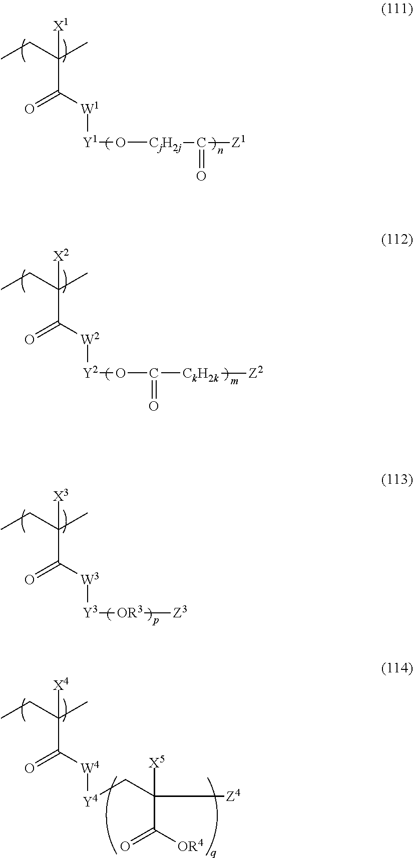

In Formulae (111) to (114), W¹, W², W³, and W⁴ each independently represent an oxygen atom or NH, X¹, X², X³, X⁴, and X⁵ each independently represent a hydrogen atom or a monovalent group, Y¹, Y², Y³, and Y⁴ each independently represent a divalent linking group, Z¹, Z², Z³, and Z⁴ each independently represent a monovalent group, R³ represents an alkylene group, R⁴ represents a hydrogen atom or a monovalent group, n, m, p, and q each independently represent an integer of 1 to 500, and j and k each independently represent an integer of 2 to 8. In Formula (113), in a case where p represents 2 to 500, a plurality of R³'s may be the same as or different from each other. In Formula (114), in a case where q represents 2 to 500, a plurality of X⁵'s and a plurality of R⁴'s may be the same as or different from each other.

The details of the graft copolymer can be found in the description of paragraphs “0025” to “0094” of JP2012-255128A, the content of which is incorporated herein by reference. In addition, specific examples of the graft copolymer include the following resins. The following resin may also be a resin having an acid group (alkali-soluble resin). Other examples of the graft copolymer include resins described in paragraphs “0072” to “0094” of JP2012-255128A, the content of which is incorporated herein by reference.

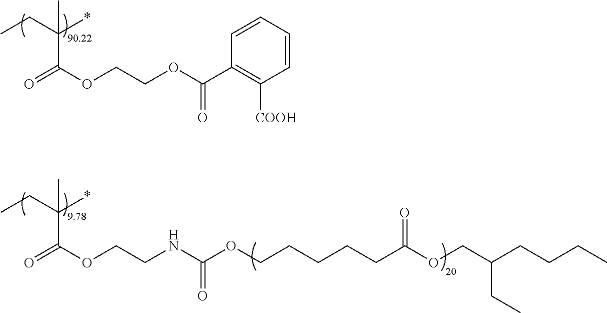

In addition, in the present invention, as the resin (dispersant), an oligoimine dispersant having a nitrogen atom at at least either a main chain or a side chain is also preferably used. As the oligoimine dispersant, a resin, which includes a structural unit having a partial structure X with a functional group (pKa: 14 or lower) and a side chain Y having 40 to 10000 atoms and has a basic nitrogen atom at at least either a main chain or a side chain, is preferable. The basic nitrogen atom is not particularly limited as long as it is a nitrogen atom exhibiting basicity. Examples of the oligoimine dispersant include a dispersant including a structural unit represented by the following Formula (I-1), a structural unit represented by the following Formula (I-2), and/or a structural unit represented by the following Formula (I-2a).

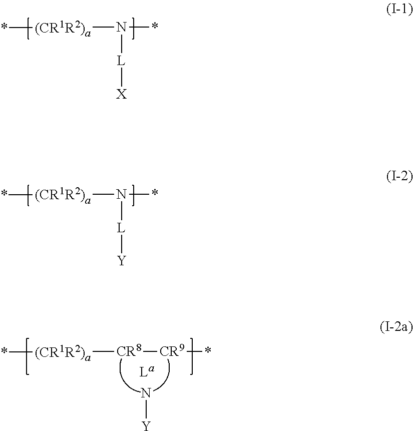

R¹ and R² each independently represent a hydrogen atom, a halogen atom, or an alkyl group (having preferably 1 to 6 carbon atoms). a's each independently represent an integer of 1 to 5. * represents a linking portion between structural units.

R⁸ and R⁹ represent the same group as that of R¹.

L represents a single bond, an alkylene group (having preferably 1 to 6 carbon atoms), an alkenylene group (having preferably 2 to 6 carbon atoms), an arylene group (having preferably 6 to 24 carbon atoms), an heteroarylene group (having preferably 1 to 6 carbon atoms), an imino group (having preferably 0 to 6 carbon atoms), an ether group, a thioether group, a carbonyl group, or a linking group of a combination of the above-described groups. Among these, a single bond or —CR⁵R⁶—NR⁷— (an imino group is present at the X or Y site) is preferable. Here, R⁵ and R⁶ each independently represent a hydrogen atom, a halogen atom, or an alkyl group (having preferably 1 to 6 carbon atoms). R⁷ represents a hydrogen atom or an alkyl group having 1 to 6 carbon atoms.

L^{a} is a structural unit which forms a ring structure with CR⁸CR⁹ and N, preferably a structural unit which forms a nonaromatic heterocycle having 3 to 7 carbon atoms with CR⁸CR⁹ and a carbon atom, more preferably a structural unit which forms a nonaromatic 5- to 7-membered heterocycle with CR⁸CR⁹ and N (nitrogen atom), still more preferably a structural unit which forms a nonaromatic 5-membered heterocycle with CR⁸CR⁹ and N, and even still more preferably a structural unit which forms pyrrolidine with CR⁸CR⁹ and N. This structural unit may have a substituent such as an alkyl group.

X represents a group having a functional group (pKa: 14 or lower).

Y represents a side chain having 40 to 10000 atoms.

The oligoimine dispersant may further include one or more copolymerization components selected from the group consisting of the structural units represented by Formulae (I-3), (I-4), and (I-5). By the oligoimine dispersant including the above-described structural units, the dispersibility of the pigment or the like can be further improved.

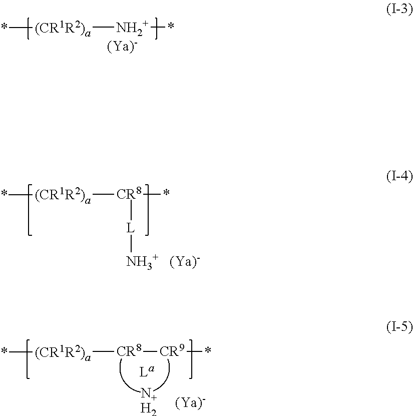

R¹, R², R⁸, R⁹, L, La, a, and * have the same definitions as R¹, R², R⁸, R⁹, L, La, a, and * in Formulae (I-1), (I-2), and (I-2a).

Ya represents a side chain having 40 to 10000 atoms which has an anionic group. The structural unit represented by Formula (I-3) can be formed by adding an oligomer or a polymer having a group, which reacts with amine to form a salt, to a resin having a primary or secondary amino group at a main chain such that they react with each other.

The oligoimine dispersant can be found in the description of paragraphs “0102” to “0166” of JP2012-255128A, the content of which is incorporated herein by reference. Specific examples of the oligoimine dispersant are as follows. The following resin may also be a resin having an acid group (alkali-soluble resin). In addition, as the oligoimine dispersant, a resin described in paragraphs “0168” to “0174” of JP2012-255128A can be used.

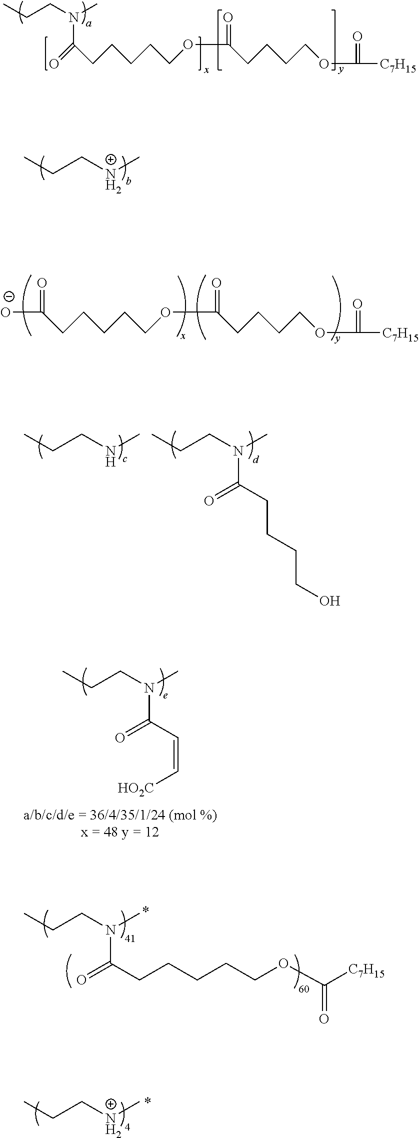

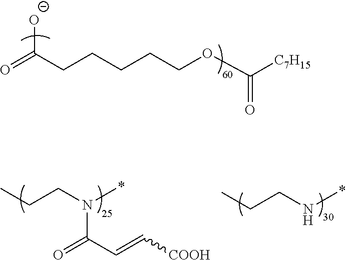

The dispersant is available as a commercially available product, and specific examples thereof include Disperbyk-111 (manufactured by BYK Chemie). In addition, a pigment dispersant described in paragraphs “0041” to “0130” of JP2014-130338A can also be used, the content of which is incorporated herein by reference. In addition, the resin having an acid group or the like can also be used as a dispersant.

In the composition according to the embodiment of the present invention, the content of the resin is preferably 1 mass % or higher, more preferably 5 mass % or higher, still more preferably 10 mass % or higher, and still more preferably 20 mass % or higher with respect to the total solid content of the composition. The upper limit is preferably 80 mass % or lower, more preferably 70 mass % or lower, and still more preferably 50 mass % or lower.

In a case where the composition according to the embodiment of the present invention includes the resin having an acid group, the content of the resin having an acid group is preferably 1 mass % or higher, more preferably 5 mass % or higher, still more preferably 10 mass % or higher, and still more preferably 20 mass % or higher with respect to the total solid content of the composition. The upper limit is preferably 80 mass % or lower, more preferably 70 mass % or lower, and still more preferably 50 mass % or lower.

In addition, in a case where the composition according to the embodiment of the present invention includes the monomer type compound that has a group having an ethylenically unsaturated bond and the resin, a mass ratio (monomer type compound/resin) of the monomer type compound that has a group having an ethylenically unsaturated bond to the resin is preferably 0.4 to 1.4. The lower limit of the mass ratio is preferably 0.5 or higher and more preferably 0.6 or higher. The upper limit of the mass ratio is preferably 1.3 or lower and more preferably 1.2 or lower. In a case where the mass ratio is in the above-described range, a pattern having more excellent rectangularity can be formed.

In addition, a mass ratio (monomer type compound/resin having an acid group) of the monomer type compound that has a group having an ethylenically unsaturated bond to the resin having an acid group is preferably 0.4 to 1.4. The lower limit of the mass ratio is preferably 0.5 or higher and more preferably 0.6 or higher. The upper limit of the mass ratio is preferably 1.3 or lower and more preferably 1.2 or lower. In a case where the mass ratio is in the above-described range, a pattern having more excellent rectangularity can be formed.

<<Ultraviolet Absorber>>

The composition according to the embodiment of the present invention can include an ultraviolet absorber. As the ultraviolet absorber, for example, a conjugated diene compound, an aminobutadiene compound, a methyldibenzoyl compound, a coumarin compound, a salicylate compound, a benzophenone compound, a benzotriazole compound, an acrylonitrile compound, or a hydroxyphenyltriazine compound can be used. The details can be found in paragraphs “0052” to “0072” of JP2012-208374A and paragraphs “0317” to “0334” of JP2013-068814A, the contents of which are incorporated herein by reference. Examples of a commercially available product of the conjugated diene compound include UV-503 (manufactured by Daito Chemical Co., Ltd.). In addition, as the benzotriazole compound, MYUA series (manufactured by Miyoshi Oil&Fat Co., Ltd.; The Chemical Daily, Feb. 1, 2016) may be used.

In the present invention, as the ultraviolet absorber, a compound represented by any one of Formulae (UV-1) to (UV-3) is preferable, a compound represented by any one of Formula (UV-1) or (UV-3) is more preferable, and a compound represented by Formula (UV-1) is still more preferable.

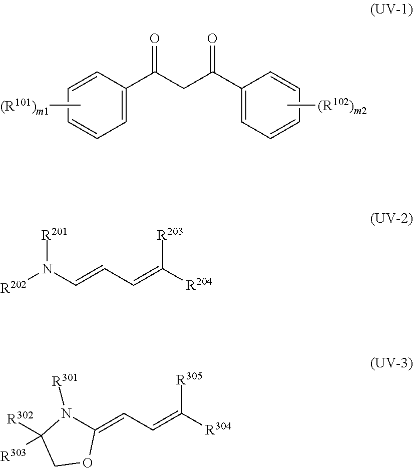

In Formula (UV-1), R¹⁰¹ and R¹⁰² each independently represent a substituent, and m1 and m2 each independently represent 0 to 4.

In Formula (UV-2), R²⁰¹ and R²⁰² each independently represent a hydrogen atom or an alkyl group, and R²⁰³ and R²⁰⁴ each independently represent a substituent.

In Formula (UV-3), R³⁰¹ to R³⁰³ each independently represent a hydrogen atom or an alkyl group, and R³⁰⁴ and R³⁰⁵ each independently represent a substituent.

Specific examples of the compound include the following compounds.

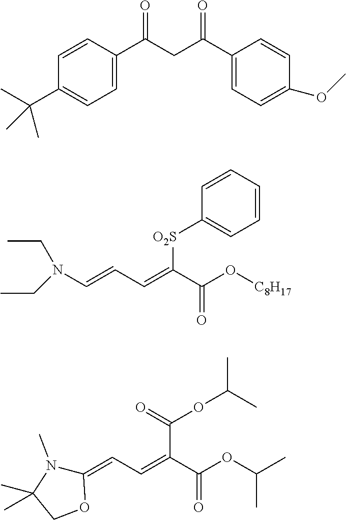

In the composition according to the embodiment of the present invention, the content of the ultraviolet absorber is preferably 0.01 to 10 mass % and more preferably 0.01 to 5 mass % with respect to the total solid content of the composition according to the embodiment of the present invention. In the present invention, as the ultraviolet absorber, one kind may be used alone, or two or more kinds may be used. In a case where two or ultraviolet absorbers are used in combination, it is preferable that the total content of the two or more ultraviolet absorbers is in the above-described range.

<<Photoinitiator>>

The composition according to the embodiment of the present invention may include a photoinitiator. Examples of the photoinitiator include a photoradical polymerization initiator and a photocationic polymerization initiator. It is preferable that the photoinitiator is selected and used according to the kind of the curable compound. In a case where the radically polymerizable compound is used as the curable compound, it is preferable that the photoradical polymerization initiator is used as the photoinitiator. In a case where the cationically polymerizable compound is used as the curable compound, it is preferable that the photocationic polymerization initiator is used as the photoinitiator. The photoinitiator is not particularly limited and can be appropriately selected from well-known photoinitiators. For example, a compound having photosensitivity to light in a range from an ultraviolet range to a visible range is preferable.

The content of the photoinitiator is preferably 0.1 to 50 mass %, more preferably 0.5 to 30 mass %, and still more preferably 1 to 20 mass % with respect to the total solid content of the composition. In a case where the content of the photoinitiator is in the above-described range, higher sensitivity and pattern formability can be obtained. The composition according to the embodiment of the present invention may include one photoinitiator or two or more photoinitiator s. In a case where the composition includes two or more photoinitiators, it is preferable that the total content of the photoinitiators is in the above-described range.

(Photoradical Polymerization Initiator)

Examples of the photoradical polymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. In addition, from the viewpoint of exposure sensitivity, as the photoradical polymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from the group consisting of an oxime compound, an α-hydroxy ketone compound, an α-aminoketone compound, and an acylphosphine compound is more preferable, and an oxime compound is still more preferable. The details of the photopolymerization initiator can be found in paragraphs “0065” to “0111” of JP2014-130173A, the content of which is incorporated herein by reference.

Examples of a commercially available product of the α-hydroxyketone compound include IRGACURE-184, DAROCUR-1173, IRGACURE-500, IRGACURE-2959, and IRGACURE-127 (all of which are manufactured by BASF SE). Examples of a commercially available product of the α-aminoketone compound include IRGACURE-907, IRGACURE-369, IRGACURE-379, and IRGACURE-379EG (all of which are manufactured by BASF SE). Examples of a commercially available product of the acylphosphine compound include IRGACURE-819, and DAROCUR-TPO (all of which are manufactured by BASF SE).

As the oxime compound, a compound described in JP2001-233842A, a compound described in JP2000-080068A, a compound described in JP2006-342166A, or a compound described in JP2016-021012A can be used. Examples of the oxime compound which can be preferably used in the present invention include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. In addition, examples of the oxime compound include a compound described in J.C.S. Perkin II (1979), pp. 1653-1660, J.C.S. Perkin II (1979), pp. 156-162 and Journal of Photopolymer Science and Technology (1995), pp. 202-232, JP2000-066385A, JP2000-080068A, JP2004-534797A, or JP2006-342166A. As a commercially available product of the oxime compound, IRGACURE-OXE01, IRGACURE-OXE02, IRGACURE-OXE03, or IRGACURE-OXE04 (all of which are manufactured by BASF SE) can also be preferably used. In addition, TR-PBG-304 (manufactured by Changzhou Tronly New Electronic Materials Co., Ltd.), ADEKA ARKLS NCI-831 (manufactured by Adeka Corporation), ADEKA ARKLS NCI-930 (manufactured by Adeka Corporation), ADEKA OPTOMER N-1919 (manufactured by Adeka Corporation, a photopolymerization initiator 2 described in JP2012-014052A) can also be used.

In the present invention, an oxime compound having a fluorene ring can also be used as the photoradical polymerization initiator. Specific examples of the oxime compound having a fluorene ring include a compound described in JP2014-137466A. The content is incorporated herein by reference.

In the present invention, an oxime compound having a fluorine atom can also be used as the photoradical polymerization initiator. Specific examples of the oxime compound having a fluorine atom include a compound described in JP2010-262028A, Compound 24 and 36 to 40 described in JP2014-500852A, and Compound (C-3) described in JP2013-164471A. The content is incorporated herein by reference.

In the present invention, as the photoradical polymerization initiator, an oxime compound having a nitro group can be used. It is preferable that the oxime compound having a nitro group is a dimer. Specific examples of the oxime compound having a nitro group include a compound described in paragraphs “0031” to “0047” of JP2013-114249A and paragraphs “0008” to “0012” and “0070” to “0079” of JP2014-137466A, a compound described in paragraphs “0007” to 0025” of JP4223071B, and ADEKA ARKLS NCI-831 (manufactured by Adeka Corporation).

Hereinafter, specific examples of the oxime compound which are preferably used in the present invention are shown below, but the present invention is not limited thereto.

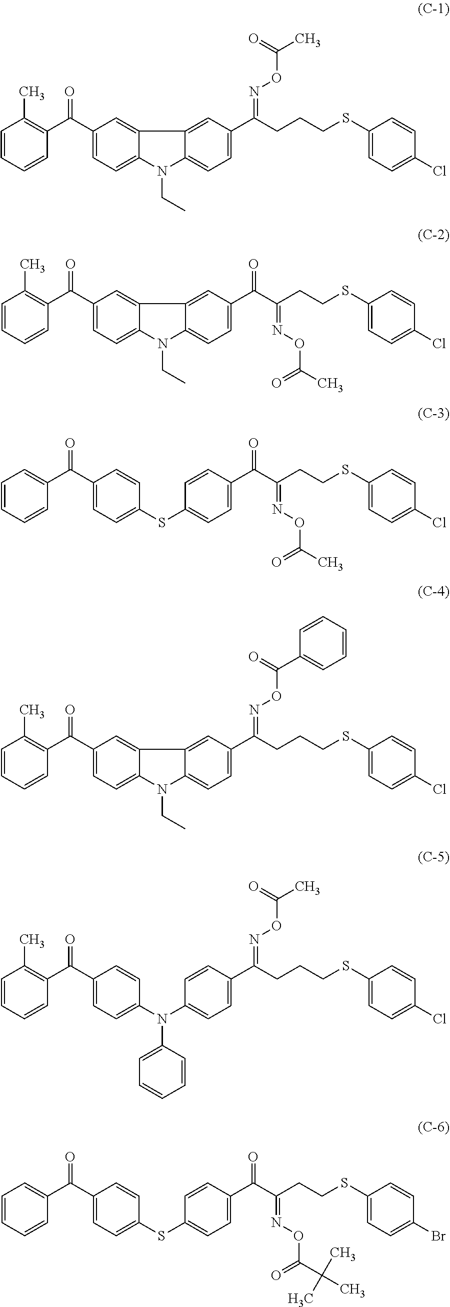 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

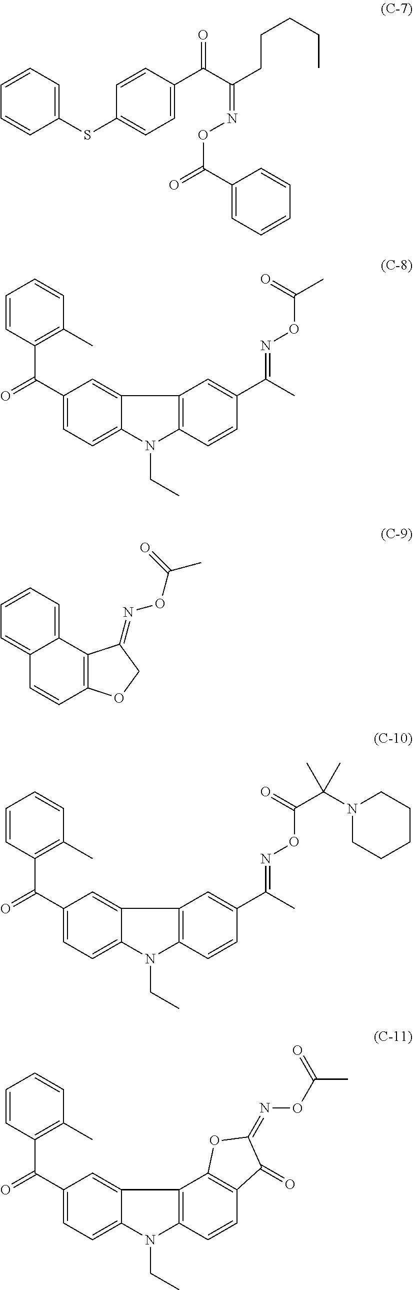

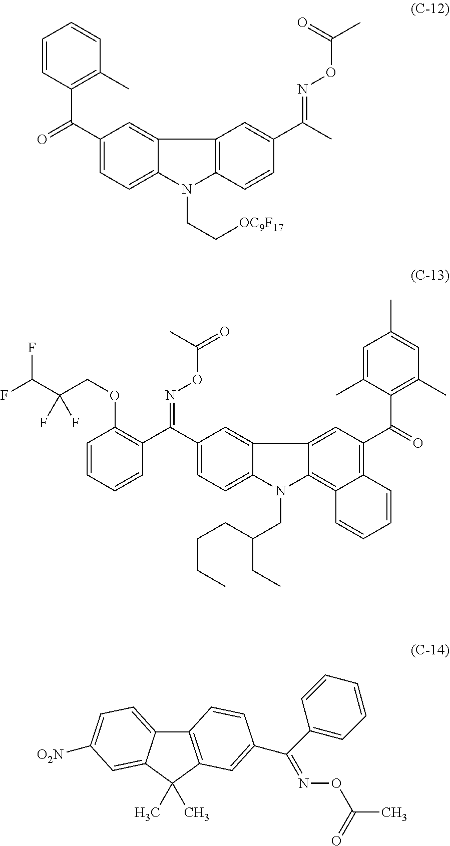

The oxime compound is preferably a compound having an absorption maximum in a wavelength range of 350 nm to 500 nm and more preferably a compound having an absorption maximum in a wavelength range of 360 nm to 480 nm. In addition, the oxime compound is preferably a compound having a high absorbance at 365 nm and 405 nm.

The molar absorption coefficient of the oxime compound at 365 nm or 405 nm is preferably 1000 to 300000, more preferably 2000 to 300000, and still more preferably 5000 to 200000 from the viewpoint of sensitivity.

The molar absorption coefficient of the compound can be measured using a well-known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

It is preferable that the photoradical polymerization initiator includes an oxime compound and an α-aminoketone compound. By using the oxime compound and the α-aminoketone compound in combination, the developability is improved, and a pattern having excellent rectangularity is likely to be formed. In a case where the oxime compound and the α-aminoketone compound are used in combination, the content of the α-aminoketone compound is preferably 50 to 600 parts by mass and more preferably 150 to 400 parts by mass with respect to 100 parts by mass of the oxime compound.

The content of the photoradical polymerization initiator is preferably 0.1 to 50 mass %, more preferably 0.5 to 30 mass %, and still more preferably 1 to 20 mass % with respect to the total solid content of the composition. In a case where the content of the photoradical polymerization initiator is in the above-described range, higher sensitivity and pattern formability can be obtained. The composition according to the embodiment of the present invention may include one photoradical polymerization initiator or two or more photoradical polymerization initiators. In a case where the composition includes two or more photoradical polymerization initiators, it is preferable that the total content of the photoradical polymerization initiators is in the above-described range.

(Photocationic Polymerization Initiator)

Examples of the photocationic polymerization initiator include a photoacid generator. Examples of the photoacid generator include compounds which are decomposed by light irradiation to generate an acid including: an onium salt compound such as a diazonium salt, a phosphonium salt, a sulfonium salt, or an iodonium salt; and a sulfonate compound such as imidosulfonate, oximesulfonate, diazodisulfone, disulfone, or o-nitrobenzyl sulfonate. For example, bis-(4-tert-butylphenyl)iodonium nonafluorobutanesulfonate can be used. The details of the photocationic polymerization initiator can be found in paragraphs “0139” to “0214” of JP2009-258603A, the content of which is incorporated herein by reference.

As the photocationic polymerization initiator, a commercially available product can also be used. Examples of the commercially available product of the photocationic polymerization initiator include ADEKA ARKLS SP series manufactured by Adeka Corporation (for example, ADEKA ARKLS SP-606) and IRGACURE 250, IRGACURE 270, and IRGACURE 290 manufactured by BASF SE.

The content of the photocationic polymerization initiator is preferably 0.1 to 50 mass %, more preferably 0.5 to 30 mass %, and still more preferably 1 to 20 mass % with respect to the total solid content of the composition. In a case where the content of the photocationic polymerization initiator is in the above-described range, higher sensitivity and pattern formability can be obtained. The composition according to the embodiment of the present invention may include one photocationic polymerization initiator or two or more photocationic polymerization initiators. In a case where the composition includes two or more photocationic polymerization initiators, it is preferable that the total content of the two or more photocationic polymerization initiators is in the above-described range.

<<Acid Anhydride, Polycarboxylic Acid>>

In a case where the composition according to the embodiment of the present invention includes the epoxy compound, it is preferable that the composition further includes at least one selected from an acid anhydride or a polycarboxylic acid.

Specific examples of the acid anhydride include phthalic anhydride, trimellitic anhydride, pyromellitic anhydride, maleic acid anhydride, tetrahydrophthalic anhydride, methyltetrahydrophthalic anhydride, methylnadic anhydride, nadic anhydride, hexahydrophthalic anhydride, methylhexahydrophthalic anhydride, glutaric anhydride, 2,4-diethylglutaric anhydride, 3,3-dimethylglutaric anhydride, butanetetracarboxylic anhydride, bicyclo[2,2,1]heptane-2,3-dicarboxylic anhydride, methylbicyclo[2,2,1]heptane-2,3-dicarboxylic anhydride, and cyclohexane-1,3,4-tricarboxylic acid-3,4-anhydride. In particular, methyltetrahydrophthalic anhydride, methylnadic anhydride, nadic anhydride, hexahydrophthalic anhydride, methylhexahydrophthalic anhydride, 2,4-diethylglutaric anhydride, butanetetracarboxylic anhydride, bicyclo[2,2,1]heptane-2,3-dicarboxylic anhydride, or methylbicyclo[2,2,1]heptane-2,3-dicarboxylic anhydride, or cyclohexane-1,3,4-tricarboxylic acid-3,4-anhydride is preferable from the viewpoints of light fastness, transparency, and workability.

The polycarboxylic acid is a compound having at least two carboxyl groups. The polycarboxylic acid is not particularly limited as long as a geometric isomer or an optical isomer is present in the following compound. As the polycarboxylic acid, a bifunctional to hexafunctional carboxylic acid is preferable. For example, an alkyltricarboxylic acid such as 1,2,3,4-butanetetracarboxylic acid, 1,2,3-propanetricarboxylic acid, 1,3,5-pentanetricarboxylic acid, or citric acid; an alicyclic polycarboxylic acid such as phthalic acid, hexahydrophthalic acid, methylhexahydrophthalic acid, tetrahydrophthalic acid, methyltetrahydrophthalic acid, cyclohexanetricarboxylic acid, nadic acid, or methylnadic acid; a polymer of an unsaturated fatty acid such as linolenic acid or oleic acid and a dimer which is a reduction product thereof; a linear alkyl diacid such as malic acid is preferable, hexanedioic acid, pentanedioic acid, heptanedioic acid, octanedioic acid, nonanedioic acid, or decanedioic acid is more preferable, and butanedioic acid is still more preferable from the viewpoint of heat resistance and transparency of the film.

The content of the acid anhydride and the polycarboxylic acid is preferably 0.01 to 20 parts by mass, more preferably 0.01 to 10 parts by mass, and still more preferably 0.1 to 6.0 parts by mass with respect to 100 parts by mass of the epoxy compound.

<<Chromatic Colorant>>

The composition according to the embodiment of the present invention may include a chromatic colorant. In the present invention, “chromatic colorant” denotes a colorant other than a white colorant and a black colorant. It is preferable that the chromatic colorant is a colorant having an absorption in a wavelength range of 400 nm or longer and shorter than 650 nm.

In the present invention, the chromatic colorant may be a pigment or a dye. As the pigment, an organic pigment is preferable. Examples of the organic pigment are as follows: Color Index (C.I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214 (all of which are yellow pigments);

C.I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C.I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments);

C.I. Pigment Green 7, 10, 36, 37, 58, and 59 (all of which are green pigments);

C.I. Pigment Violet 1, 19, 23, 27, 32, 37, and 42 (all of which are violet pigments); and

C.I. Pigment Blue 1, 2, 15, 15:1, 15:2, 15:3, 15:4, 15:6, 16, 22, 60, 64, 66, 79, and 80 (all of which are blue pigments).

Among these organic pigments, one kind may be used alone, or two or more kinds may be used in combination.

As the dye, well-known dyes can be used without any particular limitation. In terms of a chemical structure, a dye such as a pyrazole azo dye, an anilino azo dye, a triarylmethane dye, an anthraquinone dye, an anthrapyridone dye, a benzylidene dye, an oxonol dye, a pyrazolotriazole azo dye, a pyridone azo dye, a cyanine dye, a phenothiazine dye, a pyrrolopyrazole azomethine dye, a xanthene dye, a phthalocyanine dye, a benzopyran dye, an indigo dye, or a pyrromethene dye can be used. In addition, a polymer of the above-described dyes may be used. In addition, dyes described in JP2015-028144A and JP2015-034966A can also be used.

In a case where the composition according to the embodiment of the present invention includes a chromatic colorant, the content of the chromatic colorant is preferably 0.1 to 70 mass % with respect to the total solid content of the composition according to the embodiment of the present invention. The lower limit is preferably 0.5 mass % or higher and more preferably 1.0 mass % or higher. The upper limit is preferably 60 mass % or lower, and more preferably 50 mass % or lower.

The content of the chromatic colorant is preferably 10 to 1000 parts by mass and more preferably 50 to 800 parts by mass with respect to 100 parts by mass of the near infrared absorbing colorant.

In addition, the total content of the chromatic colorant and the near infrared absorbing colorant is preferably 1 to 80 mass % with respect to the total solid content of the composition according to the embodiment of the present invention. The lower limit is preferably 5 mass % or higher and more preferably 10 mass % or higher. The upper limit is preferably 70 mass % or lower, and more preferably 60 mass % or lower.

In a case where the composition according to the embodiment of the present invention includes two or more chromatic colorants, it is preferable that the total content of the two or more chromatic colorants is in the above-described range.

<<Coloring Material that Allows Transmission of Infrared Light and Shields Visible Light>>

The composition according to the embodiment of the present invention may also include the coloring material that allows transmission of infrared light and shields visible light (hereinafter, also referred to as “coloring material that shields visible light”).

In the present invention, it is preferable that the coloring material that shields visible light is a coloring material that absorbs light in a wavelength range of violet to red. In addition, in the present invention, it is preferable that the coloring material that shields visible light is a coloring material that shields light in a wavelength range of 450 to 650 nm. In addition, it is preferable that the coloring material that shields visible light is a coloring material that allows transmission of light in a wavelength range of 900 to 1300 nm.

In the present invention, it is preferable that the coloring material that shields visible light satisfies at least one of the following requirement (A) or (B).

(A): The coloring material that shields visible light includes two or more chromatic colorants, and a combination of the two or more chromatic colorants forms black.

(B): The coloring material that shields visible light includes an organic black colorant.

Examples of the chromatic colorant are as described above. Examples of the organic black colorant include a bisbenzofuranone compound, an azomethine compound, a perylene compound, and an azo compound. Among these, a bisbenzofuranone compound or a perylene compound is preferable. Examples of the bisbenzofuranone compound include a compound described in JP2010-534726A, JP2012-515233A, and JP2012-515234A. For example, “Irgaphor Black” (manufactured by BASF SE) is available. Examples of the perylene compound include C.I. Pigment Black 31 and 32. Examples of the azomethine compound include a compound described in JP1989-170601A (JP-H1-170601A) and JP1990-034664A (JP-H2-034664A). For example, “CHROMOFINE BLACK A1103” (manufactured by Dainichiseika Color & Chemicals Mfg. Co., Ltd.) is available.

In a case where a combination of two or more chromatic colorants forms black, examples of the combination of chromatic colorants are as follows.

(1) An aspect in which the coloring material that shields visible light includes a yellow colorant, a blue colorant, a violet colorant, and a red colorant

(2) An aspect in which the coloring material that shields visible light includes a yellow colorant, a blue colorant, and a red colorant

(3) An aspect in which the coloring material that shields visible light includes a yellow colorant, a violet colorant, and a red colorant

(4) An aspect in which the coloring material that shields visible light includes a yellow colorant and a violet colorant

(5) An aspect in which the coloring material that shields visible light includes a green colorant, a blue colorant, a violet colorant, and a red colorant

(6) An aspect in which the coloring material that shields visible light includes a violet colorant and an orange colorant

(7) An aspect in which the coloring material that shields visible light includes a green colorant, a violet colorant, and a red colorant

(8) An aspect in which the coloring material that shields visible light includes a green colorant and a red colorant

In a case where the composition according to the embodiment of the present invention includes the coloring material that shields visible light, the content of the coloring material that shields visible light is preferably 60 mass % or lower, more preferably 50 mass % or lower, still more preferably 30 mass % or lower, still more preferably 20 mass % or lower, and still more preferably 15 mass % or lower with respect to the total solid content of the composition. The lower limit is, for example, 0.01 mass % or higher or 0.5 mass % or higher.

<<Pigment Derivative>>

The composition according to the embodiment of the present invention may further include a pigment derivative. Examples of the pigment derivative include a compound having a structure in which a portion of a pigment is substituted with an acid group, a basic group, a group having a salt structure, or a phthalimidomethyl group. As the pigment derivative, a compound represented by Formula (B1) is preferable.

PL-(X)ₙ)ₘ (B1)

In Formula (B1), P represents a colorant structure, L represents a single bond or a linking group, X represents an acid group, a basic group, a group having a salt structure, or a phthalimidomethyl group, m represents an integer of 1 or more, n represents an integer of 1 or more, in a case where m represents 2 or more, a plurality of L's and a plurality of X's may be different from each other, and in a case where n represents 2 or more, a plurality of X's may be different from each other.

In Formula (B1), P represents a colorant structure, preferably at least one selected from the group consisting of a pyrrolopyrrole colorant structure, a diketo pyrrolopyrrole colorant structure, a quinacridone colorant structure, an anthraquinone colorant structure, a dianthraquinone colorant structure, a benzoisoindole colorant structure, a thiazine indigo colorant structure, an azo colorant structure, a quinophthalone colorant structure, a phthalocyanine colorant structure, a naphthalocyanine colorant structure, a dioxazine colorant structure, a perylene colorant structure, a perinone colorant structure, a benzimidazolone colorant structure, a benzothiazole colorant structure, a benzimidazole colorant structure, and a benzoxazole colorant structure, more preferably at least one selected from the group consisting of a pyrrolopyrrole colorant structure, a diketo pyrrolopyrrole colorant structure, a quinacridone colorant structure, and a benzimidazolone colorant structure, and still more preferably a pyrrolopyrrole colorant structure.

In Formula (B1), L represents a single bond or a linking group. The linking group is preferably a group composed of 1 to 100 carbon atoms, 0 to 10 nitrogen atoms, 0 to 50 oxygen atoms, 1 to 200 hydrogen atoms, and 0 to 20 sulfur atoms, and may be unsubstituted or may further have a substituent.

In Formula (B1), X represents an acid group, a basic group, a group having a salt structure, or a phthalimidomethyl group. Among these, an acid group or a basic group is preferable. Examples of the acid group include a carboxyl group and a sulfo group. Examples of the basic group include an amino group.

Specific examples of the pigment derivative include the following compounds. In the following structural formulae, Me represents a methyl group, and Ph represents a phenyl group. In addition, for example, compounds described in JP1981-118462A (JP-S56-118462A), JP1988-264674A (JP-S63-264674A), JP1989-217077A (JP-H1-217077A), JP1991-9961A (JP-H3-9961A), JP1991-026767A (JP-H3-026767A), JP1991-153780A (JP-H3-153780A), JP1991-045662A (JP-H3-045662A), JP1992-285669A (JP-H4-285669A), JP1994-145546A (JP-H6-145546A), JP1994-212088A (JP-H6-212088A), JP1994-240158A (JP-H6-240158A), JP1998-030063A (JP-H10-030063A), JP1998-195326A (JP-H10-195326A), paragraphs “0086” to “0098” of WO2011/024896A, and paragraphs “0063” to “0094” of WO2012/102399A can be used, the contents of which are incorporated herein by reference.

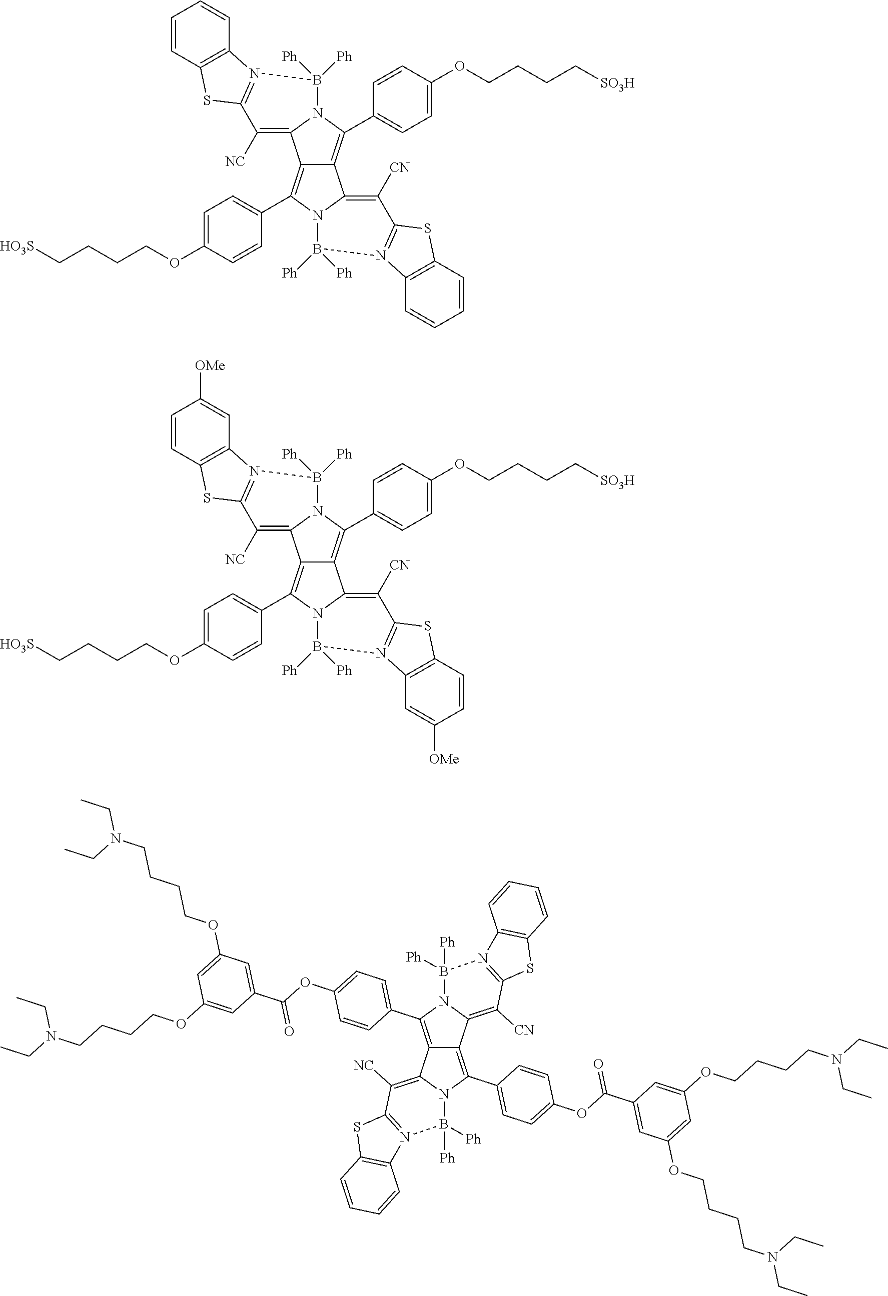

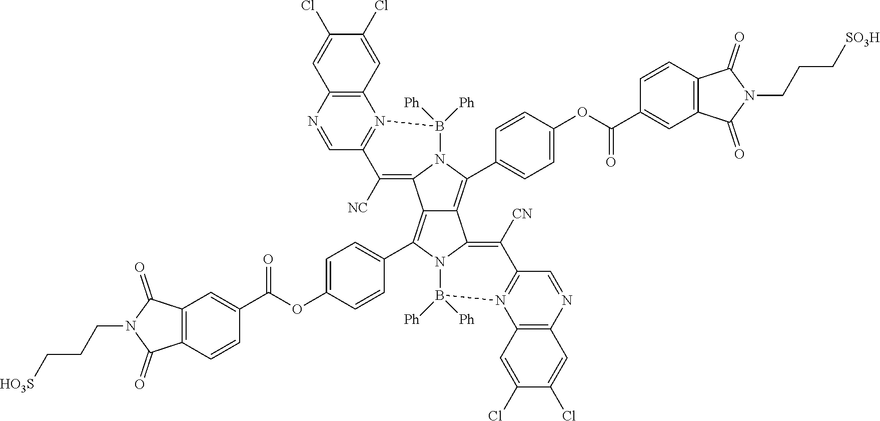

In a case where the composition according to the embodiment of the present invention includes the pigment derivative, the content of the pigment derivative is preferably 1 to 50 parts by mass with respect to 100 parts by mass of the pigment. The lower limit value is preferably 3 parts by mass or more and more preferably 5 parts by mass or more. The upper limit value is preferably 40 parts by mass or less and more preferably 30 parts by mass or less. In a case where the content of the pigment derivative is in the above-described range, the pigment dispersibility can be improved, and aggregation of the pigment can be effectively suppressed. As the pigment derivative, one kind may be used alone, or two or more kinds may be used in combination. In a case where two or more pigment derivatives are used in combination, it is preferable that the total content of the two or more pigment derivatives is in the above-described range.

<<Solvent>>

The composition according to the embodiment of the present invention may include a solvent. Examples of the solvent include an organic solvent. The solvent is not particularly limited as long as it satisfies the solubility of the respective components and the coating properties of the composition.

Examples of the organic solvent include esters, ethers, ketones, and aromatic hydrocarbons. The details of the organic solvent can be found in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, and propylene glycol monomethyl ether acetate. In the present invention, as the organic solvent, one kind may be used alone, or two or more kinds may be used in combination. In this case, it may be preferable that the content of the aromatic hydrocarbon (for example, benzene, toluene, xylene, or ethylbenzene) as the solvent is low (for example, 50 mass parts per million (ppm) or lower, 10 mass ppm or lower, or 1 mass ppm or lower with respect to the total mass of the organic solvent) in consideration of environmental aspects and the like.

In the present invention, a solvent having a low metal content is preferably used. For example, the metal content in the solvent is preferably 10 mass parts per billion (ppb) or lower. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method of removing impurities such as metal from the solvent include distillation (for example, molecular distillation or thin-film distillation) and filtering using a filter. The pore size of a filter used for the filtering is preferably 10 nm or less, more preferably 5 nm or less, and still more preferably 3 nm or less. As a material of the filter, polytetrafluoroethylene, polyethylene, or nylon is preferable.

The solvent may include an isomer (a compound having the same number of atoms and a different structure). In addition, the organic solvent may include only one isomer or a plurality of isomers.

In the present invention, as the organic solvent, an organic solvent containing 0.8 mmol/L or lower of a peroxide is preferable, and an organic solvent containing substantially no peroxide is more preferable.

The content of the solvent is preferably 10 to 90 mass %, more preferably 20 to 80 mass %, and still more preferably 25 to 75 mass % with respect to the total mass of the composition.

<<Polymerization Inhibitor>>

The composition according to the embodiment of the present invention may include a polymerization inhibitor. Examples of the polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and N-nitrosophenylhydroxyamine salt (for example, an ammonium salt or a cerium (III) salt). Among these, p-methoxyphenol is preferable. The content of the polymerization inhibitor is preferably 0.001 to 5 mass % with respect to the total solid content of the composition.

<<Silane Coupling Agent>>

The composition according to the embodiment of the present invention may include a silane coupling agent. In the present invention, the silane coupling agent refers to a silane compound having a functional group other than a hydrolyzable group. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group. Among these, an alkoxy group is preferable. That is, it is preferable that the silane coupling agent is a compound having an alkoxysilyl group. Examples of the functional group other than a hydrolyzable group include a vinyl group, a styryl group, a (meth)acryloyl group, a mercapto group, an epoxy group, an oxetanyl group, an amino group, an ureido group, a sulfide group, an isocyanate group, and a phenyl group. Among these, a (meth)acryloyl group or an epoxy group is preferable. Examples of the silane coupling agent include a compound described in paragraphs “0018” to “0036” of JP2009-288703A and a compound described in paragraphs “0056” to “0066” of JP2009-242604A, the content of which is incorporated herein by reference.

The content of the silane coupling agent is preferably 0.01 to 15.0 mass % and more preferably 0.05 to 10.0 mass % with respect to the total solid content of the composition. As the silane coupling agent, one kind may be used alone, or two or more kinds may be used. In a case where two or more silane coupling agents are used in combination, it is preferable that the total content of the two or more silane coupling agents is in the above-described range.

<<Other Components>>

Optionally, the composition according to the embodiment of the present invention may further include a sensitizer, a curing accelerator, a filler, a thermal curing accelerator, a thermal polymerization inhibitor, a plasticizer, and other auxiliary agents (for example, conductive particles, a filler, an antifoaming agent, a flame retardant, a leveling agent, a peeling accelerator, an aromatic chemical, a surface tension adjuster, or a chain transfer agent). The details of these components can be found in paragraphs “0101” to “0104” and “0107” to “0109” of JP2008-250074A, the content of which is incorporated herein by reference.

For example, in a case where a film is formed by coating, the viscosity (23° C.) of the composition according to the embodiment of the present invention is preferably in a range of 1 to 3000 mPa·s. The lower limit is preferably 3 mPa·s or higher and more preferably 5 mPa·s or higher. The upper limit is preferably 2000 mPa·s or lower and more preferably 1000 mPa·s or lower.

A storage container of the composition according to the embodiment of the present invention is not particularly limited, and a well-known storage container can be used. In addition, as the storage container, in order to suppress infiltration of impurities into the raw materials or the composition, a multilayer bottom in which a container inner wall having a six-layer structure is formed of six kinds of resins or a bottle in which a container inner wall having a seven-layer structure is formed of six kinds of resins is preferably used. Examples of the container include a container described in JP2015-123351A.

The use of the composition according to the embodiment of the present invention is not particularly limited. The composition according to the embodiment of the present invention can be preferably used to form a near infrared cut filter or the like. In addition, by the composition according to the embodiment of the present invention including the coloring material that shields visible light, an infrared transmitting filter that can allow transmission of only near infrared light at a specific wavelength or higher can also be formed.

<Method of Preparing Composition>

The composition according to the embodiment of the present invention can be prepared by mixing the above-described components with each other. During the preparation of the composition, for example, all the components may be dissolved or dispersed in an organic solvent at the same time to prepare the composition. Optionally, two or more solutions or dispersions to which the respective components are appropriately added may be prepared, and the solutions or dispersions may be mixed with each other during use (during application) to prepare the composition.

In addition, it is preferable that a method of preparing the composition according to the embodiment of the present invention includes a process of dispersing particles of the pigment and the like. Examples of a mechanical force used for dispersing the particles in the process of dispersing the particles include compression, squeezing, impact, shearing, and cavitation. Specific examples of the process include a beads mill, a sand mill, a roll mill, a ball mill, a paint shaker, a Microfluidizer, a high-speed impeller, a sand grinder, a project mixer, high-pressure wet atomization, and ultrasonic dispersion. During the pulverization of the particles using a sand mill (beads mill), it is preferable that the process is performed under conditions for increasing the pulverization efficiency, for example, by using beads having a small diameter and increasing the filling rate of the beads. In addition, it is preferable that rough particles are removed by filtering, centrifugal separation, and the like. In addition, as the process and the disperser for dispersing the particles, a process and a disperser described in “Complete Works of Dispersion Technology, Johokiko Co., Ltd., Jul. 15, 2005”, “Dispersion Technique focusing on Suspension (Solid/Liquid Dispersion) and Practical Industrial Application, Comprehensive Reference List, Publishing Department of Management Development Center, Oct. 10, 1978”, and paragraph “0022” JP2015-157893A can be suitably used. In addition, in the process of dispersing the particles, particles may be refined in a salt milling step. A material, a device, process conditions, and the like used in the salt milling step can be found in, for example, JP2015-194521A and JP2012-046629A.

During the preparation of the composition, it is preferable that the composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene. Among these materials, polypropylene (including high-density polypropylene) or nylon is preferable. The pore size of the filter is suitably about 0.01 to 7.0 μm and is preferably about 0.01 to 3.0 μm and more preferably about 0.05 to 0.5 μm. In a case where the pore size of the filter is in the above-described range, fine foreign matter can be reliably removed. In addition, it is preferable that a fibrous filter material is used. Examples of the fibrous filter material include polypropylene fiber, nylon fiber, and glass fiber. Specific examples include a filter cartridge of SBP type series (for example, SBP008), TPR type series (for example, TPR002 or TPR005), and SHPX type series (for example, SHPX003) all of which are manufactured by Roki Techno Co., Ltd.

In a case where a filter is used, a combination of different filters (for example, a first filter and a second filter) may be used. At this time, the filtering using each of the filters may be performed once, or twice or more. In addition, a combination of filters having different pore sizes in the above-described range may be used. Here, the pore size of the filter can refer to a nominal value of a manufacturer of the filter. A commercially available filter can be selected from various filters manufactured by Pall Corporation (for example, DFA4201NXEY), Toyo Roshi Kaisha, Ltd., Entegris Japan Co., Ltd. (former Mykrolis Corporation), or Kits Microfilter Corporation. The second filter may be formed of the same material as that of the first filter. In addition, the filtering using the first filter may be performed only on the dispersion, and the filtering using the second filter may be performed on a mixture of the dispersion and other components.

<Film>

The film according to the embodiment of the present invention is obtained from the above-described composition according to the embodiment of the present invention. The film according to the embodiment of the present invention has excellent infrared shielding properties and visible transparency, and thus can be preferably used as a near infrared cut filter. In addition, the film according to the embodiment of the present invention can also be used as a heat ray shielding filter or an infrared transmitting filter. The film according to the embodiment of the present invention may be used in a state where it is laminated on a support, or the film according to the embodiment of the present invention may be peeled off from a support. The film according to the embodiment of the present invention may be a film having a pattern or a film (flat film) not having a pattern. In a case where the film according to the embodiment of the present invention is used as an infrared transmitting filter, examples of the infrared transmitting filter include a filter that shields visible light and allows transmission of light in a wavelength range of 900 nm or longer. In a case where the film according to the embodiment of the present invention is used as an infrared transmitting filter, the film is a filter which is obtained using a composition including the near infrared absorbing colorant according to the embodiment of the present invention and the coloring material that shields visible light. In this case, it is preferable that the film is a filter in which a layer of the coloring material that shields visible light is separately present in addition to the layer (the film according to the embodiment of the present invention) including the near infrared absorbing colorant. In a case where the film according to the embodiment of the present invention is used as an infrared transmitting filter, the near infrared absorbing colorant has a function of limiting light to be transmitted (near infrared light) to a long wavelength side.

The thickness of the film according to the embodiment of the present invention can be adjusted according to the purpose. The thickness of the film is preferably 20 μm or less, more preferably 10 μm or less, and still more preferably 5 μm or less. The lower limit of the thickness of the film is preferably 0.1 μm or more and more preferably 0.2 μm or more.

The film according to the embodiment of the present invention has a maximum absorption preferably in a wavelength range of 700 to 1000 nm, more preferably in a wavelength range of 720 to 980 nm, and more preferably in a wavelength range of 740 to 960 nm. In addition, a ratio absorbance Amax/absorbance A550 of an absorbance Amax at the maximum absorption to an absorbance A550 at a wavelength of 550 nm is preferably 50 to 500, more preferably 70 to 450, and still more preferably 100 to 400.

In a case where the film is used as a near infrared cut filter, it is preferable that the film according to the embodiment of the present invention satisfies at least one of the following condition (1), . . . , or (4), and it is more preferable that the film according to the embodiment of the present invention satisfies all the following conditions (1) to (4).

(1) A transmittance at a wavelength of 400 nm is preferably 70% or higher, more preferably 80% or higher, still more preferably 85% or higher, and still more preferably 90% or higher

(2) A transmittance at a wavelength of 500 nm is preferably 70% or higher, more preferably 80% or higher, still more preferably 90% or higher, and still more preferably 95% or higher

(3) A transmittance at a wavelength of 600 nm is preferably 70% or higher, more preferably 80% or higher, still more preferably 90% or higher, and still more preferably 95% or higher

(4) A transmittance at a wavelength of 650 nm is preferably 70% or higher, more preferably 80% or higher, still more preferably 90% or higher, and still more preferably 95% or higher

The film according to the embodiment of the present invention can be used in combination with a color filter that includes a chromatic colorant. The color filter can be manufactured using a coloring composition including a chromatic colorant. Examples of the chromatic colorant include the chromatic colorants described regarding the composition according to the embodiment of the present invention. The coloring composition may further include, for example, a curable compound, a photopolymerization initiator, a surfactant, a solvent, a polymerization inhibitor, an ultraviolet absorber, an antioxidant. In more detail, for example, the materials described above can be used. In addition, the film according to the embodiment of the present invention may be a filter having not only a function as a near infrared cut filter but also a function as a color filter by including a chromatic colorant.

In a case where the film according to the embodiment of the present invention is used in combination with a color filter, it is preferable that the color filter is disposed on an optical path of the film according to the embodiment of the present invention. For example, the film according to the embodiment of the present invention and the color filter can be laminated to be used as a laminate. In the laminate, the film according to the embodiment of the present invention and the color filter may be or may not be adjacent to each other in a thickness direction. In a case where the film according to the embodiment of the present invention is not adjacent to the color filter in the thickness direction, the film according to the embodiment of the present invention may be formed on another support other than a support on which the color filter is formed, or another member (for example, a microlens or a planarizing layer) constituting a solid image pickup element may be interposed between the film according to the embodiment of the present invention and the color filter.

The film according to the embodiment of the present invention can be used in various devices including a solid image pickup element such as a charge coupled device (CCD) or a complementary metal-oxide semiconductor (CMOS), an infrared sensor, or an image display device.

<Film Forming Method>

Next, a film forming method according to the embodiment of the present invention will be described. The film according to the embodiment of the present invention can be formed through a step of applying the composition according to the embodiment of the present invention to a support.

In the film forming method according to the embodiment of the present invention, it is preferable that the composition is applied to a support. Examples of the support include a substrate formed of a material such as silicon, non-alkali glass, soda glass, PYREX (registered trade name) glass, or quartz glass. For example, an organic film or an inorganic film may be formed on the substrate. Examples of a material of the organic film include the above-described transparent resin. In addition, as the support, a substrate formed of the above-described resin can also be used. In addition, a charge coupled device (CCD), a complementary metal-oxide semiconductor (CMOS), a transparent conductive film, or the like may be formed on the support. In addition, a black matrix that separates pixels from each other may be formed on the support. In addition, optionally, an undercoat layer may be provided on the support to improve adhesiveness with a layer above the support, to prevent diffusion of materials, or to make a surface of the substrate flat. In addition, in a case where a glass substrate is used as the support, it is preferable that an inorganic film is formed on the glass substrate or the glass substrate may be dealkalized to be used. According to this aspect, a film in which the occurrence of foreign matter is suppressed can be easily formed.

As a method of applying the composition, a well-known method can be used. Examples of the well-known method include: a drop casting method; a slit coating method; a spray coating method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprint lithography method. The application method using an ink jet method is not particularly limited, and examples thereof include a method (in particular, pp. 115 to 133) described in “Extension of Use of Ink Jet—Infinite Possibilities in Patent-” (February, 2005, S.B. Research Co., Ltd.) and methods described in JP2003-262716A, JP2003-185831A, JP2003-261827A, JP2012-126830A, and JP2006-169325A.

A composition layer formed by applying the composition may be dried (pre-baked). In a case where a pattern is formed through a low-temperature process, pre-baking is not necessarily performed. In a case where pre-baking is performed, the pre-baking temperature is preferably 150° C. or lower, more preferably 120° C. or lower, and still more preferably 110° C. or lower. The lower limit is, for example, 50° C. or higher or 80° C. or higher. By setting the pre-baking temperature to be 150° C. or lower, the characteristics can be effectively maintained, for example, even in a case where a photoelectric conversion film of an image sensor is formed of an organic material.

The pre-baking time is preferably 10 to 3000 seconds, more preferably 40 to 2500 seconds, and still more preferably 80 to 220 seconds. Drying can be performed using a hot plate, an oven, or the like.

The film forming method according to the embodiment of the present invention may further include a step of forming a pattern. Examples of a pattern forming method include a pattern forming method using a photolithography method and a pattern forming method using a dry etching method. In a case where the film according to the embodiment of the present invention is used as a flat film, the step of forming a pattern is not necessarily performed. Hereinafter, the step of forming a pattern will be described in detail.

(Case where Pattern is Formed Using Photolithography Method)

It is preferable that the pattern forming method using a photolithography method includes: a step (exposure step) of exposing the composition layer, which is formed by applying the composition according to the embodiment of the present invention, in a pattern shape; and a step (development step) of forming a pattern by removing a non-exposed portion of the composition layer for development. Optionally, the pattern forming method may further include a step (post-baking step) of baking the developed pattern. Hereinafter, the respective steps will be described.

<<Exposure Step>>

In the exposure step, the composition layer is exposed in a pattern shape. For example, the composition layer can be exposed in a pattern shape using an exposure device such as a stepper through a mask having a predetermined mask pattern. As a result, an exposed portion can be cured. As radiation (light) used during the exposure, ultraviolet rays such as g-rays or i-rays are preferable, and i-rays are more preferable. The irradiation dose (exposure dose) is preferably 0.03 to 2.5 J/cm², more preferably 0.05 to 1.0 J/cm², and most preferably 0.08 to 0.5 J/cm². The oxygen concentration during exposure can be appropriately selected. The exposure may be performed not only in air but also in a low-oxygen atmosphere having an oxygen concentration of 19 vol % or lower (for example, 15 vol %, 5 vol %, or substantially 0 vol %) or in a high-oxygen atmosphere having an oxygen concentration of higher than 21 vol % (for example, 22 vol %, 30 vol %, or 50 vol %). In addition, the exposure illuminance can be appropriately set and typically can be selected in a range of 1000 W/m² to 100000 W/m² (for example, 5000 W/m², 15000 W/m², or 35000 W/m²). Conditions of the oxygen concentration and conditions of the exposure illuminance may be appropriately combined. For example, conditions are oxygen concentration: 10 vol % and illuminance: 10000 W/m², or oxygen concentration: 35 vol % and illuminance: 20000 W/m².

<<Development Step>>

Next, a pattern is formed by removing a non-exposed portion of the exposed composition layer by development. The non-exposed portion of the composition layer can be removed by development using a developer. As a result, a non-exposed portion of the composition layer in the exposure step is eluted into the developer, and only the photocured portion remains on the support. As the developer, an alkali developer which does not cause damages to a solid image pickup element as a substrate, a circuit or the like is desired. For example, the temperature of the developer is preferably 20° C. to 30° C. The development time is preferably 20 to 180 seconds. In addition, in order to further improve residue removing properties, a step of shaking the developer off per 60 seconds and supplying a new developer may be repeated multiple times.

Examples of the alkaline agent used as the developer include: an organic alkaline compound such as ammonia water, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, benzyltrimethylammonium hydroxide, dimethyl bis(2-hydroxyethyl)ammonium hydroxide, choline, pyrrole, piperidine, or 1,8-diazabicyclo[5.4.0]-7-undecene; and an inorganic alkaline compound such as sodium hydroxide, potassium hydroxide, sodium carbonate, sodium bicarbonate, sodium silicate, or sodium metasilicate. As the developer, an alkaline aqueous solution in which the above alkaline agent is diluted with pure water is preferably used. A concentration of the alkaline agent in the alkaline aqueous solution is preferably 0.001 to 10 mass % and more preferably 0.01 to 1 mass %. In addition, a surfactant may be used as the developer. Examples of the surfactant include the surfactants described above regarding the composition. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In a case where a developer including the alkaline aqueous solution is used, it is preferable that the layer is rinsed with pure water after development.

After the development, the film can also be dried and then heated (post-baking). Post-baking is a heat treatment which is performed after development to completely cure the film. In a case where post-baking is performed, for example, the post-baking temperature is preferably 100° C. to 240° C. From the viewpoint of curing the film, the post-baking temperature is more preferably 200° C. to 230° C. In addition, in a case where an organic electroluminescence (organic EL) element is used as a light-emitting light source, or in a case where a photoelectric conversion film of an image sensor is formed of an organic material, the post-baking temperature is preferably 150° C. or lower, more preferably 120° C. or lower, still more preferably 100° C. or lower, and still more preferably 90° C. or lower. The lower limit is, for example, 50° C. or higher. The film after the development is post-baked continuously or batchwise using heating means such as a hot plate, a convection oven (hot air circulation dryer), a high-frequency heater under the above-described conditions. In addition, in a case where a pattern is formed through a low-temperature process, post-baking is not necessarily performed.

(Case where Pattern is Formed Using Dry Etching Method)

The formation of a pattern using a dry etching method can be performed using a method including: applying the composition according to the embodiment of the present invention to a support or the like to form a composition layer; curing the composition layer to form a cured composition layer; forming a patterned photoresist layer on the cured composition layer; and dry-etching the cured composition layer with etching gas by using the patterned photoresist layer as a mask. It is preferable that pre-baking is further performed in order to form the photoresist layer. The details of the pattern formation using the dry etching method can be found in paragraphs “0010” to “0067” of JP2013-064993A, the content of which is incorporated herein by reference.

The pattern forming method according to the embodiment of the present invention may further include:

a step of forming a pattern (pixel) of a film formed of the composition according to the embodiment of the present invention using the above-described method and subsequently forming a coloring composition layer on the obtained pattern using a coloring composition including a chromatic colorant; and

a step of forming a pattern by exposing the coloring composition layer from the coloring composition layer side and subsequently developing the exposed coloring composition layer. According to this configuration, a laminate in which the pattern (colored pixel) of the coloring film is formed on the pattern (pixel) of the film formed of the composition according to the embodiment of the present invention can be formed.

In the step of forming the coloring composition layer, the coloring composition layer can be formed by applying the coloring composition to the pattern (pixel) of the film formed of the composition according to the embodiment of the present invention. Examples of a method of applying the coloring composition include the methods described above regarding the step of forming the composition layer.

Examples of an exposure method and a development method of the coloring composition layer include the methods described above regarding the exposure step and the development step. A heating treatment (post-baking) may be further performed on the developed coloring composition layer. For example, the post-baking temperature is preferably 180° C. to 260° C. The lower limit is preferably 180° C. or higher, more preferably 190° C. or higher, and still more preferably 200° C. or higher. The upper limit is preferably 260° C. or lower, more preferably 240° C. or lower, and still more preferably 220° C. or lower.

<Optical Filter>

Next, an optical filter according to the embodiment of the present invention will be described. The optical filter according to the embodiment of the present invention includes the film according to the embodiment of the present invention. Examples of the optical filter include a near infrared cut filter and an infrared transmitting filter. In the present invention, “near infrared cut filter” refers to a filter that allows transmission of light (visible light) in the visible range and shields at least a part of light (near infrared light) in the near infrared range. The near infrared cut filter may be a filter that allows transmission of light in the entire wavelength range of the visible range, or may be a filter that allows transmission of light in a specific wavelength range of the visible range and shields light in another specific wavelength range of the visible range. In addition, in the present invention, a color filter refers to a filter that allows transmission of light in a specific wavelength range of the visible range and shields light in another specific wavelength range of the visible range. In addition, in the present invention, “infrared transmitting filter” refers to a filter that shields visible light and allows transmission of at least a part of near infrared light.

In a case where the optical filter according to the embodiment of the present invention is used as an infrared transmitting filter, examples of the infrared transmitting filter include a filter that shields visible light and allows transmission of light in a wavelength range of 900 nm or longer.

In the optical filter, the thickness of the film according to the embodiment of the present invention (layer formed of the composition) can be appropriately adjusted according to the purpose. The thickness is preferably 20 μm or less, more preferably 10 μm or less, and still more preferably 5 μm or less. For example, the lower limit is preferably 0.1 μm or more, more preferably 0.2 μm or more, and still more preferably 0.3 μm or more.

In a case where the optical filter according to the embodiment of the present invention is used as a near infrared cut filter, the optical filter may further include, for example, a layer containing copper, a dielectric multi-layer film, or an ultraviolet absorbing layer in addition to the film according to the embodiment of the present invention. By further including the layer containing copper and/or the dielectric multi-layer film, the near infrared cut filter having a viewing angle and excellent infrared shielding properties can be easily obtained. In addition, by including the ultraviolet absorbing layer, the near infrared cut filter having excellent ultraviolet shielding properties can be obtained. The details of the ultraviolet absorbing layer can be found in paragraphs “0040” to “0070” and paragraphs “0119” to “0145” of WO2015/099060, the content of which is incorporated herein by reference. The details of the dielectric multi-layer film can be found in paragraphs “0255” to “0259” of JP2014-041318A As the layer containing copper, a glass substrate (copper-containing glass substrate) formed of glass containing copper, or a layer (copper complex-containing layer) containing a copper complex may also be used. Examples of the copper-containing glass substrate include a phosphate glass including copper and a fluorophosphate glass including copper. Examples of a commercially available product of the copper-containing glass include NF-50 (manufactured by AGC Techno Glass Co., Ltd.), BG-60 and BG-61 (both of which are manufactured by Schott AG), and CD5000 (manufactured by Hoya Corporation).

The optical filter according to the embodiment of the present invention can be used in various devices including a solid image pickup element such as a charge coupled device (CCD) or a complementary metal-oxide semiconductor (CMOS), an infrared sensor, or an image display device.

In addition, it is also preferable that the optical filter according to the embodiment of the present invention includes a pixel of the cured film according to the embodiment of the present invention and a pixel selected from the group consisting of a red pixel, a green pixel, a blue pixel, a magenta pixel, a yellow pixel, a cyan pixel, a black pixel, and an achromatic pixel.

It is also preferable that the optical cut filter according to the present invention includes: a pixel (pattern) of the film that is formed using the composition according to the embodiment of the present invention; and a pixel (pattern) selected from a red pixel, a green pixel, a blue pixel, a magenta pixel, a yellow pixel, a cyan pixel, a black pixel, or an achromatic pixel.

<Solid Image Pickup Element>

A solid image pickup element according to the embodiment of the present invention includes the film according to the embodiment of the present invention. The configuration of the solid image pickup element according to the embodiment of the present invention is not particularly limited as long as it includes the film according to the embodiment of the present invention and functions as a solid image pickup element. For example, the following configuration can be adopted.

The solid image pickup element includes a plurality of photodiodes and transfer electrodes on the support, the photodiodes constituting a light receiving area of the solid image pickup element, and the transfer electrode being formed of polysilicon or the like. In the solid image pickup element, a light shielding film formed of tungsten or the like which has openings through only light receiving sections of the photodiodes is provided on the photodiodes and the transfer electrodes, a device protective film formed of silicon nitride or the like is formed on the light shielding film so as to cover the entire surface of the light shielding film and the light receiving sections of the photodiodes, and the film according to the embodiment of the present invention is formed on the device protective film. Further, a configuration in which light collecting means (for example, a microlens; hereinafter, the same shall be applied) is provided above the device protective film and below the film according to the embodiment of the present invention (on a side thereof close the support), or a configuration in which light collecting means is provided on the film according to the embodiment of the present invention may be adopted. In addition, the color filter may have a structure in which a film which forms each pixel is embedded in a space which is partitioned in, for example, a lattice shape by a partition wall. In this case, it is preferable that the partition wall has a lower refractive index than each pixel. Examples of an imaging device having such a structure include a device described in JP2012-227478A and JP2014-179577A.

<Image Display Device>

An image display device according to the embodiment of the present invention includes the film according to the embodiment of the present invention. Examples of the image display device include a liquid crystal display device or an organic electroluminescence (organic EL) display device. The definition and details of the image display device can be found in, for example, “Electronic Display Device (by Akiya Sasaki, Kogyo Chosakai Publishing Co., Ltd., 1990)” or “Display Device (Sumiaki Ibuki, Sangyo Tosho Co., Ltd.). In addition, the details of a liquid crystal display device can be found in, for example, “Next-Generation Liquid Crystal Display Techniques (Edited by Tatsuo Uchida, Kogyo Chosakai Publishing Co., Ltd., 1994)”. The liquid crystal display device to which the present invention is applicable is not particularly limited. For example, the present invention is applicable to various liquid crystal display devices described in “Next-Generation Liquid Crystal Display Techniques”. The image display device may include a white organic EL element. It is preferable that the white organic EL element has a tandem structure. The tandem structure of the organic EL element is described in, for example, JP2003-045676A, or pp. 326-328 of “Forefront of Organic EL Technology Development —Know-How Collection of High Brightness, High Precision, and Long Life” (Technical Information Institute, 2008). It is preferable that a spectrum of white light emitted from the organic EL element has high maximum emission peaks in a blue range (430 nm to 485 nm), a green range (530 nm to 580 nm), and a yellow range (580 nm to 620 nm). It is more preferable that the spectrum has a maximum emission peak in a red range (650 nm to 700 nm) in addition to the above-described emission peaks.

<Infrared Sensor>

An infrared sensor according to the embodiment of the present invention includes the film according to the embodiment of the present invention. The configuration of the infrared sensor is not particularly limited as long as it functions as an infrared sensor. Hereinafter, an embodiment of the infrared sensor used in the present invention will be described using the drawings.

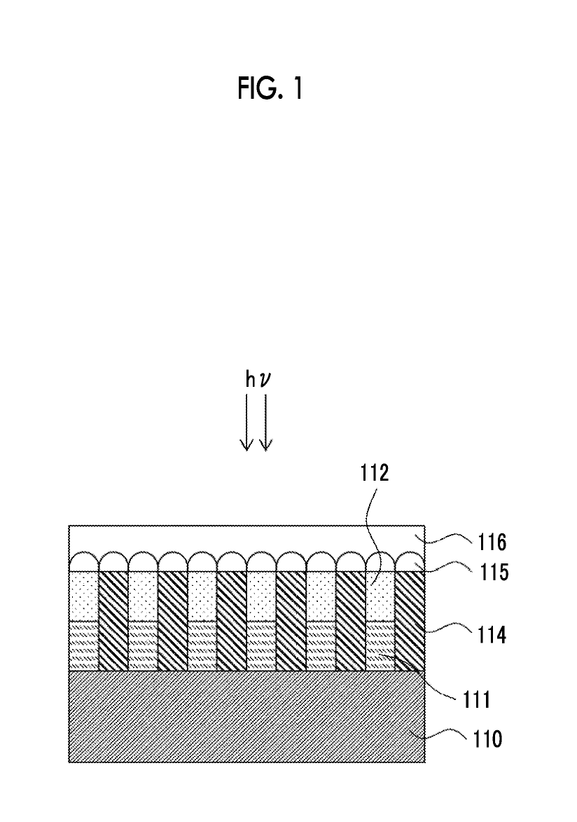

In FIG. 1, reference numeral 110 represents a solid image pickup element. In an imaging region provided on a solid image pickup element 110, near infrared cut filters 111 and infrared transmitting filters 114 are provided. In addition, color filters 112 are laminated on the near infrared cut filters 111. Microlenses 115 are disposed on an incidence ray hυ side of the color filters 112 and the infrared transmitting filters 114. A planarizing layer 116 is formed so as to cover the microlenses 115.

The near infrared cut filter 111 can be formed using the composition according to the embodiment of the present invention. Spectral characteristics of the near infrared cut filters 111 can be selected according to the emission wavelength of an infrared light emitting diode (infrared LED) to be used.

The color filters 112 is not particularly limited as long as pixels which allow transmission of light having a specific wavelength in a visible range and absorbs the light are formed therein, and well-known color filters of the related art for forming a pixel can be used. For example, pixels of red (R), green (G), and blue (B) are formed in the color filters. For example, the details of the color filters can be found in paragraphs “0214” to “0263” of JP2014-043556A, the content of which is incorporated herein by reference.

Characteristics of the infrared transmitting filters 114 can be selected according to the emission wavelength of the infrared LED to be used. For example, in a case where the emission wavelength of the infrared LED is 850 nm, a maximum value of a light transmittance of the infrared transmitting filter 114 in the thickness direction of the film in a wavelength range of 400 to 650 nm is preferably 30% or lower, more preferably 20% or lower, still more preferably 10% or lower and still more preferably 0.1% or lower. It is preferable that the transmittance satisfies the above-described conditions in the entire wavelength range of 400 to 650 nm.

A minimum value of a light transmittance of the infrared transmitting filter 114 in the thickness direction of the film in a wavelength range of 800 nm or longer (preferably 800 to 1300 nm) is preferably 70% or higher, more preferably 80% or higher, and still more preferably 90% or higher. It is preferable that the transmittance satisfies the above-described conditions in a part of a wavelength range of 800 nm or longer, and it is more preferable that the transmittance satisfies the above-described conditions at a wavelength corresponding to the emission wavelength of the infrared LED.

The thickness of the infrared transmitting filter 114 is preferably 100 μm or less, more preferably 15 μm or less, still more preferably 5 μm or less, and still more preferably 1 μm or less. The lower limit value is preferably 0.1 μm. In a case where the thickness is in the above-described range, the film can satisfy the above-described spectral characteristics.

A method of measuring the spectral characteristics, the thickness, and the like of the infrared transmitting filter 114 is as follows.

The thickness is obtained by measuring the thickness of the dried substrate including the film using a stylus surface profilometer (DEKTAK 150, manufactured by ULVAC Inc.).

The spectral characteristics of the film are values obtained by measuring the transmittance in a wavelength range of 300 to 1300 nm using a spectrophotometer (U-4100, manufactured by Hitachi High-Technologies Corporation).

In addition, for example, in a case where the emission wavelength of the infrared LED is 940 nm, it is preferable that a maximum value of a light transmittance of the infrared transmitting filter 114 in a thickness direction in a wavelength range of 450 to 650 nm is 20% or lower, that a light transmittance of the infrared transmitting filter 114 in the thickness direction at a wavelength of 835 nm is 20% or lower, and that a minimum value of a light transmittance of the infrared transmitting filter 114 in the thickness direction in a wavelength range of 1000 to 1300 nm is 70% or higher.

In the infrared sensor shown in FIG. 1, a near infrared cut filter (other near infrared cut filter) other than the near infrared cut filter 111 may be further disposed on the planarizing layer 116. As the other near infrared cut filter, for example, a layer containing copper and/or a dielectric multi-layer film may be provided. The details of the groups are as described above. In addition, as the other near infrared cut filter, a dual band pass filter may be used.

### EXAMPLES

Hereinafter, the present invention will be described in detail using examples. Materials, used amounts, ratios, treatment details, treatment procedures, and the like shown in the following examples can be appropriately changed within a range not departing from the scope of the present invention. Accordingly, the scope of the present invention is not limited to the following specific examples. Unless specified otherwise, “part(s)” and “%” represent “part(s) by mass” and “mass %”.

### Test Example 1

<Preparation of Composition>

Raw materials shown in the following tables were mixed with each other to prepare a composition. In the composition in which a dispersion was used as a raw material, the dispersion was prepared as follows.

A near infrared absorbing colorant, a pigment derivative, a dispersant, and a solvent described in “Dispersion” of the following tables were mixed with each other in part(s) by mass shown in “Dispersion” of the following tables, 230 parts by mass of zirconia beads having a diameter of 0.3 mm was further added thereto, the mixture was dispersed using a paint shaker for 5 hours, and the beads were separated by filtration. As a result, a dispersion was manufactured.

TABLE 1

| | Dispersion | | | | | | | | | | | | | | |
|---|---|---|---|---|---|---|---|---|---|---|---|---|---|---|---|
| | Near Infrared | | | | | | | | Near Infared | | | | | | |
| -. | Absorbing Colorant | | Pigment Derivative | | Dispersant | | Solvent | | Absorbing Colorant | | Resin | | Monomer | | Photointiator and |
| | | Parts(s) | | Parts(s) | | Parts(s) | | Parts(s) | | Parts(s) | | Parts(s) | | Parts(s) | Polycarboxylic |
| | | by | | by | | by | | by | | by | | by | | by | Acid |
| Name | Kind | Mass | Kind | Mass | Kind | Mass | Kind | Mass | Kind | Mass | Kind | Mass | Kind | Mass | Kind |
| Example 1 | A1 | 2.5 | B1 | 0.5 | C1 | 1.8 | J1 | 39 | — | | D1 | 5.5 | M1 | 6.4 | F1 |
| Example 2 | A1 | 2.5 | B1 | 0.5 | C1 | 1.8 | J1 | 39 | — | | D1 | 5.5 | M1 | 6.4 | F1 |
| Example 3 | A1 | 2.5 | B1 | 0.5 | C1 | 1.8 | J1 | 39 | — | | D1 | 5.5 | M1 | 6.4 | F1 |
| Example 4 | A1 | 2.5 | B1 | 0.5 | C1 | 1.8 | J1 | 39 | — | | D1 | 5.5 | M1 | 6.4 | F1 |
| Example 5 | A1 | 2.5 | B1 | 0.5 | C1 | 1.8 | J1 | 39 | — | | D1 | 5.5 | M1 | 6.4 | F1 |
| Example 6 | A1 | 2.5 | B1 | 0.5 | C1 | 1.8 | J1 | 39 | — | | D1 | 5.5 | M1 | 6.4 | F1 |
| Example 7 | A1 | 2.5 | B1 | 0.5 | C1 | 1.8 | J1 | 39 | — | | D1 | 5.5 | M1 | 6.4 | F1 |
| Example 8 | A1 | 2.5 | B1 | 0.5 | C1 | 1.8 | J1 | 39 | — | | D1 | 5.5 | M1 | 6.4 | F1 |
| Example 9 | A1 | 2.5 | B1 | 0.5 | C1 | 1.8 | J1 | 39 | — | | D1 | 5.5 | M1 | 6.4 | F1 |
| Example 10 | A1 | 2.5 | B1 | 0.5 | C1 | 1.8 | J1 | 39 | — | | D1 | 5.5 | M1 | 6.4 | F1 |
| Example 11 | A2 | 2.5 | B1 | 0.5 | C1 | 1.8 | J1 | 39 | — | | D1 | 5.5 | M1 | 6.4 | F1 |
| Example 12 | A12 | 2.5 | B4 | 0.5 | C1 | 1.8 | J1 | 39 | — | | D1 | 5.5 | M1 | 6.4 | F1 |
| Example 13 | A13 | 2.5 | B1 | 0.5 | C1 | 1.8 | J1 | 39 | — | | D1 | 5.5 | M1 | 6.4 | F1 |
| Example 14 | — | | — | | — | | — | | A3 | 3 | D1 | 7.3 | M1 | 6.4 | F1 |
| Example 15 | — | | — | | — | | — | | A4 | 3 | D1 | 7.3 | M1 | 6.4 | F1 |
| Example 16 | — | | — | | — | | — | | A5 | 3 | D1 | 7.3 | M1 | 6.4 | F1 |
| Example 17 | — | | — | | — | | — | | A6 | 3 | D1 | 7.3 | M1 | 6.4 | F1 |
| Example 18 | — | | — | | — | | — | | A7 | 3 | D1 | 7.3 | M1 | 6.4 | F1 |
| Example 19 | A1 + A2 | 1.25 + 0.25 | B1 | 0.5 | C1 | 1.8 | J1 | 39 | — | | D1 | 5.5 | M1 | 6.4 | F1 |
| Example 20 | A1 | 2.5 | B1 + B2 | 0.25 + 0.25 | C1 | 1.8 | J1 | 39 | — | | D1 | 5.5 | M1 | 6.4 | F1 |
| Example 21 | A1 | 2.5 | B1 | 0.5 | C1 + C2 | 0.9 + 0.9 | J1 | 39 | — | | D1 | 5.5 | M1 | 6.4 | F1 |
| Example 22 | A1 | 2.5 | B3 | 0.5 | C3 | 1.8 | J1 | 19.5 | — | | D1 | 5.5 | M1 | 6.4 | F1 |
| Example 23 | A1 | 1.25 | B1 | 0.25 | C1 | 0.9 | J1 | 39 | A3 | 1.5 | D1 | 6.4 | M1 | 6.4 | F1 |
| Example 24 | — | | — | | — | | — | | A6 + A7 | 1.5 + 1.5 | D1 | 7.3 | M1 | 6.4 | F1 |
| Example 25 | A1 | 2.5 | B1 | 0.5 | C1 | 1.8 | J1 | 39 | — | | D2 | 5.5 | M1 | 6.4 | F1 |
| Example 26 | A1 | 2.5 | B1 | 0.5 | C1 | 1.8 | J1 | 39 | — | | D3 | 5.5 | M1 | 6.4 | F1 |
| Example 27 | A1 | 2.5 | B1 | 0.5 | C1 | 1.8 | J1 | 39 | — | | D1 + D3 | 2.75 + 2.75 | M1 | 6.4 | F1 |
| Example 28 | A1 | 2.5 | B1 | 0.5 | C1 | 1.8 | J1 | 39 | — | | D1 | 5.5 | M2 | 6.4 | F1 |
| Example 29 | A1 | 2.5 | B1 | 0.5 | C1 | 1.8 | J1 | 39 | — | | D1 | 5.5 | M3 | 6.4 | F1 |
| Example 30 | A1 | 2.5 | B1 | 0.5 | C1 | 1.8 | J1 | 39 | — | | D1 | 5.5 | M2 + M3 | 3.2 + 3.2 | F1 |
| Example 31 | A1 | 2.5 | B1 | 0.5 | C1 | 1.8 | J1 | 39 | — | | D1 | 5.5 | M1 | 6.4 | F2 |
| Example 32 | A1 | 2.5 | B1 | 0.5 | C1 | 1.8 | J1 | 39 | — | | D1 | 5.5 | M1 | 6.4 | F3 |
| Example 33 | A1 | 2.5 | B1 | 0.5 | C1 | 1.8 | J1 | 39 | — | | D1 | 5.5 | M1 | 6.4 | F1 + F3 |
| Example 34 | A1 | 2.5 | B1 | 0.5 | C1 | 1.8 | J1 | 39 | — | | D1 | 5.5 | M1 | 6.4 | F1 |
| Example 35 | A1 | 2.5 | B1 | 0.5 | C1 | 1.8 | J1 | 39 | — | | D1 | 5.5 | M1 | 6.4 | F1 |
| Example 36 | A1 | 2.5 | B1 | 0.5 | C1 | 1.8 | J1 | 39 | — | | D1 | 5.5 | M1 | 6.4 | F1 |
| Example 37 | A1 | 2.5 | B1 | 0.5 | C1 | 1.8 | J1 | 39 | — | | D1 | 5.5 | M3 | 5.4 | F1 |
| Example 38 | A1 | 2.5 | B1 | 0.5 | C1 | 1.8 | J1 | 39 | — | | D1 | 5.5 | M3 | 5.4 | F1 |

| | Photointiator and | | | | | | | | | | | | |
|---|---|---|---|---|---|---|---|---|---|---|---|---|---|
| | Polycarboxylic | | | | | Polymerization | | | | | | | |
| | Acid | Ultraviolet Absorber | | Surfactant | | Inhibitor | | Antioxidant | | Epoxy Resin | | Solvent | |
| | Parts(s) | | Parts(s) | | Parts(s) | | Parts(s) | | Parts(s) | | Parts(s) | | Parts(s) |
| | by | | by | | by | | by | | by | | by | | by |
| | Mass | Kind | Mass | Kind | Mass | Kind | Mass | Kind | Mass | Kind | Mass | Kind | Mass |
| Example 1 | 1 | UV1 | 1.6 | W1 | 0.025 | H1 | 0.003 | I1 | 0.2 | — | | J1 | 41.472 |
| Example 2 | 1 | UV1 | 1.6 | W2 | 0.025 | H1 | 0.003 | I1 | 0.2 | — | | J1 | 41.472 |
| Example 3 | 1 | UV1 | 1.6 | W3 | 0.025 | H1 | 0.003 | I1 | 0.2 | — | | J1 | 41.472 |
| Example 4 | 1 | UV1 | 1.6 | W1 + W2 | 0.013 + 0.013 | H1 | 0.003 | I1 | 0.2 | — | | J1 | 41.471 |
| Example 5 | 1 | UV1 | 1.6 | W1 | 0.025 | H1 | 0.003 | I2 | 0.2 | — | | J1 | 41.472 |
| Example 6 | 1 | UV1 | 1.6 | W1 | 0.025 | H1 | 0.003 | I3 | 0.2 | — | | J1 | 41.472 |
| Example 7 | 1 | UV1 | 1.6 | W1 | 0.025 | H1 | 0.003 | I6 | 0.2 | — | | J1 | 41.472 |
| Example 8 | 1 | UV1 | 1.6 | W1 | 0.025 | H1 | 0.003 | I1 + I2 | 0.1 + 0.1 | — | | J1 | 41.472 |
| Example 9 | 1 | UV1 | 1.6 | W1 | 0.025 | H1 | 0.003 | I2 + I3 | 0.1 + 0.1 | — | | J1 | 41.472 |
| Example 10 | 1 | UV1 | 1.6 | W1 | 0.025 | H1 | 0.003 | I3 + I1 | 0.1 + 0.1 | — | | J1 | 41.472 |
| Example 11 | 1 | UV1 | 1.6 | W1 | 0.025 | H1 | 0.003 | I1 | 0.2 | — | | J1 | 41.472 |
| Example 12 | 1 | UV1 | 1.6 | W1 | 0.025 | H1 | 0.003 | I1 | 0.2 | — | | J1 | 41.472 |
| Example 13 | 1 | UV1 | 1.6 | W1 | 0.025 | H1 | 0.003 | I1 | 0.2 | — | | J1 | 41.472 |
| Example 14 | 1 | UV1 | 1.6 | W1 | 0.025 | H1 | 0.003 | I1 | 0.2 | — | | J1 | 80.472 |
| Example 15 | 1 | UV1 | 1.6 | W1 | 0.025 | H1 | 0.003 | I1 | 0.2 | — | | J1 | 80.472 |
| Example 16 | 1 | UV1 | 1.6 | W1 | 0.025 | H1 | 0.003 | I1 | 0.2 | — | | J1 | 80.472 |
| Example 17 | 1 | UV1 | 1.6 | W1 | 0.025 | H1 | 0.003 | I1 | 0.2 | — | | J1 | 80.472 |
| Example 18 | 1 | UV1 | 1.6 | W1 | 0.025 | H1 | 0.003 | I1 | 0.2 | — | | J1 | 80.472 |
| Example 19 | 1 | UV1 | 1.6 | W1 | 0.025 | H1 | 0.003 | I1 | 0.2 | — | | J1 | 41.472 |
| Example 20 | 1 | UV1 | 1.6 | W1 | 0.025 | H1 | 0.003 | I1 | 0.2 | — | | J1 | 41.472 |
| Example 21 | 1 | UV1 | 1.6 | W1 | 0.025 | H1 | 0.003 | I1 | 0.2 | — | | J1 | 41.742 |
| Example 22 | 1 | UV1 | 1.6 | W1 | 0.025 | H1 | 0.003 | I1 | 0.2 | — | | J1 | 41.472 |
| Example 23 | 1 | UV1 | 1.6 | W1 | 0.025 | H1 | 0.003 | I1 | 0.2 | — | | J1 | 60.972 |
| Example 24 | 1 | UV1 | 1.6 | W1 | 0.025 | H1 | 0.003 | I1 | 0.2 | — | | J1 | 80.472 |
| Example 25 | 1 | UV1 | 1.6 | W1 | 0.025 | H1 | 0.003 | I1 | 0.2 | — | | J1 | 41.472 |
| Example 26 | 1 | UV1 | 1.6 | W1 | 0.025 | H1 | 0.003 | I1 | 0.2 | — | | J1 | 41.472 |
| Example 27 | 1 | UV1 | 1.6 | W1 | 0.025 | H1 | 0.003 | I1 | 0.2 | — | | J1 | 41.472 |
| Example 28 | 1 | UV1 | 1.6 | W1 | 0.025 | H1 | 0.003 | I1 | 0.2 | — | | J1 | 41.472 |
| Example 29 | 1 | UV1 | 1.6 | W1 | 0.025 | H1 | 0.003 | I1 | 0.2 | — | | J1 | 41.472 |
| Example 30 | 1 | UV1 | 1.6 | W1 | 0.025 | H1 | 0.003 | I1 | 0.2 | — | | J1 | 41.472 |
| Example 31 | 1 | UV1 | 1.6 | W1 | 0.025 | H1 | 0.003 | I1 | 0.2 | — | | J1 | 41.472 |
| Example 32 | 1 | UV1 | 1.6 | W1 | 0.025 | H1 | 0.003 | I1 | 0.2 | — | | J1 | 41.472 |
| Example 33 | 0.5 + 0.5 | UV1 | 1.6 | W1 | 0.025 | H1 | 0.003 | I1 | 0.2 | — | | J1 | 41.472 |
| Example 34 | 1 | UV2 | 1.6 | W1 | 0.025 | H1 | 0.003 | I1 | 0.2 | — | | J1 | 41.472 |
| Example 35 | 1 | UV3 | 1.6 | W1 | 0.025 | H1 | 0.003 | I1 | 0.2 | — | | J1 | 41.472 |
| Example 36 | 1 | UV1 + UV2 | 0.8 + 0.8 | W1 | 0.025 | H1 | 0.003 | I1 | 0.2 | — | | J1 | 41.472 |
| Example 37 | 1 | UV1 | 1.6 | W1 | 0.025 | H1 | 0.003 | I1 | 0.2 | EP1 | 1 | J1 | 41.472 |
| Example 38 | 1 | UV1 | 1.6 | W1 | 0.025 | H1 | 0.003 | I1 | 0.2 | EP2 | 1 | J1 | 41.472 |

TABLE 2

| | Dispersion | | | | | | | | | | | | | | |
|---|---|---|---|---|---|---|---|---|---|---|---|---|---|---|---|
| | Near Infrared | | | | | | | | Near Infrared | | | | | | |
| | Absorbing Colorant | | Pigment Derivative | | Dispersant | | Solvent | | Absorbing Colorant | | Resin | | Monomer | | Photoinitiator and |
| | | Part(s) by | | Part(s) by | | Part(s) by | | Part(s) by | | Part(s) by | | Part(s) by | | Part(s) by | Polycarboxylic Acid |
| Name | Kind | Mass | Kind | Mass | Kind | Mass | Kind | Mass | Kind | Mass | Kind | Mass | Kind | Mass | Kind |
| Example 39 | A1 | 2.5 | B1 | 0.5 | C1 | 1.8 | J1 | 39 | — | | D1 | 4.2 | M1 | 7.7 | F1 |
| Example 40 | A1 | 2.5 | B1 | 0.5 | C1 | 1.8 | J1 | 39 | — | | D1 | 6.8 | M1 | 5.1 | F1 |
| Example 41 | A1 | 3.125 | B1 | 0.625 | C1 | 2.25 | J1 | 48.75 | — | | D1 | 4.72 | M1 | 5.98 | F1 |
| Example 42 | A1 | 1.56 | B1 | 0.313 | C1 | 1.125 | J1 | 24.4 | — | | D1 | 6.918 | M1 | 6.784 | F1 |
| Example 43 | A1 | 2.5 | B1 | 0.5 | C1 | 1.8 | J1 | 39 | — | | D1 | 5.45 | M1 | 6.35 | F1 |
| Example 44 | A1 | 2.5 | B1 | 0.5 | C1 | 1.8 | J1 | 39 | — | | D1 | 5.55 | M1 | 6.45 | F1 |
| Example 45 | A1 | 2.5 | B1 | 0.5 | C1 | 1.8 | J1 | 39 | — | | D1 | 5.036 | M1 | 6.389 | F1 |
| Example 46 | A1 | 2.5 | B1 | 0.5 | C1 | 1.8 | J1 | 39 | — | | D1 | 5.512 | M1 | 6.4 | F1 |
| Example 47 | A1 | 0.42 | B1 | 0.084 | C1 | 0.3 | J1 | 6.5 | — | | — | | — | | F4 |
| Example 48 | A1 | 2.5 | B1 | 0.5 | C1 | 1.8 | J1 | 39 | — | | D1 | 5.5 | M4 | 6.4 | F4 |
| Example 49 | — | | — | | — | | — | | A5 | 0.5 | — | | — | | F4 |
| Example 50 | — | | — | | — | | — | | A6 | 0.5 | — | | — | | F4 |
| Example 51 | A1 | 0.21 | B1 | 0.042 | C1 | 0.15 | J1 | 3.25 | A3 | 1.5 | — | | — | | F4 |
| Example 52 | — | | — | | — | | — | | A6 + A7 | 0.33 + 0.17 | — | | — | | F4 |
| Example 53 | A1 | 0.037 | B1 | 0.007 | C1 | 0.026 | J1 | 0.572 | — | | D4 | 39.2 | — | | — |
| Example 54 | — | | — | | — | | — | | A8 | 0.044 | D4 | 39.2 | — | | — |
| Example 55 | — | | — | | — | | — | | A9 | 0.044 | D4 | 39.2 | — | | — |
| Example 56 | — | | — | | — | | — | | A10 | 0.044 | D4 | 39.2 | — | | — |
| Example 57 | A1 | 0.019 | B1 | 0.004 | C1 | 0.013 | J1 | 0.276 | A3 | 0.022 | D4 | 39.2 | — | | — |
| Example 58 | — | | — | | — | | — | | A8 + | 0.012 + | D4 | 39.2 | — | | — |
| | | | | | | | | | A9 + | 0.020 + | | | | | |
| | | | | | | | | | A10 | 0.012 | | | | | |
| Example 59 | A1 | 0.83 | B1 | 0.17 | C1 | 1.5 | J1 | 32.5 | — | | D6 | 13.8 | M5 | 5.4 | F5 |
| Example 60 | — | | — | | — | | — | | A11 | 1 | D6 | 15.3 | M5 | 5.4 | F5 |
| Example 61 | A1 | 0.42 | B1 | 0.09 | C1 | 0.75 | J1 | 16.3 | A11 | 1 | D6 | 14.55 | M5 | 5.4 | F5 |
| Example 62 | — | | — | | — | | — | | A7 + A11 | 0.5 + 0.5 | D6 | 15.3 | M5 | | — |
| Example 63 | A1 | 0.037 | B1 | 0.007 | C1 | 0.026 | J1 | 0.572 | — | | D5 | 39.2 | — | | — |
| Example 64 | — | | — | | — | | — | | A8 | 0.044 | D5 | 39.2 | — | | — |
| Example 65 | — | | — | | — | | — | | A9 | 0.044 | D5 | 39.2 | — | | — |
| Example 66 | — | | — | | — | | — | | A10 | 0.044 | D5 | 39.2 | — | | — |
| Example 67 | A1 | 0.019 | B1 | 0.004 | C1 | 0.013 | J1 | 0.276 | A3 | 0.022 | D5 | 39.2 | — | | — |
| Example 68 | — | | — | | — | | — | | A8 + | 0.012 + | D5 | 39.2 | — | | — |
| | | | | | | | | | A9 + | 0.020 + | | | | | |
| | | | | | | | | | A10 | 0.012 | | | | | |
| Comparative | A1 | 2.5 | B1 | 0.5 | C1 | 1.8 | J1 | 39 | — | | D1 | 5.7 | M1 | 6.4 | F1 |
| Example 1 | | | | | | | | | | | | | | | |
| Comparative | A1 | 2.5 | B1 | 0.5 | C1 | 1.8 | J1 | 39 | — | | D1 | 5.525 | M1 | 6.4 | F1 |
| Example 2 | | | | | | | | | | | | | | | |
| Comparative | A1 | 2.5 | B1 | 0.5 | C1 | 1.8 | J1 | 39 | — | | D1 | 5.5 | M1 | 6.4 | F1 |
| Example 3 | | | | | | | | | | | | | | | |
| Comparative | A1 | 2.5 | B1 | 0.5 | C1 | 1.8 | J1 | 39 | — | | D1 | 5.5 | M1 | 6.4 | F1 |
| Example 4 | | | | | | | | | | | | | | | |
| Comparative | A1 | 2.5 | B1 | 0.5 | C1 | 1.8 | J1 | 39 | — | | D1 | 5.725 | M1 | 6.4 | F1 |
| Example 5 | | | | | | | | | | | | | | | |

| | Photoinitiator and | | | | | Polymerization | | | | | | | |
|---|---|---|---|---|---|---|---|---|---|---|---|---|---|
| | Polycarboxylic Acid | Ultraviolet Absorber | | Surfactant | | Inhibitor | | Antioxidant | | Epoxy Resin | | Solvent | |
| | Part(s) by | | Part(s) by | | Part(s) by | | Part(s) by | | Part(s) by | | Part(s) by | | Part(s) by |
| Name | Mass | Kind | Mass | Kind | Mass | Kind | Mass | Kind | Mass | Kind | Mass | Kind | Mass |
| Example 39 | 1 | UV1 | 1.6 | W1 | 0.025 | H1 | 0.003 | I1 | 0.2 | | | J1 | 41.472 |
| Example 40 | 1 | UV1 | 1.6 | W1 | 0.025 | H1 | 0.003 | I1 | 0.2 | | | J1 | 41.472 |
| Example 41 | 1 | UV1 | 1.6 | W1 | 0.025 | H1 | 0.003 | I1 | 0.2 | | | J1 | 31.722 |
| Example 42 | 1 | UV1 | 1.6 | W1 | 0.025 | H1 | 0.003 | I1 | 0.2 | | | J1 | 56.072 |
| Example 43 | 1 | UV1 | 1.6 | W1 | 0.025 | H1 | 0.003 | I1 | 0.3 | | | J1 | 41.472 |
| Example 44 | 1 | UV1 | 1.6 | W1 | 0.025 | H1 | 0.003 | I1 | 0.1 | | | J1 | 41.472 |
| Example 45 | 1 | UV1 | 1.6 | W1 | 0.5 | H1 | 0.003 | I1 | 0.2 | | | J1 | 41.472 |
| Example 46 | 1 | UV1 | 1.6 | W1 | 0.013 | H1 | 0.003 | I1 | 0.2 | | | J1 | 41.472 |
| Example 47 | 0.33 | — | | W1 | 0.016 | — | | I1 | 0.33 | EP3 | 32.64 | J1 | 59.38 |
| Example 48 | 1 | — | | W1 | 0.025 | H1 | 0.003 | I1 | 0.2 | — | | J1 | 43.072 |
| Example 49 | 0.33 | — | | W1 | 0.016 | — | | I1 | 0.33 | EP3 | 32.94 | J1 | 65.884 |
| Example 50 | 0.33 | — | | W1 | 0.016 | — | | I1 | 0.33 | EP3 | 32.94 | J1 | 65.884 |
| Example 51 | 0.33 | — | | W1 | 0.016 | — | | I1 | 0.33 | EP3 | 32.79 | J1 | 61.382 |
| Example 52 | 0.33 | — | | W1 | 0.016 | — | | I1 | 0.33 | EP3 | 32.94 | J1 | 65.884 |
| Example 53 | | — | | W1 | 0.015 | — | | I1 | 0.01 | — | | J1 | 60.133 |
| Example 54 | | — | | W1 | 0.015 | — | | I1 | 0.01 | — | | J1 | 60.731 |
| Example 55 | | — | | W1 | 0.015 | — | | I1 | 0.01 | — | | J1 | 60.731 |
| Example 56 | | — | | W1 | 0.015 | — | | I1 | 0.01 | — | | J1 | 60.731 |
| Example 57 | | — | | W1 | 0.015 | — | | I1 | 0.01 | — | | J1 | 60.441 |
| Example 58 | | — | | W1 | 0.015 | — | | I1 | 0.01 | — | | J1 | 60.731 |
| Example 59 | 0.34 | — | | W4 | 0.02 | — | | I1 | 0.08 | — | | J2 | 45.36 |
| Example 60 | 0.34 | — | | W4 | 0.02 | — | | I1 | 0.08 | — | | J2 | 77.86 |
| Example 61 | 0.34 | — | | W4 | 0.02 | — | | I1 | 0.08 | — | | J2 | 61.05 |
| Example 62 | 0.34 | — | | W4 | 0.02 | — | | I1 | 0.08 | — | | J2 | 60.731 |
| Example 63 | | — | | W1 | 0.015 | — | | I1 | 0.01 | — | | J3 | 60.133 |
| Example 64 | | — | | W1 | 0.015 | — | | I1 | 0.01 | — | | J3 | 60.731 |
| Example 65 | | — | | W1 | 0.015 | — | | I1 | 0.01 | — | | J3 | 60.731 |
| Example 66 | | — | | W1 | 0.015 | — | | I1 | 0.01 | — | | J3 | 60.731 |
| Example 67 | | — | | W1 | 0.015 | — | | I1 | 0.01 | — | | J3 | 60.441 |
| Example 68 | | — | | W1 | 0.015 | — | | I1 | 0.01 | — | | J3 | 60.731 |
| Comparative | 1 | UV1 | 1.6 | W1 | 0.025 | H1 | 0.003 | | | — | | J1 | 41.472 |
| Example 1 | | | | | | | | | | | | | |
| Comparative | 1 | UV1 | 1.6 | | | H1 | 0.003 | I2 | 0.2 | — | | J1 | 41.472 |
| Example 2 | | | | | | | | | | | | | |
| Comparative | 1 | UV1 | 1.6 | W1 | 0.025 | H1 | 0.003 | I4 | 0.2 | — | | J1 | 41.472 |
| Example 3 | | | | | | | | | | | | | |
| Comparative | 1 | UV1 | 1.6 | W1 | 0.025 | H1 | 0.003 | I5 | 0.2 | — | | J1 | 41.472 |
| Example 4 | | | | | | | | | | | | | |
| Comparative | 1 | UV1 | 1.6 | | | H1 | 0.003 | | | — | | J1 | 41.472 |
| Example 5 | | | | | | | | | | | | | |

The raw materials shown above in the table are as follows.

(Near Infrared Absorbing Colorant)

A1 to A5, A12, A13: compounds having the following structures. In the following formulae, Me represents a methyl group, Ph represents a phenyl group, and EH represents an ethylhexyl group.

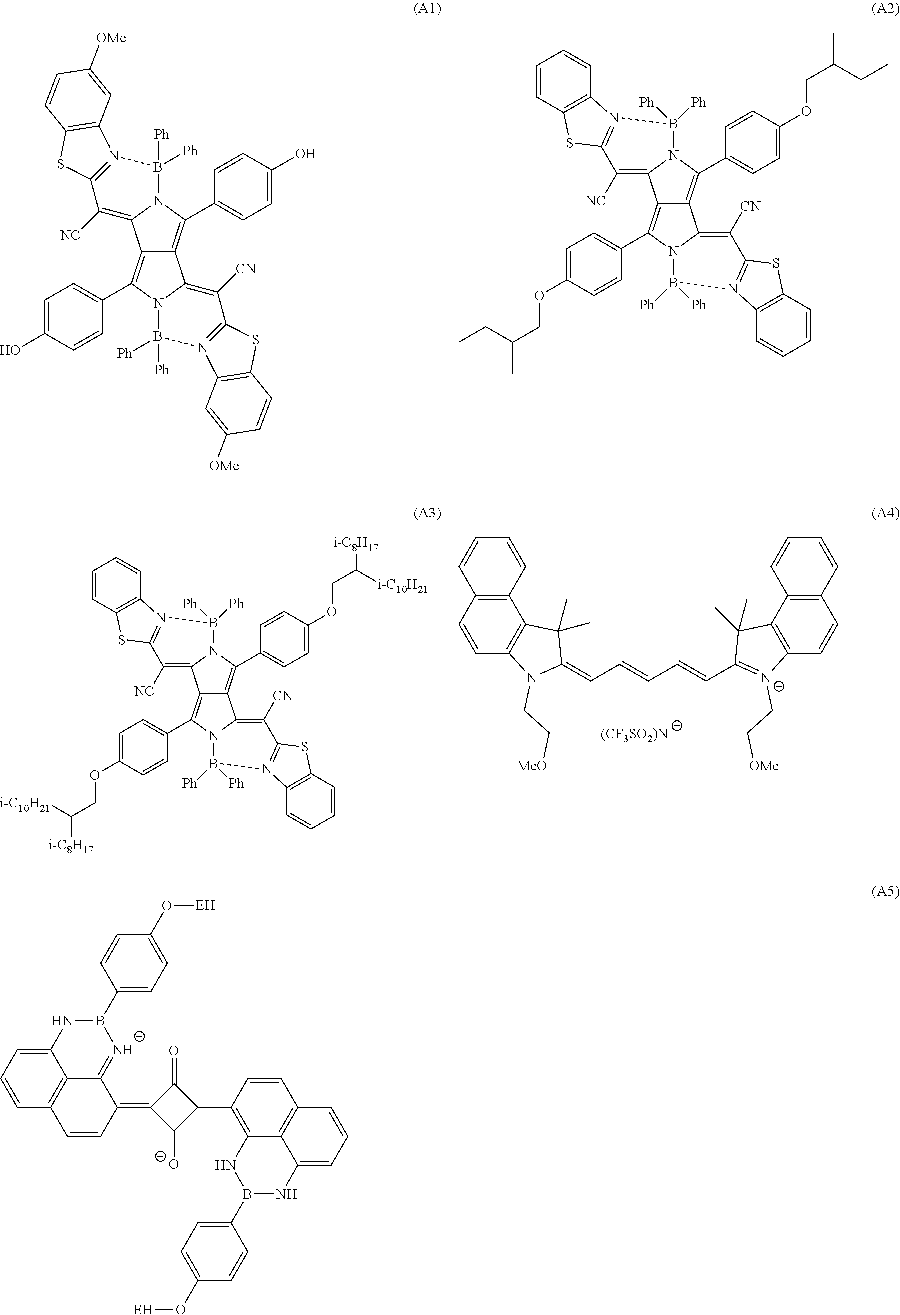

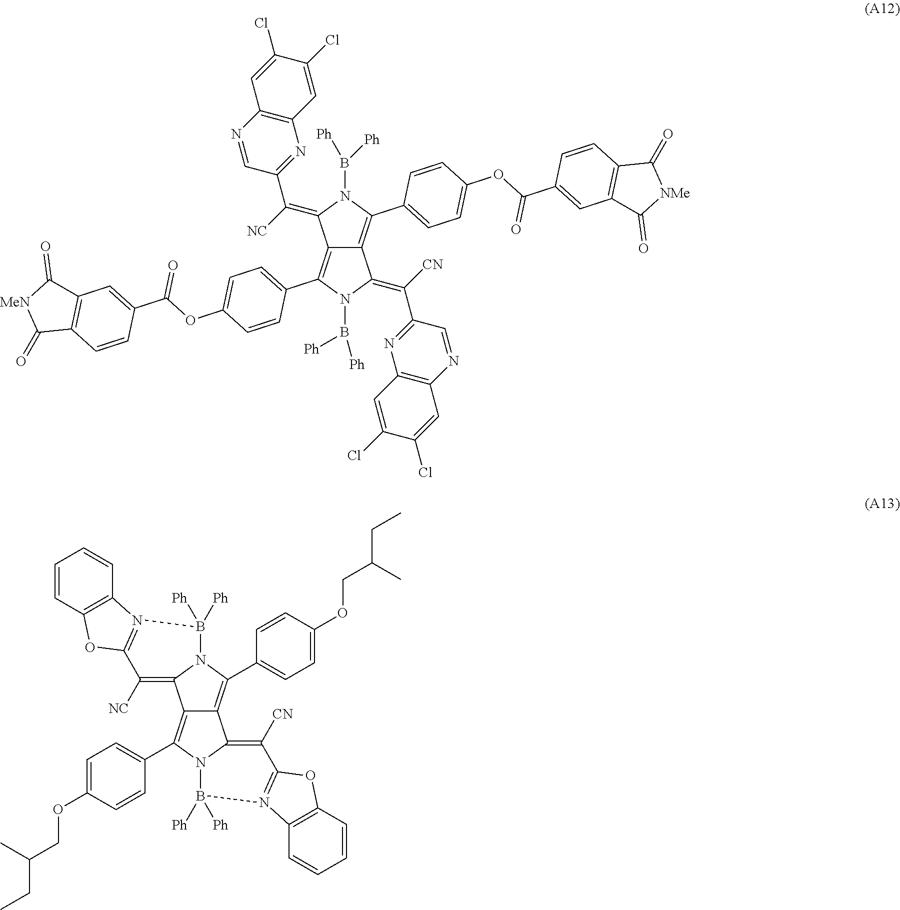

A6: a compound 31 described in paragraph “0051” of JP2008-088426A

A7: a compound 16 described in paragraph “0049” of JP2008-088426A

A8: a compound a-1 described in paragraph “0173” of JP2016-146619A

A9: a compound a-2 described in paragraph “0173” of JP2016-146619A

A 10: a compound a-3 described in paragraph “0173” of JP2016-146619A

A11: NK-5060 (manufactured by Hayashibara Co., Ltd., Cyanine Compound)

(Pigment Derivative)

B1 to B4: compounds having the following structures. In the following structural formulae, Me represents a methyl group, and Ph represents a phenyl group.

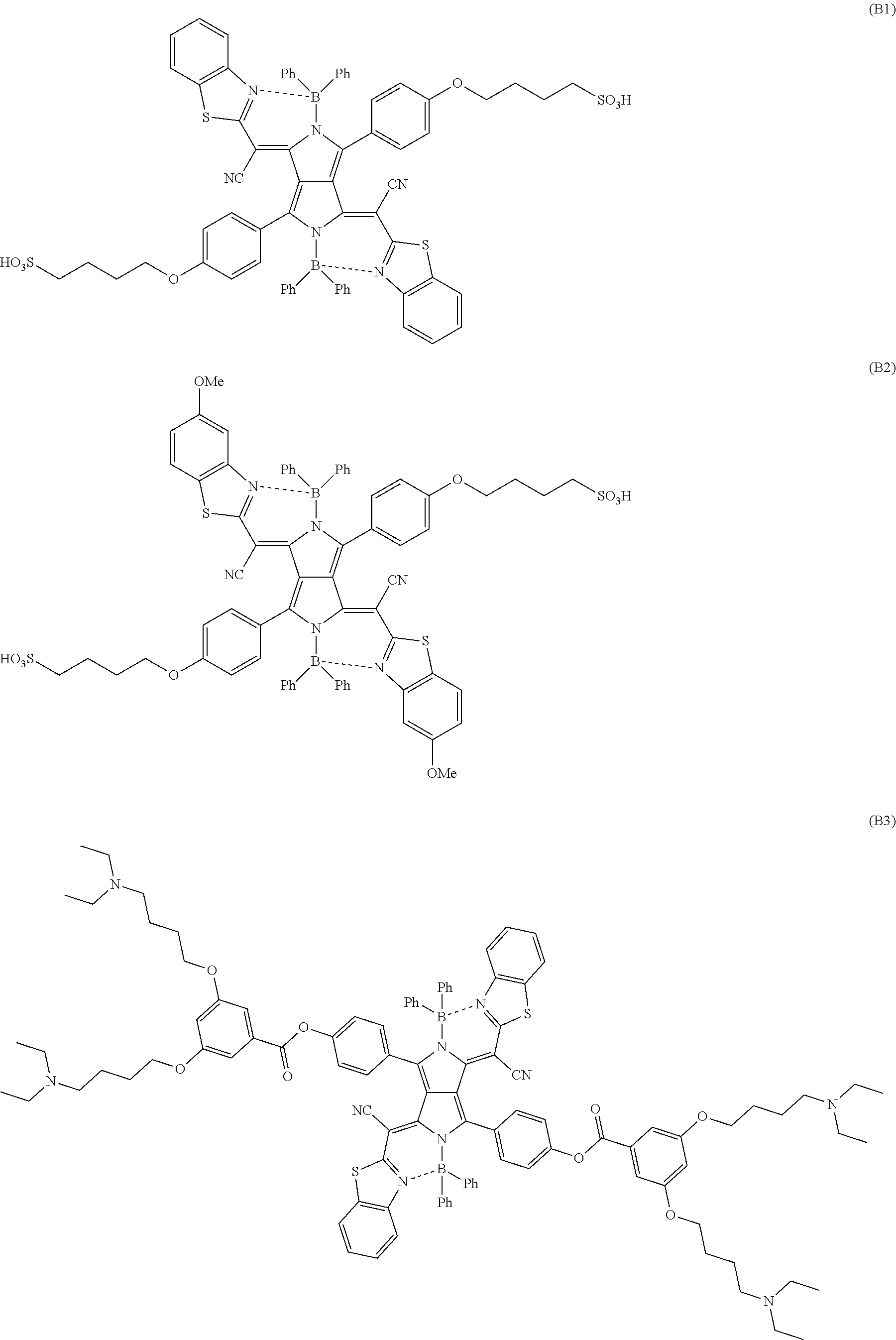

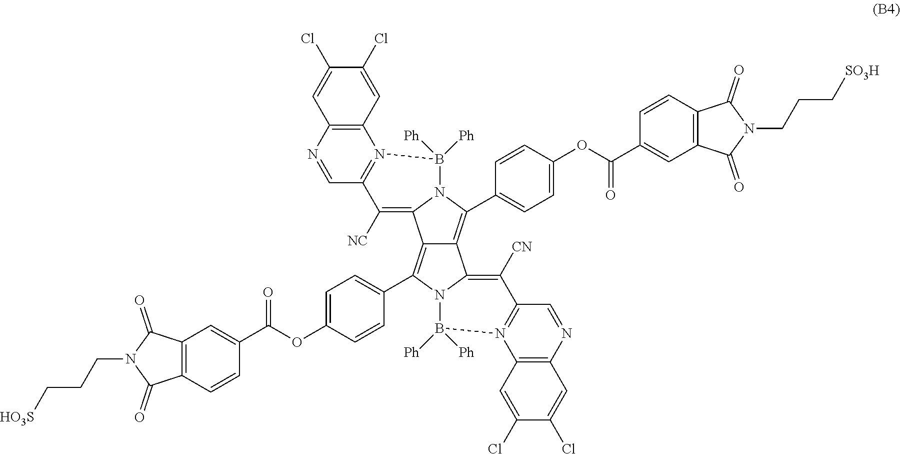

(Dispersant)

C1: a resin having the following structure (a numerical value added to a main chain represents a molar ratio, and a numerical value added to a side chain represents the number of repeating units; Mw=20000, acid value=105 mgKOH/g)

C2: a resin having the following structure (a numerical value added to a main chain represents a molar ratio, and a numerical value added to a side chain represents the number of repeating units; Mw=20000, acid value=30 mgKOH/g)

C3: a resin having the following structure (a numerical value added to a main chain represents a molar ratio, and a numerical value added to a side chain represents the number of repeating units; Mw=20000, acid value=105 mgKOH/g)

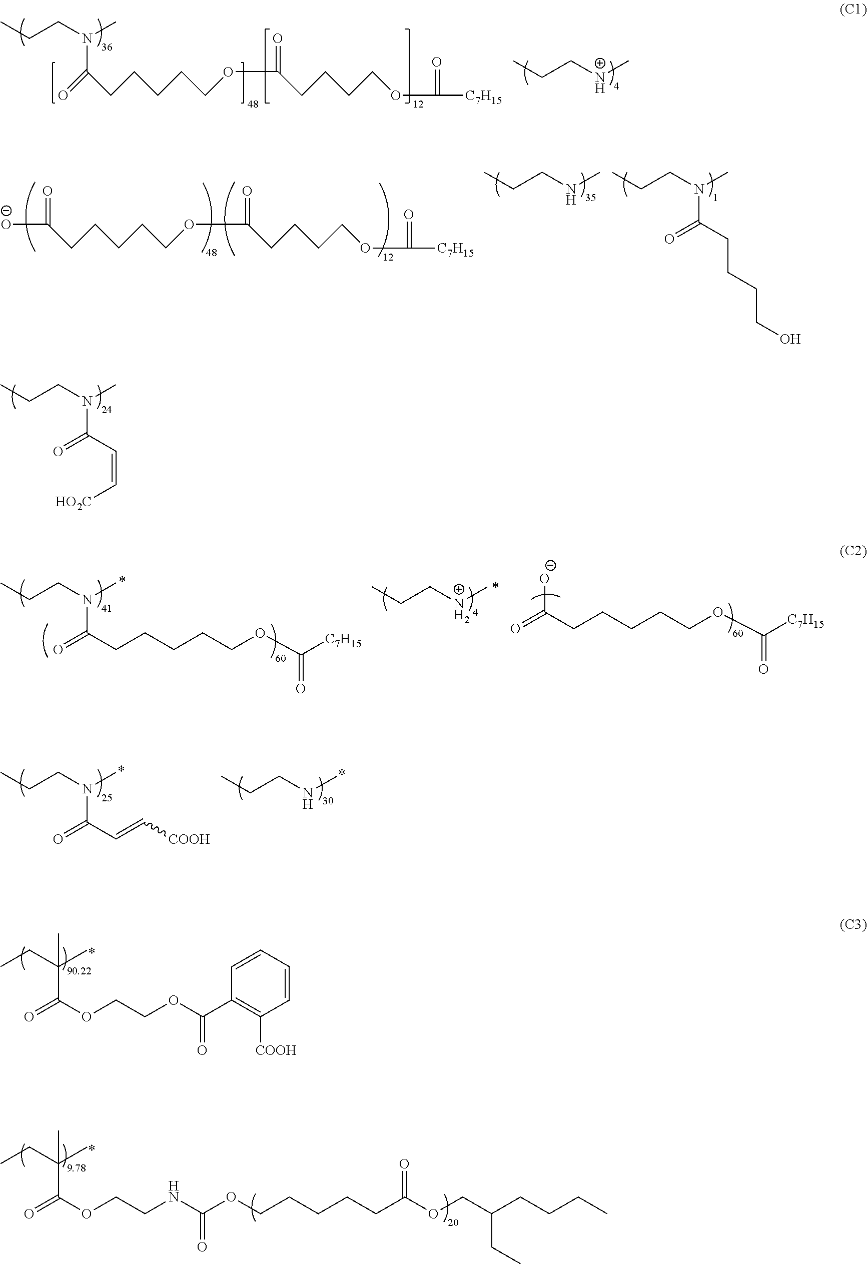

(Resin)

D1: represents a molar ratio; Mw=40000, acid value=100 mgKOH/g)

D2: a resin having the following structure (a numerical value added to a main chain represents a molar ratio; Mw=10000, acid value=70 mgKOH/g)

D3: a resin having the following structure (a numerical value added to a main chain represents a molar ratio; Mw=10000, acid value=70 mgKOH/g)

D4: a resin A formed using a method described in paragraphs “0169” to “0171” of JP2016-146619A

D5: ARTON F4520 (manufactured by JSR Corporation)

D6: a resin A formed using a method described in paragraph “0181” of JP2016-146619A

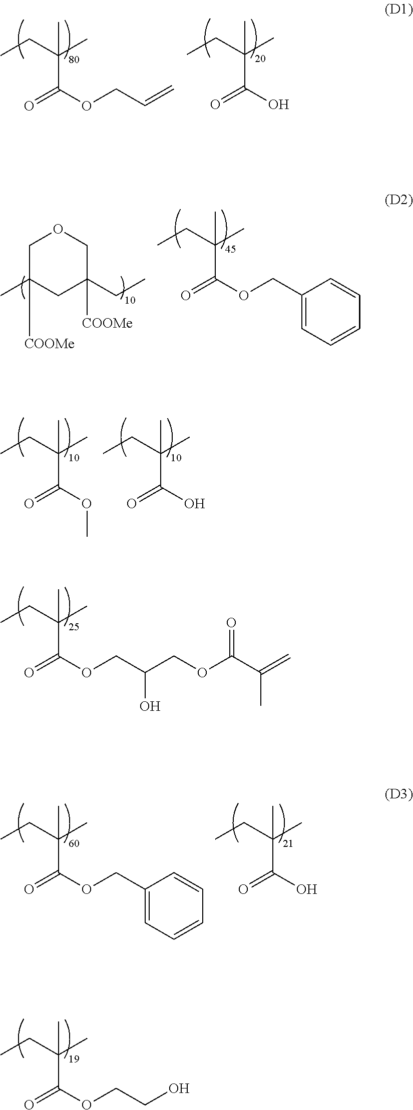

(Monomer)

M1: ARONIX M-305 (manufactured by Toagosei Co., Ltd., radically polymerizable compound)

M2: NK ESTER A-TMMT (manufactured by Shin-Nakamura Chemical Co., Ltd., radically polymerizable compound)

M3: ARONIX M-510 (manufactured by Toagosei Co., Ltd., radically polymerizable compound)

M4: ADEKA GLYCILOL ED-505 (manufactured by Adeka Corporation, an epoxy compound)

M5: RESITOP C-357 (manufactured by Gunei Chemical Industry Co., Ltd., a methylol compound).

(Epoxy Resin)

EPI: EPICLON N-695 (manufactured by DIC Corporation)

EP2: EHPE 3150 (manufactured by Daicel Corporation)

EP3: MARPROOF G-0150M (manufactured by NOF Corporation)

(Photoinitiator and Polycarboxylic Acid)

F1: IRGACURE OXE01 (manufactured by BASF SE, photoradical polymerization initiator)

F2: IRGACURE OXE02 (manufactured by BASF SE, photoradical polymerization initiator)

F3: IRGACURE OXE03 (manufactured by BASF SE, photoradical polymerization initiator)

F4: butanedioic acid (polycarboxylic acid)

F5: bis-(4-tert-butylphenyl)iodonium nonafluorobutanesulfonate (photocationic polymerization initiator)

(Ultraviolet Absorber)

UV1 to UV3: compounds having the following structures

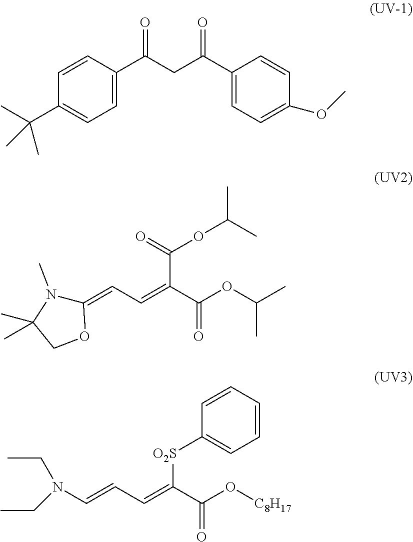

(Surfactant)

W1: the following mixture (Mw=14000, a fluorine surfactant; in the following formula, “%” representing the proportion of a repeating unit is mol %)

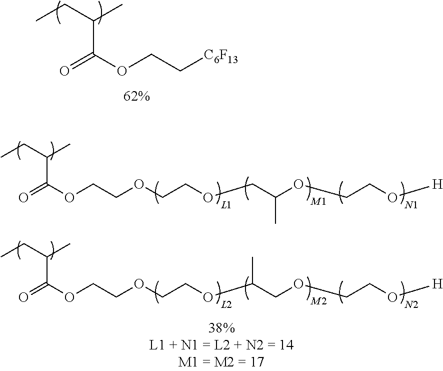

W2: KF6001 (manufactured by Shin-Etsu Chemical Co., Ltd., a silicone surfactant)

W3: MEGAFACE RS-72K (manufactured by DIC Corporation, a fluorine surfactant)

W4: FTERGENT FTX-218D (manufactured by Neos Co., Ltd., a fluorine surfactant)

(Polymerization Inhibitor)

H1: p-methoxyphenol

### (Antioxidant)

I1: ADEKA STAB AO-80 (manufactured by Adeka Corporation, a compound having the following structure)

I2: ADEKA STAB AO-60 (manufactured by Adeka Corporation, a compound having the following structure)

I3: ADEKA STAB AO-30 (manufactured by Adeka Corporation, a compound having the following structure)

I4: ADEKA STAB AO-2112 (manufactured by Adeka Corporation, a compound having the following structure)

I5: ADEKA STAB AO-412S (manufactured by Adeka Corporation, a compound having the following structure)

I6: a compound having the following structure

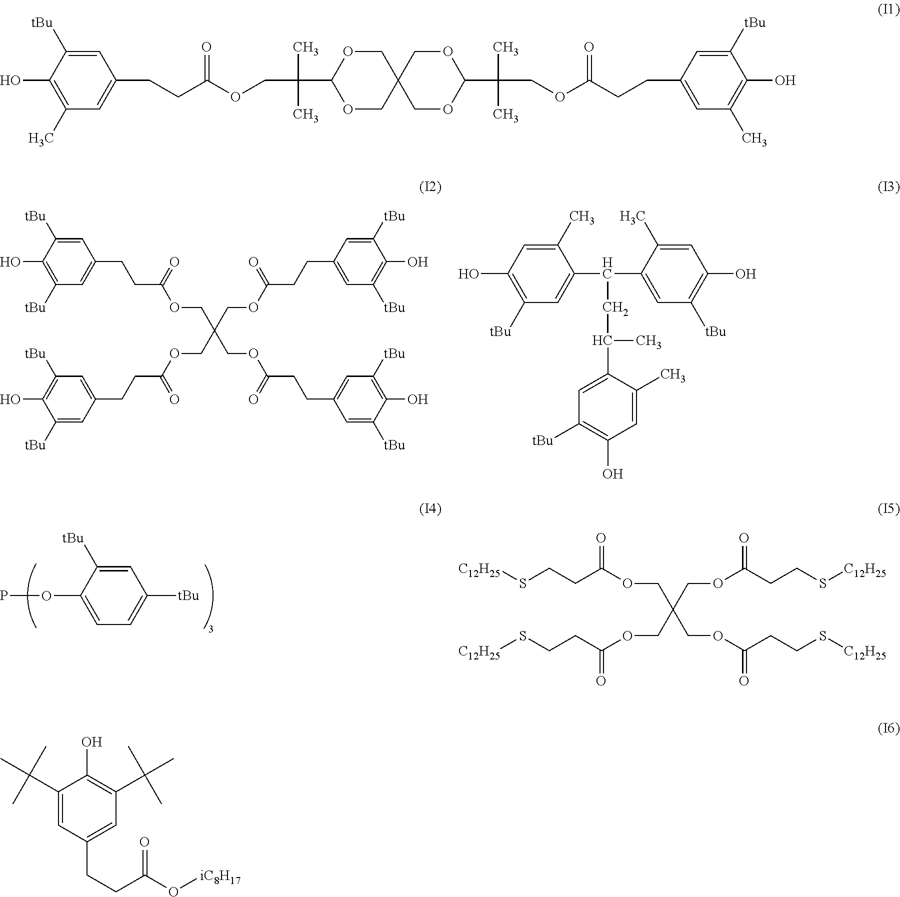

(Solvent)

J1: propylene glycol monomethyl ether acetate (PGMEA)

J2: cyclohexanone

J3: dichloromethane

<Evaluation>

[Heat Resistance] Each of the compositions was applied to a glass substrate using a spin coater (manufactured by Mikasa Co., Ltd.) such that the thickness after pre-baking was 0.8 μm. As a result, a coating film was formed. Next, the silicon wafer was heated (pre-baked) using a hot plate at 100° C. for 120 seconds. Next, the entire surface of the coating film was exposed using an i-ray stepper exposure device FPA-3000 i5+ (manufactured by Canon Corporation) at an exposure dose of 1000 mJ/cm² and then was heated (post-baked) again using a hot plate at 200° C. for 300 seconds. As a result, a film was obtained. Regarding the obtained film, the transmittance at each wavelength in a wavelength range of 400 to 450 nm was measured. Next, this film was put into a constant-temperature tank at 150° C. and was stored therein for 6 months to perform a heat-resistance test. Regarding the film after the heat-resistance test, the transmittance at each wavelength in a wavelength range of 400 to 450 nm was measured. The transmittance of the film was measured using a spectrophotometer (manufactured by Hitachi High-Technologies Corporation, U-4100).

A maximum value (ΔT) of a change in transmittance at each wavelength in a wavelength range of 400 to 450 nm before and after the heat-resistance test was measured and was set as an index indicating heat resistance.

Change (ΔT) in Transmittance=|Transmittance (%) of Film before Heat-Resistance Test−Transmittance (%) of Film after Heat-Resistance Test|

5: ΔT<2%

4: 2%≤ΔT<4%

3: 4%≤ΔT<6%

2: 6%≤ΔT<10%

1: 10%≤ΔT

[Moisture Resistance]

Each of the compositions was applied to a glass substrate using a spin coater (manufactured by Mikasa Co., Ltd.) such that the thickness after pre-baking was 0.8 μm. As a result, a coating film was formed. Next, the silicon wafer was heated (pre-baked) using a hot plate at 100° C. for 120 seconds. Next, the entire surface of the coating film was exposed using an i-ray stepper exposure device FPA-3000 i5+(manufactured by Canon Corporation) at an exposure dose of 1000 mJ/cm² and then was heated (post-baked) again using a hot plate at 200° C. for 300 seconds. As a result, a film was obtained. Regarding the obtained film, the transmittance at each wavelength in a wavelength range of 700 to 1000 nm was measured. Next, this film was put into a constant-temperature tank at 85° C. and a humidity of 95% and was stored therein for 6 months to perform a moisture-resistance test. Regarding the film after the moisture-resistance test, the transmittance at each wavelength in a wavelength range of 700 to 1000 nm was measured. The transmittance of the film was measured using a spectrophotometer (manufactured by Hitachi High-Technologies Corporation, U-4100).

A maximum value (ΔT) of a change in transmittance at each wavelength in a wavelength range of 700 to 1000 nm before and after the moisture-resistance test was measured and was set as an index indicating moisture resistance.

Change (ΔT) in Transmittance=|Transmittance (%) of Film before Moisture-Resistance Test−Transmittance (%) of Film after Moisture-Resistance Test

5: ΔT %<2%

4: 2%<ΔT<4%

3: 4%<ΔT %<6%

2: 6%<ΔT %<10%

1: 10%<ΔT %

<Sensitivity>

Each of the compositions was applied to a silicon wafer using a spin coater (manufactured by Mikasa Co., Ltd.) such that the thickness after post-baking was 1.0 μm. As a result, a coating film was formed. Next, the silicon wafer was heated using a hot plate at 100° C. for 2 minutes. Next, using an i-ray stepper exposure device FPA-3000 i5+(manufactured by Canon Corporation), the coating film was exposed through a mask having a 1 μm×1 μm Bayer pattern at an exposure dose of 1000 mJ/cm². Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated (post-baked) using a hot plate at 200° C. for 5 minutes. As a result, a pattern (near infrared cut filter) was formed.

Next, the pattern size was measured using a scanning electron microscope (SEM) to evaluate the sensitivity based on the following standards. As the pattern size increases, the sensitivity increases. In addition, in the item “Sensitivity” of the following tables, “-” represents that the sensitivity was not evaluated.

5: pattern size≥1.0 μm

4: 1.0 μm>pattern size≥0.95 μm

3: 0.95 μm>pattern size≥0.9 μm

2: 0.9 μm>pattern size≥0.8 μm

1: 0.8 μm>pattern size

<Evaluation of Cissing>

Each of the compositions was applied to a silicon wafer using a spin coater (manufactured by Mikasa Co., Ltd.) such that the thickness after post-baking was 1.0 μm. As a result, a coating film was formed. Next, the silicon wafer was heated using a hot plate at 100° C. for 2 minutes. Next, using an i-ray stepper exposure device FPA-3000 i5+(manufactured by Canon Corporation), the coating film was exposed through a mask having a 1 μm×1 μm Bayer pattern at an exposure dose of 1000 mJ/cm². Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated (post-baked) using a hot plate at 200° C. for 5 minutes. As a result, a pattern (near infrared cut filter) was formed.

Next, SR-2000S (manufactured by FFEM) was applied to the near infrared cut filter using a spin coater (manufactured by Mikasa Co., Ltd.) such that the thickness of the formed film was 1.0 μm. Next, the silicon wafer was heated using a hot plate at 100° C. for 2 minutes. Next, using an i-ray stepper exposure device FPA-3000 i5+ (manufactured by Canon Corporation), the coating film was exposed through a mask having a 1 μm×1 μm Bayer pattern at an exposure dose of 1000 mJ/cm². Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated using a hot plate at 200° C. for 5 minutes. As a result, a laminate in which a pattern of a red color filter was formed on the pattern of the near infrared cut filter was manufactured.

Next, cissing was evaluated based on the following standards.

5: the application was able to be performed without unevenness and cissing

4: there was no cissing, but unevenness was present in an area of ⅓ or less of the substrate

3: there was no cissing, but unevenness was present in an area of more than ⅓ of the substrate

2: cissing having a size of 5 mm or less was present

1: cissing having a size of more than 5 mm was present

TABLE 3

| | Evaluation Result | | | |
|---|---|---|---|---|
| | Heat | Moisture | | |
| Name | Resistance | Resistance | Sensitivity | Cissing |
| Example 1 | 5 | 5 | 5 | 5 |
| Example 2 | 4 | 3 | 5 | 5 |
| Example 3 | 4 | 5 | 5 | 5 |
| Example 4 | 4 | 4 | 5 | 5 |
| Example 5 | 3 | 4 | 5 | 5 |
| Example 6 | 4 | 3 | 5 | 5 |
| Example 7 | 3 | 3 | 5 | 5 |
| Example 8 | 4 | 5 | 5 | 5 |
| Example 9 | 4 | 4 | 5 | 5 |
| Example 10 | 5 | 4 | 5 | 5 |
| Example 11 | 5 | 5 | 5 | 5 |
| Example 12 | 5 | 5 | 5 | 5 |
| Example 13 | 5 | 5 | 5 | 5 |
| Example 14 | 4 | 5 | 5 | 5 |
| Example 15 | 3 | 4 | 5 | 5 |
| Example 16 | 3 | 4 | 5 | 5 |
| Example 17 | 3 | 4 | 5 | 5 |
| Example 18 | 3 | 4 | 5 | 5 |
| Example 19 | 5 | 5 | 5 | 5 |
| Example 20 | 5 | 5 | 5 | 5 |
| Example 21 | 5 | 5 | 5 | 5 |
| Example 22 | 3 | 5 | 5 | 5 |
| Example 23 | 4 | 5 | 5 | 5 |
| Example 24 | 3 | 4 | 5 | 5 |
| Example 25 | 4 | 5 | 5 | 5 |
| Example 26 | 5 | 4 | 4 | 5 |
| Example 27 | 5 | 4 | 5 | 5 |
| Example 28 | 5 | 5 | 5 | 5 |
| Example 29 | 5 | 3 | 4 | 5 |
| Example 30 | 5 | 4 | 4 | 5 |
| Example 31 | 5 | 5 | 5 | 5 |
| Example 32 | 4 | 3 | 4 | 5 |
| Example 33 | 5 | 4 | 4 | 5 |
| Example 34 | 5 | 5 | 4 | 5 |
| Example 35 | 5 | 5 | 4 | 5 |
| Example 36 | 5 | 5 | 4 | 5 |
| Example 37 | 5 | 4 | 5 | 5 |
| Example 38 | 5 | 4 | 5 | 5 |
| Example 39 | 4 | 5 | 4 | 5 |
| Example 40 | 5 | 4 | 5 | 5 |
| Example 41 | 5 | 4 | 5 | 5 |
| Example 42 | 4 | 5 | 4 | 5 |
| Example 43 | 5 | 5 | 3 | 5 |
| Example 44 | 3 | 3 | 5 | 5 |
| Example 45 | 5 | 5 | 5 | 3 |
| Example 46 | 3 | 3 | 5 | 5 |
| Example 47 | 4 | 5 | — | 5 |
| Example 48 | 4 | 4 | 5 | 5 |
| Example 49 | 3 | 5 | — | 5 |
| Example 50 | 3 | 5 | — | 5 |
| Example 51 | 4 | 5 | — | 5 |
| Example 52 | 5 | 5 | — | 5 |
| Example 53 | 5 | 4 | — | 5 |
| Example 54 | 3 | 3 | — | 5 |
| Example 55 | 4 | 4 | — | 5 |
| Example 56 | 3 | 3 | — | 5 |
| Example 57 | 3 | 3 | — | 5 |
| Example 58 | 3 | 3 | — | 5 |
| Example 59 | 5 | 4 | 5 | 5 |
| Example 60 | 3 | 3 | 5 | 5 |
| Example 61 | 3 | 3 | 5 | 5 |
| Example 62 | 3 | 3 | 5 | 5 |
| Example 63 | 4 | 4 | — | 5 |
| Example 64 | 3 | 3 | — | 5 |
| Example 65 | 3 | 3 | — | 5 |
| Example 66 | 3 | 3 | — | 5 |
| Example 67 | 3 | 3 | — | 5 |
| Example 68 | 3 | 3 | — | 5 |
| Comparative Example 1 | 2 | 2 | 5 | 5 |
| Comparative Example 2 | 2 | 2 | 5 | 5 |
| Comparative Example 3 | 3 | 2 | 5 | 5 |
| Comparative Example 4 | 3 | 2 | 5 | 5 |
| Comparative Example 5 | 1 | 1 | 5 | 5 |

As shown in the table, in the films formed using the compositions according to Examples, moisture resistance was excellent. Further, heat resistance was also excellent. In addition, visible transparency and near infrared shielding properties were also excellent. On the other hand, in the films formed using the compositions according to Comparative Examples 1, 2, and 5, heat resistance and moisture resistance were poor. In the films formed using the compositions according to Comparative Examples 3 and 4, moisture resistance was poor.

In each of Examples, even in a case where two or more solvents described in this specification were mixed and used as the solvent within a range where the solubility of the composition did not deteriorate, the same effects as those of each of Examples were obtained.

In each of Examples, even in a case where cyclohexyl acetate or cyclopentanone was used as the solvent, the same effects as those of each of Examples were obtained.

### Test Example 2

The composition according to Example 1 was applied to a silicon wafer using a spin coating method such that the thickness of the formed film was 1.0 μm. Next, the silicon wafer was heated using a hot plate at 100° C. for 2 minutes. Next, using an i-ray stepper exposure device FPA-3000 i5+(manufactured by Canon Corporation), the coating film was exposed through a mask having a 2 μm×2 μm Bayer pattern at an exposure dose of 1000 mJ/cm².

Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated using a hot plate at 200° C. for 5 minutes. As a result, a 2 μm×2 μm Bayer pattern (near infrared cut filter) was formed.

Next, a Red composition was applied to the Bayer pattern of the near infrared cut filter using a spin coating method such that the thickness of the formed film was 1.0 μm Next, the silicon wafer was heated using a hot plate at 100° C. for 2 minutes. Next, using an i-ray stepper exposure device FPA-3000 i5+(manufactured by Canon Corporation), the coating film was exposed through a mask having a 2 μm×2 μm Bayer pattern at an exposure dose of 1000 mJ/cm². Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated using a hot plate at 200° C. for 5 minutes. As a result, the Red composition was patterned on the Bayer pattern of the near infrared cut filter. Likewise, a Green composition and a Blue composition were sequentially patterned to form red, green, and blue color patterns.

Next, the composition for forming an infrared transmitting filter was applied to the pattern-formed film using a spin coating method such that the thickness of the formed film was 2.0 μm. Next, the silicon wafer was heated using a hot plate at 100° C. for 2 minutes. Next, using an i-ray stepper exposure device FPA-3000 i5+(manufactured by Canon Corporation), the coating film was exposed through a mask having a 2 μm×2 μm Bayer pattern at an exposure dose of 1000 mJ/cm². Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated using a hot plate at 200° C. for 5 minutes. As a result, the infrared transmitting filter was patterned on a portion where the Bayer pattern of the near infrared cut filter was not formed. This filter was incorporated into a solid image pickup element using a well-known method.

Using the obtained solid image pickup element, a subject was irradiated with an infrared light emitting diode (infrared LED) as a light source in a low-illuminance environment (0.001 Lux) to acquire images. Next, the imaging performance of the solid image pickup element was evaluated. The subject was able to be clearly recognized on the image. In addition, incidence angle dependence was good.

The Red composition, the Green composition, the Blue composition, and the composition for forming an infrared transmitting filter used in Test Example 2 are as follows.

(Red Composition)

The following components were mixed and stirred, and the obtained mixture was filtered through a nylon filter (manufactured by Pall Corporation) having a pore size of 0.45 μm to prepare a Red composition.

| | |
|---|---|
| Red Pigment Dispersion | 51.7 parts by mass |
| Resin 4 (40 mass % PGMEA solution) | 0.6 parts by mass |
| Polymerizable Compound 4 | 0.6 parts by mass |
| Photoradical polymerization initiator 1 | 0.4 parts by mass |
| Surfactant 1 | 4.2 parts by mass |
| Ultraviolet absorber (UV-503, manufactured by | 0.3 parts by mass |
| Daito Chemical Co., Ltd.) | |
| PGMEA | 42.6 parts by mass |

(Green Composition)

The following components were mixed and stirred, and the obtained mixture was filtered through a nylon filter (manufactured by Pall Corporation) having a pore size of 0.45 μm to prepare a Green composition.

| | |
|---|---|
| Green Pigment Dispersion | 73.7 parts by mass |
| Resin 4 (40 mass % PGMEA solution) | 0.3 parts by mass |
| Polymerizable Compound 1 | 1.2 parts by mass |
| Photoradical polymerization initiator 1 | 0.6 parts by mass |
| Surfactant 1 | 4.2 parts by mass |
| Ultraviolet absorber (UV-503, manufactured by | 0.5 parts by mass |
| Daito Chemical Co., Ltd.) | |
| PGMEA | 19.5 parts by mass |

(Blue Composition)

The following components were mixed and stirred, and the obtained mixture was filtered through a nylon filter (manufactured by Pall Corporation) having a pore size of 0.45 μm to prepare a Blue composition.

| | |
|---|---|
| Blue Pigment Dispersion | 44.9 parts by mass |
| Resin 4 (40 mass % PGMEA solution) | 2.1 parts by mass |
| Polymerizable Compound 1 | 1.5 parts by mass |
| Polymerizable Compound 4 | 0.7 parts by mass |
| Photoradical polymerization initiator 1 | 0.8 parts by mass |
| Surfactant 1 | 4.2 parts by mass |
| Ultraviolet absorber (UV-503, manufactured by | 0.3 parts by mass |
| Daito Chemical Co., Ltd.) | |
| PGMEA | 45.8 parts by mass |

(Composition for Forming Infrared Transmitting Filter)

The components having the following compositions were mixed and stirred, and the obtained mixture was filtered through a nylon filter (manufactured by Pall Corporation) having a pore size of 0.45 μm to prepare a composition for forming an infrared transmitting filter.

| | |
|---|---|
| Pigment Dispersion 1-1 | 46.5 parts by mass |
| Pigment Dispersion 1-2 | 37.1 parts by mass |
| Polymerizable Compound 5 | 1.8 parts by mass |
| Resin 4 | 1.1 parts by mass |
| Photoradical polymerization initiator 2 | 0.9 parts by mass |
| Surfactant 1 | 4.2 parts by mass |
| Polymerization inhibitor (p-methoxyphenol) | 0.001 parts by mass |
| Silane coupling agent | 0.6 parts by mass |
| PGMEA | 7.8 parts by mass |

Raw materials used in the Red composition, the Green composition, the Blue composition, and the composition for forming an infrared transmitting filter are as follows.

Red Pigment Dispersion

9.6 parts by mass of C.I. Pigment Red 254, 4.3 parts by mass of C.I. Pigment Yellow 139, 6.8 parts by mass of a dispersant (Disperbyk-161, manufactured by BYK Chemie), and 79.3 parts by mass of PGMEA were mixed with each other to obtain a mixed solution, and the mixed solution was mixed and dispersed using a beads mill (zirconia beads; diameter: 0.3 mm) for 3 hours. As a result, a pigment dispersion was prepared. Next, using a high-pressure disperser NANO-3000-10 (manufactured by Nippon BEE Chemical Co., Ltd.) equipped with a pressure reducing mechanism, the pigment dispersion was further dispersed under a pressure of 2000 kg/cm³ at a flow rate of 500 g/min. This dispersing treatment was repeated 10 times. As a result, a Red pigment dispersion was obtained.

Green Pigment Dispersion

6.4 parts by mass of C.I. Pigment Green 36, 5.3 parts by mass of C.I. Pigment Yellow 150, 5.2 parts by mass of a dispersant (Disperbyk-161, manufactured by BYK Chemie), and 83.1 parts by mass of PGMEA were mixed with each other to obtain a mixed solution, and the mixed solution was mixed and dispersed using a beads mill (zirconia beads; diameter: 0.3 mm) for 3 hours. As a result, a pigment dispersion was prepared. Next, using a high-pressure disperser NANO-3000-10 (manufactured by Nippon BEE Chemical Co., Ltd.) equipped with a pressure reducing mechanism, the pigment dispersion was further dispersed under a pressure of 2000 kg/cm³ at a flow rate of 500 g/min. This dispersing treatment was repeated 10 times. As a result, a Green pigment dispersion was obtained.

Blue Pigment Dispersion

9.7 parts by mass of C.I. Pigment Blue 15:6, 2.4 parts by mass of C.I. Pigment Violet 23, 5.5 parts by mass of a dispersant (Disperbyk-161, manufactured by BYK Chemie), 82.4 parts by mass of PGMEA were mixed with each other to obtain a mixed solution, and the mixed solution was mixed and dispersed using a beads mill (zirconia beads; diameter: 0.3 mm) for 3 hours. As a result, a pigment dispersion was prepared. Next, using a high-pressure disperser NANO-3000-10 (manufactured by Nippon BEE Chemical Co., Ltd.) equipped with a pressure reducing mechanism, the pigment dispersion was further dispersed under a pressure of 2000 kg/cm³ at a flow rate of 500 g/min. This dispersing treatment was repeated 10 times. As a result, a Blue pigment dispersion was obtained.

Pigment Dispersion 1-1

A mixed solution having a composition shown below was mixed and dispersed for 3 hours using a beads mill (a high-pressure disperser with a pressure reducing mechanism, NANO-3000-10 (manufactured by Nippon BEE Chemical Co., Ltd.)) in which zirconia beads having a diameter of 0.3 mm were used. As a result, Pigment Dispersion 1-1 was prepared.

| | |
|---|---|
| Mixed pigment including a red pigment (C.I. | 11.8 parts by mass |
| Pigment Red 254) and a yellow pigment (C.I. | |
| Pigment Yellow 139) | |
| Resin (Disperbyk-111, manufactured by BYK | 9.1 parts by mass |
| Chemie) | |
| PGMEA | 79.1 parts by mass |

Pigment Dispersion 1-2

A mixed solution having a composition shown below was mixed and dispersed for 3 hours using a beads mill (a high-pressure disperser with a pressure reducing mechanism, NANO-3000-10 (manufactured by Nippon BEE Chemical Co., Ltd.)) in which zirconia beads having a diameter of 0.3 mm were used. As a result, Pigment Dispersion 1-2 was prepared.

| | |
|---|---|
| Mixed pigment including a blue pigment (C.I. | 12.6 parts by mass |
| Pigment Blue 15:6) and a violet pigment (C.I. | |
| Pigment Violet 23) | |
| Resin (Disperbyk-111, manufactured by BY | 2.0 parts by mass |
| K Chemie) | |
| Resin A | 3.3 parts by mass |
| Cyclohexanone | 31.2 parts by mass |
| PGMEA | 50.9 parts by mass |

Resin A: a resin having the following structure (Mw=14000, a ratio in a structural unit is a molar ratio)

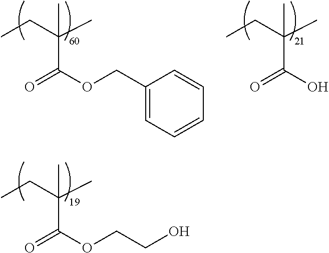

Polymerizable compound 1: KAYARAD DPHA (manufactured by Nippon Kayaku Co., Ltd.)

Polymerizable compound 4: a compound having the following structure

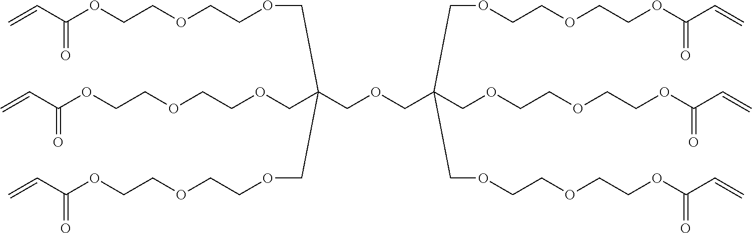 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Polymerizable compound 5: a compound having the following structures (a mixture in which a molar ratio between a left compound and a right compound is 7:3)

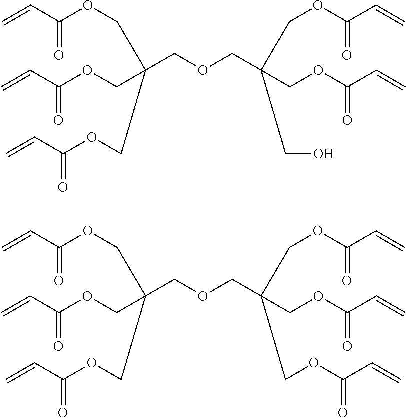

Resin 4: a resin having the following structure (acid value: 70 mgKOH/g, Mw=11000; a ratio in a structural unit is a molar ratio)

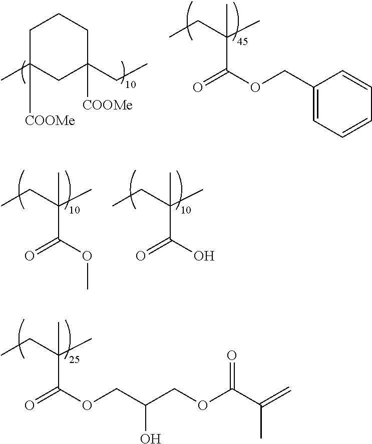

Photoradical polymerization initiator 1: IRGACURE-OXE01 (manufactured by BASF SE)

Photoradical polymerization initiator 2: a compound having the following structure

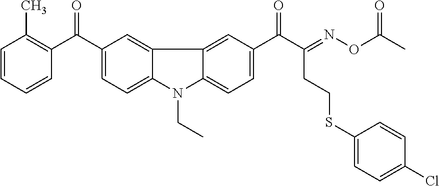 [SMILES: CCn1c2ccc(C(=O)/C(CCSc3ccc(Cl)cc3)=N/OC(C)=O)cc2c2cc(C(=O)c3ccccc3C)ccc21]

Surfactant 1: the surfactant W1

Silane coupling agent: a compound having the following structure. In the following structural formulae, Et represents an ethyl group.

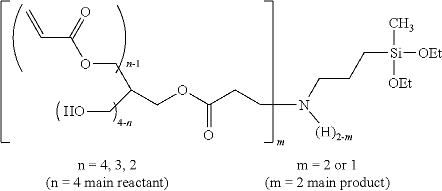

### EXPLANATION OF REFERENCES

110: solid image pickup element
111: near infrared cut filter
112: color filter
114: infrared transmitting filter
115: microlens
116: planarizing layer

What is claimed is:

1. A composition comprising:
a near infrared absorbing colorant;
a surfactant; and
an antioxidant,
wherein the near infrared absorbing colorant is a compound that includes a π-conjugated plane having a monocyclic or fused aromatic ring,
a content of the near infrared absorbing colorant is 10 mass % or higher with respect to a total solid content of the composition, and
the antioxidant is a compound that includes a phenol structure with a hydrocarbon group having one or more carbon atoms.

2. The composition according to claim 1,
wherein the antioxidant is a compound having a structure represented by the following Formula (A-1), 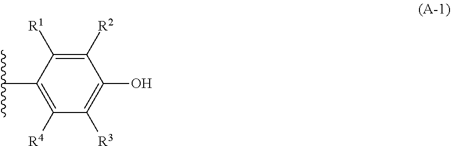
in Formula (A-1), R¹ to R⁴ each independently represent a hydrogen atom or a substituent, at least one of R¹, . . . , or R⁴ represents a hydrocarbon group having one or more carbon atoms, and a wave line represents a direct bond to another atom or atomic group in the antioxidant.

3. The composition according to claim 2,
wherein at least one of R² or R³ in Formula (A-1) represents a hydrocarbon group having one or more carbon atoms.

4. The composition according to claim 2,
wherein the antioxidant is a compound having two or more structures represented by Formula (A-1) in one molecule.

5. The composition according to claim 3,
wherein the antioxidant is a compound having two or more structures represented by Formula (A-1) in one molecule.

6. The composition according to claim 1,
wherein the antioxidant is a compound represented by the following Formula (A-2), 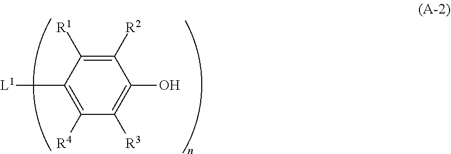
in Formula (A-2), R¹ to R⁴ each independently represent a hydrogen atom or a substituent, at least one of R¹, . . . , or R⁴ represents a hydrocarbon group having one or more carbon atoms, L¹ represents an n-valent group, and n represents an integer of 1 or more.

7. The composition according to claim 1,
wherein the surfactant is a fluorine surfactant.

8. The composition according to claim 1,
wherein the near infrared absorbing colorant has a maximum absorption in a wavelength range of 700 to 1000 nm, and
a ratio Amax/A550 of an absorbance Amax at the maximum absorption to an absorbance A550 at a wavelength of 550 nm is 50 to 500.

9. The composition according to claim 1,
wherein the near infrared absorbing colorant is at least one selected from the group consisting of a pyrrolopyrrole compound, a squarylium compound, and a cyanine compound.

10. The composition according to claim 1, further comprising:
a chromatic colorant or a coloring material that allows transmission of infrared light and shields visible light.

11. The composition according to claim 1, further comprising:
a curable compound.

12. The composition according to claim 11, further comprising:
a photoradical polymerization initiator,
wherein the curable compound includes a radically polymerizable compound.

13. A film which is formed using the composition according to claim 1.

14. An optical filter which is formed using the composition according to claim 1.

15. The optical filter according to claim 14,
wherein the optical filter is a near infrared cut filter or an infrared transmitting filter.

16. A pattern forming method comprising:
forming a composition layer on a support using the composition according to claim 1; and
forming a pattern on the composition layer using a photolithography method or a dry etching method.

17. A solid image pickup element comprising:
the film according to claim 13.

18. An image display device comprising:
the film according to claim 13.

19. An infrared sensor comprising:
the film according to claim 13.
